(19) United States
(12) Patent Application Publication
(10) Pub. No.: US 2014/0311379 A1
(43) Pub. Date: Oct. 23, 2014

(54) Method for Preparing Liquid Chemical for Forming Water Repellent Protective Film

(71) Applicant: CENTRAL GLASS COMPANY, LIMITED, Yamaguchi (JP)

(72) Inventors: Atsushi Ryokawa, Ube-shi (JP); Shuhei Yamada, Ube-shi (JP); Masahiro Fujitani, Sanyoonoda-shi (JP); Soichi Kumon, Matsusaka-shi (JP); Masanori Saito, Matsusaka-shi (JP); Takashi Saio, Nabari-shi (JP); Shinobu Arata, Matsusaka-shi (JP); Yosuke Hashimoto, Ube-shi (JP)

(21) Appl. No.: 14/361,240

(22) PCT Filed: Nov. 19, 2012
(86) PCT No.: PCT/JP2012/079902

§ 371 Date: May 28, 2014

(30) Foreign Application Priority Data
Nov. 29, 2011 (JP) 2011-261011
Oct. 29, 2012 (JP) 2012-237503

(51) Int. Cl. H01L 21/02

(52) U.S. Cl. CPC H01L 21/02282; H01L 21/02068
USPC 106/2

(57) ABSTRACT

A method for preparing a liquid chemical for forming a water-repellant protective film, the liquid chemical having a solvent and an agent for forming a water-repellant protective film, the liquid chemical being for forming a water-repellent protective film at least on surfaces of recessed portions of an uneven pattern of a wafer having the uneven pattern at its surface, the method including: a first refinement step for eliminating the elements (metal impurities) Na, Mg, K, Ca, Mn, Fe, Cu, Li, Al, Cr, Ni, Zn and Ag in a solvent by distilling the solvent or by a particle-eliminating membrane and an ion exchange resin membrane; a mixing step for mixing the solvent after the first refinement step and an agent for forming a water-repellant protective film; and a second refinement step for eliminating particles in a liquid chemical after the mixing step by a particle-eliminating membrane.

### TECHNICAL FIELD

The present invention relates to a technique for cleaning a substrate (a wafer) in semiconductor device manufacturing and the like, the objective of which is to improve the production yield of devices having a circuit pattern. The present invention particularly relates to: a liquid chemical for forming a water-repellent protective film and to a method for preparing the same, the objective of which is to improve a cleaning step which tends to induce a wafer having an uneven pattern at its surface to cause a collapse of the uneven pattern.

### BACKGROUND OF THE INVENTION

Semiconductor devices for use in networks or digital household electric appliances are being further desired to be sophisticated, multifunctional, and low in power consumption. Accordingly the trend toward micro-patterning for circuits has been developed, with which micro-sizing of particles has so advanced as to cause reduction of production yield. As a result of this, a cleaning step for the purpose of removing contaminants such as the micro-sized particles and the like has frequently been used. As a result, 30-40% of the whole of the semiconductor fabrication process is occupied with the cleaning step.

On the other hand, at the time of cleaning as conventionally performed with an ammonia-mixed cleaning agent, damages to a wafer due to its basicity has been getting serious together with the trend toward micro-patterning for circuits. Therefore, alternation with a less damaging one e.g. a dilute hydrofluoric acid-based cleaning agent has been proposed.

With this, problems about the damages to the wafer due to cleaning have been solved; however, problems due to an aspect ratio increased with the trend toward micro-processing in the semiconductor devices have become obvious. In other words, a phenomenon where the pattern causes a collapse when a gas-liquid interface passes through the pattern is brought about after cleaning or rinsing so as to largely reduce the yield, which has become a significant problem.

The pattern collapse occurs at the time of removing cleaning liquid or rinsing liquid from the wafer. The reason thereof is said that a difference in height of residual liquid between a part having a high aspect ratio and a part having a low aspect ratio makes a difference in capillary force which acts on the pattern.

Accordingly, the pattern collapse is excepted to be solved by reducing the capillary force to decrease the difference in capillary force due to the difference in height of the residual liquid. The degree of the capillary force is the absolute value of P obtained by the equation as shown below. From this equation, it is expected that the capillary force can be reduced by decreasing γ or cos θ.

P=2×γ×cos θ/S

(γ: Surface tension, θ: Contact angle, S: Pattern width (the widths of the recessed portions))

In Patent Publication 1, there is disclosed a cleaning process in which a wafer surface provided to have an uneven pattern with a film containing silicon is surface-reformed by oxidation or the like and a water-repellent protective film is formed on the surface by using a water-soluble surfactant or a silane coupling agent thereby reducing the capillary force to prevent the pattern collapse. Additionally, in Patent Publications 2 to 6, it is disclosed that a cleaning step which tends to cause a collapse can be improved by using a water-repellent cleaning liquid for imparting water-repellency at least to recessed portions of an uneven pattern of a silicon wafer.

As the above-mentioned wafer, a wafer that contains a silicon element at its surface has generally been employed; however, a wafer that contains elements such as titanium, tungsten, aluminum, copper, tin, tantalum and ruthenium at its surface is getting employed together with the diversification of the pattern. In Patent Document 7, there is disclosed a wafer having a finely uneven pattern at its surface and containing at least one kind of element selected from the group consisting of titanium, titanium nitride, tungsten, aluminum, copper, tin, tantalum nitride, ruthenium and silicon at surfaces of recessed portions of the uneven pattern, and it is disclosed that a cleaning step which tends to cause a collapse in such a wafer can be improved by using a liquid chemical that contains a water-repellent protective film-forming agent for forming a water-repellent protective film at least on the surfaces of the recessed portions at the time of cleaning the wafer.

### REFERENCES ABOUT PRIOR ART

### Patent Documents

Patent Document Japanese Patent No. 4403202
Patent Document 2: Japanese Patent Application Publication No. 2010-192878
Patent Document 3: Japanese Patent Application Publication No. 2010-192879
Patent Document 4: Japanese Patent Application Publication No. 2011-272852
Patent Document 5: Japanese Patent Application Publication No. 2012-033873
Patent Document 6: Japanese Patent Application Publication No. 2012-015335
Patent Document 7: Japanese Patent No. 4743340

### SUMMARY OF THE INVENTION

### Problems to be Solved by the Invention

A liquid chemical for forming a water-repellant protective film which liquid chemical is for forming a water-repellent protective film at least on surfaces of recessed portions of an uneven pattern of a wafer having the uneven pattern at its surface (the liquid chemical may hereinafter be referred to as “a liquid chemical for forming a protective film” or merely as “a liquid chemical”) is required to be low in content of metal impurities which can bring about a fear of increasing a junction leak current in the device and to be clean, like a cleaning liquid for cleaning a wafer. However, of the above-mentioned liquid chemical, some are subject to degeneration by heat and some are liable to exhibit hydrolizability; hence such liquid chemicals may not be refined by distillation. The present invention is directed to a liquid chemical for forming a water-repellant protective film which liquid chemical is for forming a water-repellent protective film at least on surfaces of recessed portions of an uneven pattern of a wafer having the uneven pattern at its surface (the wafer may hereinafter be referred to merely as “a wafer”), in which an object of the present invention is to provide: a liquid chemical reduced in concentration of the elements Na, Mg, Ca, Mn, Fe, Cu, Li, Al, Cr, Ni, Zn and Ag (the concentration may hereinafter be referred to as “metal impurity concentration”) and in amount of particles contained in the liquid chemical; and a method for preparing the same. Another object of the present invention is to provide: a liquid chemical kit for forming a water-repellant protective film, the liquid chemical kit allowing producing the liquid chemical by being mixed; and a method for preparing the liquid chemical kit.

### Means for Solving the Problems

In the present invention, “a water-repellent protective film” means a film formed on a wafer surface no as to reduce the wettability of the wafer surface, i.e., a film that imparts water-repellency to the surface. In the present invention, “water-repellency” means to decrease a surface energy of a surface of an article thereby weakening the interaction between water or another liquid and the surface of the article (i.e., at the interface) such as a hydrogen bond, intermolecular forces and the like. The effect of reducing the interaction is particularly exhibited against water, but it is also exhibited against a mixture liquid of water and a liquid other than water or against a liquid other than water. With the reduction of the interaction, the contact angle of the liquid to the article surface can be increased. Hereinafter, the water-repellent protective film may be referred to merely as “a protective film”. Incidentally, the water-repellent protective film may be formed from an agent for forming a water-repellent protective film as will be discussed below, and may be formed to contain a reactant of which primary component is the agent for forming a water-repellent protective film.

If a treatment is conducted on the wafer by using the liquid chemical or a liquid chemical obtained from a liquid chemical kit of the present invention, the protective film has been formed on the surfaces of the recessed portions of the wafer at the time of removing or drying the cleaning liquid out of the recessed portions of the uneven pattern of the wafer, so that the capillary force of the surfaces of the recessed portions is lowered to make a pattern collapse difficult to occur. “A treatment on the wafer by using a liquid chemical” means to form a protective film at least on the surfaces of the recessed portions while retaining the liquid chemical or a liquid chemical obtained from a liquid chemical kit at least in the recessed portions of the uneven pattern of the wafer. A system of treating the wafer is not particularly limited so long as the liquid chemical can be retained at least in the recessed portions of the uneven pattern of the wafer. Examples of the system of treating the wafer are: a single treatment system represented by spin treatment where a generally horizontally held wafer is rotated and treated one by one while supplying a liquid chemical to the vicinity of the center of the rotation; and a batch system where a plurality of wafer sheets are immersed in a treatment bath to be treated. Incidentally the form of the liquid chemical at the time of supplying the liquid chemical at least to the recessed portions of the uneven pattern of the wafer is not particularly limited as far as it is in a condition of liquid at the time of being retained in the recessed portions, and is exemplified by liquid, vapor or the like.

The liquid chemical preferably has a metal impurity concentration of not higher than 0.1 mass ppb per each element, relative to the total amount of the liquid chemical. A concentration of higher than 0.1 mass ppb brings about a fear of increasing a junction leak current in the device so as to result in the occurrence of the reduction of the yield of the device and the reduction of the reliability which is therefore not preferable. On the other hand, a concentration of not higher than 0.1 mass ppb is preferable because a step of cleaning the wafer surface (or the surface of the protective film) with use of a solvent or water after the protective film is formed on the wafer surface can be omitted or downscaled. Thus a lower metal impurity concentration is preferable. However, a concentration of not lower than 0.001 mass ppb per each element relative to the total amount of the liquid chemical is acceptable insofar as it falls within the abovementioned concentration range. In the case of a liquid chemical kit, the metal impurity concentration in a liquid chemical obtained from the liquid chemical kit is preferably of not higher than 0.1 mass ppb per each element, relative to the total amount of the liquid chemical. Incidentally the liquid chemical kit according to the present invention is provided to contain a treatment liquid (A) and a treatment liquid (B) as will be mentioned below, wherein the metal impurity concentration in the treatment liquid (A) is not higher than 0.1 mass ppb per each element relative to the total amount of the treatment liquid (A) while the metal impurity concentration in the treatment liquid (B) is not higher than 0.1 mass ppb per each element relative to the total amount of the treatment liquid (B). The reason for preparing the treatment liquids (A) and (B) to fall within the above-mentioned metal impurity concentration range is that the metal impurity concentration in the liquid chemical obtained from the liquid chemical kit becomes readily adjusted to not higher than 0.1 mass ppb per each element relative to the total amount of the liquid chemical. Measurement of the metal impurity concentration in the present invention can be performed by a measurement using an inductively coupled plasma mass spectroscope, for example.

The above-mentioned metal impurities include the elements Na, Mg, K, Ca, Mn, Fe, Cu, Li, Al, Cr, Ni, Zn and Ag in the form of metal particle, ion, colloid, complex, oxide and nitride, and correspond to all that exists in the liquid chemical irrespective of whether it is dissolved or not.

Additionally, concerning a particle measurement in a liquid phase of the liquid chemical conducted by a laser light-scattering type detector, it is preferable that the number of particles of larger than 0.2 μm is not more than 100 per 1 mL of the liquid chemical. If the number of particles of larger than 0.2 μm exceeds 1.00 per 1 mL of the liquid chemical, there arises a fear of inducing a pattern damage due to particles so as to result in reducing the device in yield and reliability and therefore not preferable. Additionally, if the number of particles of larger than 0.2 μm is not more than 100 per 1 mL of the liquid chemical, a cleaning operation to be conducted with a solvent or water after the formation of the protective film can be omitted or downscaled and therefore preferable. Incidentally, a lower number of particles of larger than 0.2 μm is more preferable but one or more per 1 mL of the liquid chemical is acceptable. Incidentally, the liquid chemical kit according to the present invention is provided to contain a treatment, liquid (A) and a treatment liquid (B) as will be mentioned below, wherein the number of particles of larger than 0.2 μm measured by a particle measurement in a liquid phase of the treatment liquid (A) conducted by a laser light-scattering type detector is preferably not more than 100 per 1 mL of the treatment liquid (A) while the number of such particles in a liquid phase of the treatment liquid (B) is preferably not more than 100 per 1 mL of the treatment liquid (B). The reason for preparing the treatment liquids (A) and (B) to fall within the above-mentioned particle number range is that the particle number in the liquid chemical obtained from the liquid chemical kit becomes readily adjusted to not more than 100 per 1 mL. Additionally, the particle measurement in the liquid phase of the liquid chemical or the treatment liquid according to the present invention is conducted by using a commercially available measurement device to which a light-scattering type measuring method for particles in liquid is applied, where a particle diameter means a light-scattering equivalent diameter based on a PSL (a latex formed of polystyrene) standard particle.

By the way, “particle” as discussed above means particle of dust, organic solid matters, inorganic solid matters and the like contained in the raw material as impurities, particle of dust, organic solid matters, inorganic solid matters and the like brought about as impurities during preparation of the liquid chemical or the treatment liquid, etc., and correspond to all that is not dissolved and finally exists in the liquid chemical or the treatment liquid as particles.

Among the liquid chemicals, some have corrosivity against metals. In this case, it is necessary for the material of a portion brought into contact with the liquid to adopt a resinous material not causing metal elution into the liquid chemical, in order to reduce metal impurities in the liquid chemical and keep the liquid chemical clear. The resinous material is low in electric conductivity and insulative; therefore, when the liquid chemical is led through a resinous pipe or when the liquid chemical is refined by filtration using a particle-eliminating resinous membrane or resinous ion exchange resin membrane having a large contacting area between a filter medium and a liquid, the charged electric potential in the liquid chemical is so increased as to raise a fear of causing an electric shock at the time of human body being contacted with the exterior or the like of the pipe or a fear of causing fire or damage (e.g. cracks and pinpole) to the pipe or facilities due to spark (spark discharge), which sometimes increases the risk of bringing about static electricity disaster. A measure of management of the liquid chemical for forming a water-repellent protective film, the liquid chemical kit for forming a water-repellent protective film and the solvent used as raw material in terms of the charged electric potential is as discussed in page 88 of “Static Electricity Safety Guideline 2007” edited by National Institute of Occupational Safety and Health, Japan, More specifically; the charged electric potential of a liquid is preferably managed to be not higher than 1 kV when the minimum ignition energy of a liquid is less than 0.1 mJ, and not higher than 5 kV when the minimum ignition energy of a liquid is not less than 0.1 mJ and less than 1 mJ, and not higher than 1.0 kV when the minimum ignition energy of a liquid exceeds 1 mJ. Furthermore, a charged electric potential which is held smaller makes the obtained liquid chemical or liquid chemical kit more difficult to ignite, which is therefore preferable in view of safety. In the present invention, incidentally the measurement of the charged electric potential can be conducted by a static meter, for example.

The present invention is a method for preparing a liquid chemical for forming a water-repellant protective film, the liquid chemical having a solvent and an agent for forming a water-repellant protective film, the liquid chemical being for forming a water-repellent protective film at least on surfaces of recessed portions of an uneven pattern of a wafer having the uneven pattern at its surface, the method being characterized by comprising:

a first refinement step for eliminating the elements (metal impurities.) Na, Mg, K, Ca, Mn, Fe, Cu, Li, Al, Cr, Ni, Zn and Ag in a solvent by distilling the solvent or by using a particle-eliminating membrane and an ion exchange resin membrane;

a mixing step for mixing the solvent of after the first refinement step and an agent for forming a water-repellant protective film; and

a second refinement step for eliminating particles in a liquid chemical of after the mixing step by using a particle-eliminating membrane. Hereinafter, the above-mentioned preparation method will be referred to as “a first preparation method of the present invention”. A flowchart of the first preparation method is shown in FIG. 1.

The solvent to be mixed with the agent for forming a water-repellent protective film in the mixing step of the first preparation method of the present invention may be formed of the solvent of after the first refinement step only. Incidentally the solvent to be mixed with the agent for forming a water-repellent protective film in the mixing step may be a mixed solvent formed of two or more kinds of solvents and all of them may be the solvent refined by the first refinement step.

Moreover, the solvent to be mixed with the agent for forming a water-repellent protective film in the mixing step of the first preparation method may be two or more kind. Of these, a solvent component of less than 35 mass % relative to the total amount of the mixed solvent may not undergo the first refinement step. More specifically, among the solvents to be mixed with the agent for forming a water-repellent protective film in the mixing step, a solvent component of not less than 35 mass % relative to the total amount of the solvents undergoes the first refinement step but a solvent component of less than 35 mass % relative to the total amount of the solvents may not undergo the first refinement step. If a solvent component of less than 35 mass % is two or more kinds and the total of these amounts to not less than 35 mass %, any of the solvent components of less than 35 mass % is required to undergo the first refinement step thereby adjusting the total amount of solvent components that have undergone the first refinement step to 65 mass % or more relative to the total amount of solvents to be mixed with the agent for forming a water-repellent protective film.

Additionally, it is preferable that the first preparation method of the present invention further involves a discharge step where at least one selected from the solvent of after the first refinement step and the liquid chemical for forming a water-repellent protective film which liquid chemical is obtained after the second refinement step is brought into contact with an electrically conductive material. By virtue of the discharge step, the charged electric potential of a solvent or liquid chemical which is under a charged condition can be reduced to the range as discussed above in the measure of management of the charged electric potential. With this, it becomes possible to safely prepare the liquid chemical while obtaining a liquid chemical which is under a safer condition, i.e., a condition lower in risk of ignition.

Moreover, the present invention is a method for preparing a liquid chemical for forming a water-repellant protective film, the liquid chemical having a solvent and an agent for forming a water-repellant protective film, the liquid chemical being for forming a water-repellent protective film at least on surfaces of recessed portions of an uneven pattern of a wafer having the uneven pattern at its surface, the method being characterized by comprising:

a mixing step for mixing a solvent and an agent for forming a water-repellant protective film; and

a third refinement step for eliminating the elements (metal impurities) Na, Mg, K, Ca, Mn, Fe, Cu, Li, Al, Cr, Ni, Zn and Ag and particles in a liquid chemical of after the mixing step, by using a particle-eliminating membrane and an ion exchange resin membrane. Hereinafter, the above-mentioned preparation method will be referred to as “a second preparation method of the present invention”. A flowchart of the second preparation method is shown in FIG. 2.

Additionally, it is preferable that the second preparation method of the present invention further involves a discharge step where the liquid chemical for forming a water-repellent protective film obtained after the third refinement, step is brought into contact with an electrically conductive material. By virtue of the discharge step, the charged electric potential of a liquid chemical which is under a charged condition can be reduced to the range as discussed above in the measure of management of the charged electric potential. With this, it becomes possible to safely prepare the liquid chemical while obtaining a liquid chemical which is under a safer condition, i.e., a condition lower in risk of ignition.

In the first and second preparation methods, it is preferable that the agent for forming a water-repellant protective film comprises at least one selected from the group consisting of silylation reagents represented by the following general formula [1] and an acid or base. Hereinafter, the method for preparing a liquid chemical for forming a water-repellant protective film, to which the above-mentioned agent for forming a water-repellant protective film is used may be referred to as “a first embodiment”.

(R¹)ₐSi(H)_{b}X¹_{4-a-b} [1]

[In the formula [1], R¹ mutually independently represents a monovalent organic group having a C₁-C₁₈ monovalent hydrocarbon group the hydrogen elements of which may partially or entirely be replaced with a fluorine element(s); X¹ mutually independently represents at least one selected from the group consisting of a monovalent functional group of which element to be bonded to a silicon element is nitrogen, a monovalent functional group of which element to be bonded to a silicon element is oxygen, a halogen group, a nitrile group and —CO—NH—Si(CH₃)₃ group; “a” is an integer of from 1 to 3; “b” is an integer of from 0 to 2; and the total of “a” and “b” is 1 to 3.]

Hereinafter, a first embodiment will be discussed.

The acid preferably comprises at least one selected from the group consisting of hydrogen chloride, sulfuric acid, perchloric acid, phosphoric acid, sulfonic acid represented by the following general formula [2] and anhydride thereof, carboxylic acid represented by the following general formula [3] and anhydride thereof, alkyl borate ester, aryl borate ester, boron tris(trifluoroacetate), trialkoxyboroxin, boron trifluoride and a silane compound represented by the following general formula [4].

R²S(O)₂OH [2]

[In the formula [2], R² represents a C₁-C₁₈ monovalent hydrocarbon group the hydrogen elements of which may partially or entirely be replaced with a fluorine element(s).]

R³COOH [3]

[In the formula [3]. R³ represents a C₁-C₁₈ monovalent hydrocarbon group the hydrogen elements of which may partially or entirely be replaced with a fluorine element(s).]

(R⁴)_{c}Si(H)_{d}X²_{4-c-d} [4]

[In the formula [4], R⁴ mutually independently represents a C₁-C₁₈ monovalent, hydrocarbon group the hydrogen elements of which may partially or entirely be replaced with a fluorine element(s); X² mutually independently represents at least one selected from the group consisting of chloro group, —OCO—R⁵ (where R⁵ is a C₁-C₁₈ monovalent hydrocarbon group the hydrogen elements of which may partially or entirely be replaced with a fluorine element(s)) and —OS(O)₂—R⁶ (where R⁶ is a C₁-C₁₈ monovalent hydrocarbon group the hydrogen elements of which may partially or entirely be replaced with a fluorine element(s)); “c” is an integer of from 1 to 3; “d” is an integer of from 0 to 2; and the total of “c” and “d” is 1 to 3.]

The base preferably comprises at least one selected from the group consisting of ammonia, N,N,N′,N′-tetramethylethylenediamine, triethylenediamine, dimethylaniline, alkylamine, dialkylamine, trialkylamine, pyridine, piperazine. N-alkylmorpholine and a silane compound represented by the following general formula [5].

(R⁷)ₑSi(H)_{f}X³_{4-e-f} [5]

[In the formula [5]. R⁷ mutually independently represents a C₁-C₁₈ monovalent hydrocarbon group the hydrogen elements of which may partially or entirely be replaced with a fluorine element(s); X³ mutually independently represents a monovalent, functional group of which element to be bonded to a silicon element is nitrogen, the monovalent functional group possibly containing a fluorine element or a silicon element; “e” is an integer of from 1 to 3; “f” is an integer of from 0 to 2; and the total of “e” and “f” is 1 to 3.]

The solvent, preferably comprises at least one selected from the group consisting of hydrocarbons, esters, ethers, ketones, halogen-containing solvents, sulfoxide-based solvents, lactone-based solvents, carbonate-based solvents, polyalcohol derivatives having no OH group, and nitrogen element-containing solvents having no N—H group.

Additionally, in the first and second preparation methods, it is preferable that the agent for forming a water-repellant protective film comprises at least one kind selected from the group consisting of compounds represented by the following general formulas [6] to [13] and their salts. Hereinafter, a method for preparing a liquid chemical for forming a water-repellent protective film where the above-mentioned agent for forming a water-repellant protective film is used will sometimes be referred to as “a second embodiment”.

R⁸—P(═O)(OH)_{g}(R⁹)_{2-g} [6]

[In the formula [6], R⁸ represents a C₁-C₁₈ monovalent hydrocarbon group the hydrogen elements of which may partially or entirely be replaced with a fluorine element(s); R⁹ mutually independently represents a monovalent organic group having a C₁-C₃ hydrocarbon group the hydrogen elements of which may partially or entirely be replaced with a fluorine element(s); and “g” is an integer of from 0 to 2.]

R¹⁰C(═O)—X⁴ [7]

[In the formula [7], R¹⁰ represents a monovalent organic group having a C₁-C₁₈ hydrocarbon group or a monovalent organic group having a C₁-C₈ fluoroalkyl chain; X⁴ represents a group selected from the group consisting of fluoro group, chloro group, bromo group and iodo group.]

R¹¹R¹²R¹³N [8]

[In the formula [8], R¹¹ represents a monovalent organic group having a C₁-C₁₈ hydrocarbon group or a monovalent organic group having a. C₁-C₁₈ fluoroalkyl chain; R¹² represents a hydrogen element, a monovalent organic group having a C₁-C₁₈ is hydrocarbon group, or a monovalent organic group having a C₁-C₈ fluoroalkyl chain; R¹³ represents a hydrogen element, a monovalent organic group having a C₁-C₁₈ is hydrocarbon group, or a monovalent organic group having a C₁-C₈ fluoroalkyl chain.]

R¹⁴—C(═O)—X⁵—X⁶ [9]

the formula [9], R¹⁴ represents a monovalent organic group having a C₁-C₁₈ hydrocarbon group or a monovalent organic group having a. C₁-C₈ fluoroalkyl chain; X⁵ represents an oxygen element or sulfur element; X⁶ represents a group selected from the group consisting of a hydrogen element, alkyl group, aromatic group, pyridyl group, quinolyl group, succinimide group, maleimide group, benzoxazole group, benzothiazole group and benzotriazole group; and a hydrogen element(s) of these groups may be substituted with an organic group.]

R¹⁵(X⁷)ₕ [10]

[The formula 10] represents a compound where “h” hydrogen elements) or fluorine elements) of R¹⁵ representing a C₁-C₁₈ hydrocarbon the hydrogen elements of which may partially or entirely be replaced with a fluorine element(s) is mutually independently substituted with a group represented by X⁷, the group X⁷ being at least one selected from the group consisting of an isocyanate group, mercapto group, aldehyde group, —CONHOH group and a cyclic structure containing a nitrogen element, wherein “h” is an integer of from 1 to 6.]

R¹⁶—X⁸ [11]

[In the formula [11], X⁸ represents a cyclic structure containing a sulfur element; R¹⁶ represents a monovalent organic group having a C₁-C₁₈ hydrocarbon group or a monovalent organic group having a C₁-C₈ fluoroalkyl chain.]

R¹⁷—C(═O)—X⁹—C(═O)—R¹⁸ [12]

[In the formula [12], R¹⁷ represents a monovalent organic group having a C₁-C₁₈ hydrocarbon group or a monovalent organic group having a. C₁-C₈ fluoroalkyl chain; R¹⁸ represents a monovalent organic group having a C₁-C₁₈ hydrocarbon group or a monovalent organic group having a C₁-C₈ fluoroalkyl chain; and X⁹ represents an oxygen element or a sulfur element.]

(R²⁴—O—(R²⁵O)ₜ—ᵤP(═O)(OH)₃₋ᵤ [13]

[In the formula [13], R²⁴ mutually independently represents a C₄-C₁₈ monovalent hydrocarbon group the hydrogen elements of which may partially or entirely be replaced with a fluorine element(s); R²⁵ mutually independently represents a C₂-C₆ divalent hydrocarbon group the hydrogen elements of which may partially or entirely be replaced with a fluorine element(s); “t” mutually independently represents an integer of from 0 to 10; and “u” is 1 or 2.]

Hereinafter, the second embodiment will be discussed.

The solvent preferably comprises at least one selected from the group consisting of hydrocarbons, esters, ethers, ketones, halogen-containing solvents, sulfoxide-based solvents, lactone-based solvents, carbonate-based solvents, alcohols, polyalcohol derivatives, nitrogen element-containing solvents and water.

Furthermore, the present invention is a liquid chemical for forming a water-repellant protective film, prepared through the steps of the method for preparing a liquid chemical for forming a water-repellant protective film, as discussed in any of the above.

Additionally, the present invention is a method for preparing a liquid chemical kit for forming a water-repellant protective film, the liquid chemical kit being for forming a water-repellent protective film at least on surfaces of recessed portions of an uneven pattern of a wafer having the uneven pattern at its surface, the liquid chemical kit having a treatment liquid (A) that contains a nonaqueous organic solvent and a silylation reagent and a treatment liquid (B) that contains a nonaqueous organic solvent and an acid or base, the method being characterized by comprising:

a fourth refinement step for eliminating the elements (metal impurities) Na, Mg, K, Ca, Mn, Fe, Cu, Li, Al, Cr, Ni, Zn and Ag in a nonaqueous organic solvent by distilling the nonaqueous organic solvent or by using a particle-eliminating membrane and an ion exchange resin membrane;

a step of preparing a treatment liquid (A) by mixing the nonaqueous organic solvent of after the fourth refinement step and a silylation reagent;

a step of preparing a treatment liquid (B) by mixing the nonaqueous organic solvent of after the fourth refinement step and an acid or base; and

a fifth refinement step for eliminating particles in the treatment liquid (A) of after the step of preparing the treatment liquid (A) and for the treatment liquid (B) of after the step of preparing the treatment liquid (B), by using a particle-eliminating membrane. Hereinafter, the above-mentioned preparation method will be referred to as “a third preparation method of the present invention”. A flowchart of the third preparation method is shown in FIG. 3.

Hereinafter, the third preparation method will be discussed.

The nonaqueous organic solvent to be mixed with the silylation reagent and the acid or base in the step of preparing a treatment liquid (A) and in the step of preparing a treatment liquid (B) of the third preparation method of the present invention may be formed of the nonaqueous organic solvent of after the fourth refinement step only. Incidentally the nonaqueous organic solvent to be mixed with the silylation agent and the acid or base in each of the step of preparing a treatment liquid (A) and the step of preparing a treatment liquid (B) may be a mixed solvent formed of two or more kinds of nonaqueous organic solvents and all of them may be the nonaqueous organic solvent refined by the fourth refinement step.

Moreover, the nonaqueous organic solvent mixed with the silylation reagent and the acid or base in the step of preparing a treatment liquid (A) and in the step of preparing a treatment liquid (B) of the third preparation method may be two or more kind. Of these, a nonaqueous organic solvent component of less than 35 mass % relative to the total amount of the mixed nonaqueous organic solvent may not undergo the fourth refinement step. More specifically, among the nonaqueous organic solvents to be mixed with silylation reagent and the acid or base in the step of preparing a treatment liquid (A) and in the step of preparing a treatment liquid (B), a nonaqueous organic solvent component of not less than 35 mass % relative to the total amount of the nonaqueous organic solvents undergoes the fourth refinement step but a nonaqueous organic solvent component of less than 35 mass % may not undergo the fourth refinement step. If a nonaqueous organic solvent component of less than 35 mass % is two or more kinds and the total of these amounts to not less than 35 mass % any of the nonaqueous organic solvent components of less than 35 mass % is required to undergo the fourth refinement step thereby adjusting the total amount of solvent components that have undergone the fourth refinement step to 65 mass % or more relative to the total amount of nonaqueous organic solvents to be mixed with the silylation reagent and the acid or base.

Additionally, it is preferable that a discharge step where at least one selected from the nonaqueous organic solvent of after the fourth refinement step and a treatment liquid obtained after the fifth refinement step is brought into contact with an electrically conductive material is involved. By virtue of the discharge step, the charged electric potential of the nonaqueous organic solvent, the treatment liquid (A) or the treatment liquid (B) which is under a charged condition can be reduced to the range as discussed above in the measure of management of the charged electric potential. With this, it becomes possible to safely prepare the treatment liquid (A) and the treatment liquid (B) while obtaining a treatment liquid (A) and a treatment liquid (B) which are under a safer condition, i.e.; a condition lower in risk of ignition.

Additionally, the present invention is a method for preparing a liquid chemical kit for forming a water-repellant protective film, the liquid chemical kit being for forming a water-repellent protective film at least on surfaces of recessed portions of an uneven pattern of a wafer having the uneven pattern at its surface, the liquid chemical kit having a treatment liquid (A) that contains a nonaqueous organic solvent and a silylation reagent and a treatment liquid (B) that contains a nonaqueous organic solvent and an acid or base, the method being characterized by comprising:

a step of preparing a treatment liquid (A mixing a nonaqueous organic solvent and a silylation reagent;

a step of preparing a treatment liquid (B) by mixing a nonaqueous organic solvent and an acid or base; and

a sixth refinement step for eliminating the elements (metal impurities) Na, Mg, K, Ca, Mn, Fe, Cu, Li, Al, Cr, Ni, Zn and Ag and particles in the treatment liquid (A) of after the step of preparing the treatment liquid (A) and/or the treatment liquid (B) of after the step of preparing the treatment liquid (B), by using a particle-eliminating membrane and an ion exchange resin membrane. Hereinafter, the above-mentioned preparation method will be referred to as “a fourth preparation method of the present invention”. A flowchart of the fourth preparation method is shown in FIG. 4.

Hereinafter, the fourth preparation method will be discussed.

In the fourth preparation method, it is preferable that a discharge step where the treatment liquid (A) and/or the treatment liquid (B) obtained after the sixth refinement step is brought into contact with an electrically conductive material. By virtue of the discharge step, the charged electric potential of the treatment liquid (A) or the treatment liquid (B) which is under a charged condition can be reduced to the range as discussed above in the measure of management of the charged electric potential. With this, it becomes possible to safely prepare the treatment liquid (A) and the treatment liquid (B) while Obtaining a treatment liquid (A) and a treatment liquid (B) which are under a safer condition, i.e., a condition lower in risk of ignition.

In the third and fourth preparation methods, the nonaqueous organic solvent preferably comprises at least one selected from the group consisting of hydrocarbons, esters, ethers, ketones, halogen-containing solvents, sulfoxide-based solvents, lactone-based solvents, carbonate-based solvents, polyalcohol derivatives having no OH group, and nitrogen element-containing solvents having no N—H group.

In the third and fourth preparation methods, the silylation reagent preferably comprises at least one selected from the group consisting of silicon compounds represented by the following general formula [1].

(R¹)ₐSi(H)_{b}X¹_{4-a-b} [1]

[In the formula [1], R¹ mutually independently represents a monovalent organic group having a C₁-C₁₈ monovalent hydrocarbon group the hydrogen elements of which may partially or entirely be replaced with a fluorine element(s); X¹ mutually independently represents at least one selected from the group consisting of a monovalent functional group of which element to be bonded to a silicon element is nitrogen, a monovalent functional group of which element to be bonded to a silicon element is oxygen, a halogen, group, a nitrile group and —CO—NH—Si(CH₃)₃ group; “a” is an integer of from 1 to 3; “b” is an integer of from 0 to 2; and the total of “a” and “b” is 1 to 3.]

Moreover, the silylation reagent preferably comprises a silicon compound represented by the following general formula [14].

R¹⁹ᵢSiX¹⁰₄₋ᵢ [4]

[In the formula [14], R¹⁹ mutually independently represents at least one group selected from a hydrogen group and a C₁-C₁₈ is monovalent hydrocarbon group the hydrogen elements of which may partially or entirely be replaced with a fluorine element(s), wherein the total number of carbons contained in all of the hydrocarbon groups bonded to a silicon element is not smaller than 6; X¹⁰ mutually independently represents at least one group selected from a monovalent functional group of which element to be bonded to a silicon element is nitrogen, a monovalent functional group of which element to be bonded to a silicon element is oxygen, a halogen group, a nitrile group and —CO—NH—Si(CH₃)₃ group; “i” is an integer of from 1 to 3.]

The acid preferably comprises at least one selected from the group consisting of hydrogen chloride, sulfuric acid, perchloric acid, phosphoric acid, sulfonic acid represented by the following general formula [2] and anhydride thereof, carboxylic acid represented by the following general formula [3] and anhydride thereof, alkyl borate ester, aryl borate ester, boron tris(trifluoroacetate), trialkoxyboroxin, boron trifluoride and a silane compound represented by the following general formula [4].

R²S(O)₂OH [2]

[In the formula [2], R² represents a C₁-C₁₈ monovalent hydrocarbon group the hydrogen elements of which may partially or entirely be replaced with a fluorine element(s).]

R³COOH [3]

[In the formula [3], R³ represents a C₁-C₁₈ monovalent hydrocarbon group the hydrogen elements of which may partially or entirely be replaced with a fluorine element(s).]

(R⁴)_{c}Si(H)_{d}X²_{4-c-d} [4]

[In the formula [4], R⁴ mutually independently represents a C₁-C₁₈ monovalent hydrocarbon group the hydrogen elements of which may partially- or entirely be replaced with a fluorine element(s); X² mutually independently represents at least one selected from the group consisting of chloro group, —OCO—R⁵ (where R⁵ is a C₁-C₁₈ monovalent hydrocarbon group the hydrogen elements of which may partially or entirely be replaced with a fluorine element(s)) and —OS(O)₂—R⁶ (where R⁶ is a C₁-C₁₈ is monovalent hydrocarbon group the hydrogen elements of which may partially or entirely be replaced with a fluorine element(s)); “c” is an integer of from 1 to 3; “d” is an integer of from 0 to 2; and the total of “c” and “d” is 1 to 3.]

The base preferably comprises at least one selected from the group consisting of ammonia, N,N,N′,N′ tetramethylethylenediamine, triethylenediamine, dimethylaniline, alkylamine, dialkylamine, trialkylamine, pyridine, piperazine, N-alkylmorpholine and a silane compound represented by the following general formula [5].

(R⁷)ₑSi(H)_{f}X³_{4-e-f} [5]

[In the formula [5], R⁷ mutually independently represents a C₁-C₁₈ monovalent hydrocarbon group the hydrogen elements of which may partially or entirely be replaced with a fluorine element(s); X³ mutually independently represents a monovalent functional group of which element to be bonded to a silicon element is nitrogen, the monovalent functional group possibly containing a fluorine element or a silicon element; “e” is an integer of from 1 to 3; “f” is an integer of from 0 to 2; and the total of “e” and “f” is 1 to 3.]

Furthermore, the present invention is a liquid chemical kit for forming a water-repellant protective film, prepared through the steps of the method for preparing a liquid chemical kit for forming a water-repellant protective film, as discussed in any of the above.

### Effects of the Invention

By the method for preparing a liquid chemical for forming a water-repellant protective film according to the present invention, it becomes possible to obtain a liquid chemical for forming a water-repellant protective film which liquid chemical is for forming a water-repellent protective film at least on surfaces of recessed portions of an uneven pattern of a wafer having the uneven pattern, at its surface, in such a condition that the concentration of the elements Na, Mg, K, Ca, Mn, Fe, Cu, Li, Al, Cr, Ni, Zn and Ag and the amount of particles contained in the liquid chemical are reduced. Moreover, by the method for preparing a liquid chemical kit for forming a water-repellant protective film according to the present invention, it becomes possible to obtain a liquid chemical kit for forming a water-repellant protective film which liquid chemical kit can provide the above-mentioned liquid chemical by mixture, in such a condition that the concentration of the elements Na, Mg, K, Ca, Mn, Fe, Cu, Li, Al, Cr, Ni, Zn and Ag and the amount of particles contained in the liquid chemical kit are reduced.

### BRIEF DESCRIPTION OF THE DRAWINGS

FIG. 1 A flowchart of a first preparation method.

FIG. 2 A flowchart of a second preparation method.

FIG. 3 A flowchart of a third preparation method.

FIG. 4 A flowchart of a fourth preparation method.

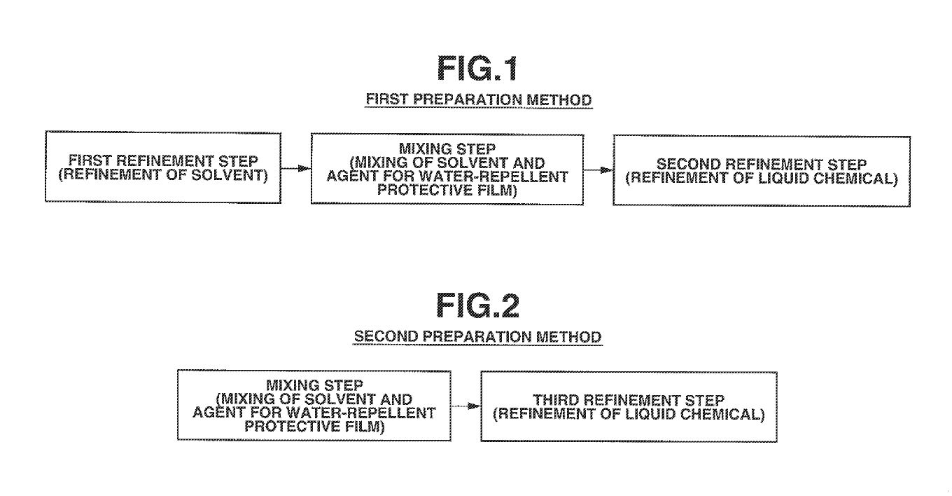

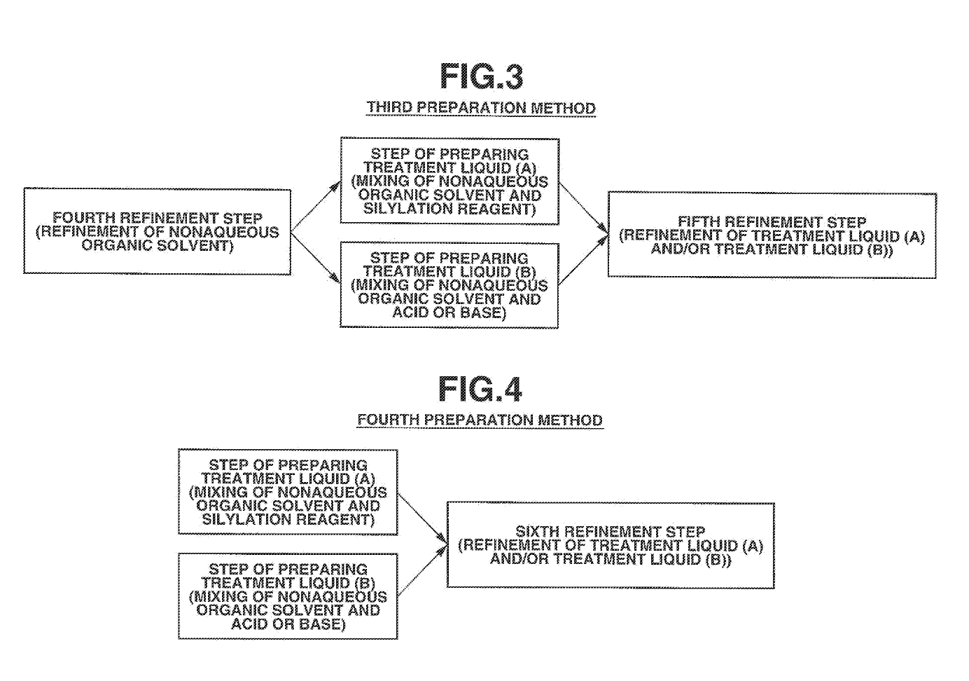

### MODE(S) FOR CARRYING OUT THE INVENTION

In a first refinement step of a first preparation method or a forth refinement step of a third preparation method according to the present invention, distillation of a solvent or nonaqueous organic solvent is sometimes carried out in order to eliminate metal impurities contained in the solvent or nonaqueous organic solvent. For example, it is possible to cite a distillation of a solvent or nonaqueous organic solvent not having hydrolizability and not subject to degeneration by heat, under reduced pressure or atmospheric pressure. If a liquid chemical for forming a water-repellent protective film is prepared by using a solvent obtained by distilling a solvent or nonaqueous organic solvent having hydrolizability or a solvent or nonaqueous organic solvent subject to degeneration by heat, the liquid chemical sometimes cannot impart sufficient water-repellency to a wafer surface, which is not favorable for the formation of a protective film.

In the first refinement step of the first preparation method or the forth refinement step of the third preparation method according to the present invention, elimination of metal impurities by using a particle-eliminating membrane and an ion exchange resin membrane is sometimes carried out in order to eliminate metal impurities contained in the solvent or nonaqueous organic solvent. For example, elimination of metal impurities is performed by: permeating the solvent or nonaqueous organic solvent through a particle-eliminating membrane formed of a membrane material such as a high-density polyethylene membrane, a high-density polypropylene membrane, a tetrafluoroethylene membrane, a membrane of copolymer of tetrafluoroethylene and perfluoroalkylvinylether and a membrane of nylon-6,6 and having a particle-eliminating diameter of 0.005-10 μm or through an ion exchange resin membrane such as a strongly acidic cation exchange obtained by chemically modifying a high-density polyethylene membrane by a cation exchange group e.g. a sulfo group; or permeating the solvent or nonaqueous organic solvent through an ion exchange resin membrane with particle-eliminating membrane in which an ion exchange resin membrane and a particle-eliminating membrane are integrally formed by chemically introducing a strongly acidic cation exchange resin onto surfaces of pores of a porous high-density polyethylene media. Concrete examples of the particle-eliminating membrane include Optimizer produced by Nihon Entegris K.K., NanoSHIELD produced by Sumitomo 3M Limited, Fluoroline produced by Nihon Entegris K.K., Ultipleat P-Nylon produced by Pall Corporation, etc. Concrete examples of the ion exchange resin membrane include IonKleen SL produced by Pall Corporation, IonKleen AQ produced by Pall Corporation, etc. Concrete examples of the ion exchange resin membrane with particle-eliminating membrane include Protego Plus produced by Nihon Entegris K.K., etc. A system of permeation may be the so-called one-pass system where the solvent or nonaqueous organic solvent is permeated through the membrane one time, or may be a system of circulating the solvent or nonaqueous organic solvent to be permeated through the membrane two or more times. Additionally, each of the above-mentioned membranes may be of only one stage type or of a multistage type.

In a third refinement step of a second preparation method or a sixth refinement step of a fourth preparation method according to the present invention, a method for eliminating metal impurities and particles contained in a liquid chemical or in a treatment liquid is exemplified by permeation of the liquid chemical or the treatment liquid through the particle-eliminating membrane and the ion exchange resin membrane as discussed above. For permeation, a system of circulating the solvent or nonaqueous organic solvent to be permeated through the membrane two or more times is preferable. Additionally, each of the above-mentioned membranes may be of only one stage type or of a multistage type. In a second refinement step of the first preparation method or a fifth refinement step of the third preparation method according to the present invention, it is possible to use the particle-eliminating membrane alone or to use the particle-eliminating membrane and the ion exchange resin membrane.

It is preferable that the particle-eliminating membrane and the ion exchange resin membrane used in the present invention have a larger surface area. Since metal impurities and particles not dissolved in the liquid chemical are adsorbed and trapped on the particle-eliminating membrane, a particle-eliminating membrane having a larger surface area tends to more lower the load applied on the membrane at the time of refinement. Moreover, since metal impurities dissolved in the liquid chemical are adsorbed and trapped on the ion exchange resin membrane by being brought into contact with ion exchange groups that exist in the ion exchange resin membrane, the metal impurities becomes more readily adsorbed if a time for intercepting the liquid to be permeated in the membrane becomes longer. Furthermore, an on exchange resin membrane having a larger surface area can intercept the liquid in the membrane for a longer time and therefore tends to have a better effect on the elimination of metal impurities. In the first preparation method of the present invention, it is preferable that the surface area of the particle-eliminating membrane and the ion exchange resin membrane used in the second refinement step is larger than the surface area of the particle-eliminating membrane and the ion exchange resin membrane used in the first refinement step because the metal impurity concentration in the obtained liquid chemical can be readily adjusted to be smaller. Likewise, it is preferable in the third preparation method that the surface area of the particle-eliminating membrane and the ion exchange resin membrane used in the fifth refinement step is larger than the surface area of the particle-eliminating membrane and the ion exchange resin membrane used in the fourth refinement step.

In the first refinement step of the first preparation method, metal impurities are previously removed from a neutral solvent. In this refinement step, the target for refinement is a neutral solvent only therefore, the degree of dissociation of metal impurities is so high as to be able to reduce the metal impurity concentration in the solvent sufficiently only by one-pass filtration. Additionally, the solvent is formed containing a neutral solvent only and therefore the metal impurity concentration in the solvent may sufficiently be reduced by distillation. In a subsequent refinement step (the second refinement step), metal impurities have previously been removed from the solvent because of having already undergone the first refinement step, so that the content of metal impurities and particles in the liquid chemical may sufficiently be reduced only by one-pass filtration. On the contrary, in the third refinement step of the second preparation method, if the obtained liquid chemical is acidic or basic, the degree of dissociation of metal impurities is so low. Since the metal impurities and particles are eliminated from a liquid chemical of after the mixing step, the metal impurity concentration in the liquid chemical may not be sufficiently reduced by one-pass filtration. In this case, it is necessary to carry out refinement by a system of conducting one-pass filtration at multistage to permeate the liquid chemical through the membrane two or more times or by a system of circulating the liquid chemical to permeate it through the membrane two or more times. In order to shorten the refinement time, therefore, it is required to increase the membrane area of the particle-eliminating membrane and the ion exchange resin membrane to increase the permeation amount of the liquid chemical. In view of facilities and efficiency thus required, the first preparation method is preferable to the second preparation method.

In the fourth refinement step of the third preparation method, metal impurities are previously removed from a neutral nonaqueous organic solvent. In this refinement step, the target for refinement is a neutral nonaqueous organic solvent only; therefore, the degree of dissociation of metal impurities is so high as to be able to reduce the metal impurity concentration in the nonaqueous organic solvent sufficiently only by one-pass filtration. Additionally, the nonaqueous organic solvent is formed containing a neutral nonaqueous organic solvent only and therefore the metal impurity concentration in the nonaqueous organic solvent may sufficiently be reduced by distillation. In a subsequent refinement step the fifth refinement step), metal impurities have previously been removed from the nonaqueous organic solvent because of having already undergone the fourth refinement step, so that refinement is efficiently performed and the content of metal impurities and particles in the treatment liquid may sufficiently be reduced only by one-pass filtration. On the contrary, in the sixth refinement step of the fourth preparation method, if the obtained treatment liquid is acidic or basic, the degree of dissociation of metal impurities is so low. Since the metal impurities and particles are eliminated from a treatment liquid of after the step of preparing the treatment liquid, the metal impurity concentration in the treatment liquid may not be sufficiently reduced by one-pass filtration. In this case, it is necessary to carry out refinement by a system of conducting one-pass filtration at multistage to permeate the treatment liquid through the membrane two or more times or by a system of circulating the treatment liquid to permeate it through the membrane two or more times. In order to shorten the refinement time, therefore, it is required to increase the membrane area of the particle-eliminating membrane and the ion exchange resin membrane to increase the permeation amount of the treatment liquid. In view of facilities and efficiency thus required, the third preparation method is preferable to the fourth preparation method.

A liquid chemical for forming a water-repellent protective film, obtained according to a first embodiment of the present invention can form a water-repellent protective film on surfaces of recessed portions of a wafer having the uneven pattern at its surface and containing silicon element at least at the surfaces of the recessed portions (hereinafter, such a wafer may be referred to as “a silicon element-containing wafer”). Examples of the above-mentioned wafer include: a wafer the surface of which is formed with a film containing a silicon element such as silicon, silicon oxide and silicon nitride; and a wafer formed with an uneven pattern and contains a silicon element such as silicon, silicon oxide and silicon nitride at least at a part of the surface of the uneven pattern. Additionally the liquid chemical can form a protective film also against a wafer consisting of two or more components including at least a silicon element on the surface of the component including a silicon element. Examples of the above-mentioned wafer that consists of two or more components include: a wafer the surface of which is formed of a component containing a silicon element such as silicon, silicon oxide and silicon nitride; and a wafer formed with an uneven pattern and wherein at least a part of the uneven pattern is formed of a component containing a silicon element such as silicon, silicon oxide and silicon nitride. Incidentally, where the protective film can be formed by the liquid chemical is on the unevenly patterned surface that corresponds to a part containing a silicon element.

The formation of the protective film on the surfaces of the recessed portions of the silicon element-containing wafer is achieved such that a reactive moiety of a silylation reagent contained in the liquid chemical prepared according to the first embodiment causes reaction with a silanol group that serves as a reaction site of the silicon element-containing wafer, i.e., such that the silylation reagent is chemically bonded to a silicon element of the silicon element-containing wafer through a siloxane bond. The reaction moiety is a group represented by X¹ in general formula [1].

The monovalent functional group of which element to be bonded to silicon element is nitrogen, which is one example of X¹ of the general formula [1], may include not only hydrogen element, carbon element, nitrogen element and oxygen element but also silicon element, sulfur element and halogen element and the like. Examples of the functional group are an isocyanate group, amino group, dialkylamino group, isothiocyanate group, azide group, acetamide group, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring (the following formula [15]), oxazolidinone ring (the following formula [16]), morpholine ring (the following formula [17]), —NH—C(O)—Si(CH₃)₃, —N(H)₂₋ⱼ(Si(H)ₖR²⁰₃₋ₖ)^{j} (where R²⁰ is a C₁-C₁₈ monovalent hydrocarbon group the hydrogen elements of which may partially or entirely be replaced with a fluorine element(s), “j” is an integer of 1 or 2, and “k” is an integer of from 0 to 2) and the like.

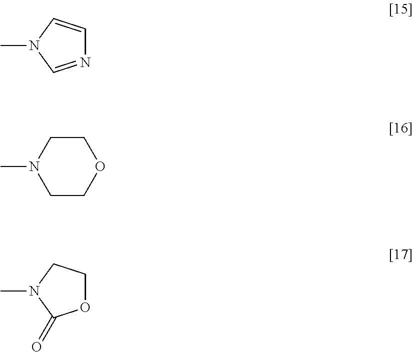

The monovalent functional group of which element to be bonded to silicon, element is oxygen, which is one example of X¹ of the general formula [1], may include not only hydrogen element, carbon element, nitrogen element and oxygen element but also silicon element, sulfur element and halogen element and the like. Examples of the organic group are an alkoxy group, —OC(CH₃)═CHCOCH₃, —OC(CH₃)═N—Si(CH₃)₃, —OC(CF₃)═N—Si(CH₃)₃, —O—CO—R²¹ (where R²¹ is a C₁-C₁₈ monovalent hydrocarbon group the hydrogen elements of which may partially or entirely be replaced with a fluorine element(s)) and an alkyl sulfonate group the hydrogen elements of which may partially or entirely be replaced with a fluorine element(s) and the like.

Additionally, a halogen group, which is one example of X¹ of the general formula [1], is exemplified by a chloro group, bromo group, iodo group and the like.

In addition, R¹ of the general formula [1] serves as a hydrophobic moiety which decreases a surface energy of an article to reduce the interaction caused between water or another liquid and the article surface (i.e., at the interface), such as hydrogen bond, intermolecular forces and the like. The effect of reducing the interaction is particularly exhibited with water, but the effect of reducing the interaction is exhibited also with a mixture liquid of water and a liquid other than water or with a liquid other than water. With this, the contact angle of the liquid to the article surface can be increased.

Examples of the silylation reagent represented by the general formula [1] are: alkylmethoxysilanes such as CH₃Si(OCH₃)₃, C₂H₅Si(OCH₃)₃, C₃H₇Si(OCH₃)₃, C₄H₉Si(OCH₃)₃, C₅H₁₁Si(OCH₃)₃, C₆H₁₃Si(OCH₃)₃, C₁₅H₃₁Si(OCH₃)₃, C₁₆H₃₃Si(OCH₃)₃, C₁₇H₃₅Si(OCH₃)₃, C₁₈H₃₇Si(OCH₃)₃, (CH₃)₂Si(OCH₃)₂, C₂H₅Si(CH₃)(OCH₃)₂, (C₂H₅)₂Si(OCH₃)₂, C₃H₇Si(CH₃)(OCH₃)₂, (C₃H₇)₂Si(OCH₃)₂, C₄H₉Si(CH₃)(OCH₃)₂, (C₄H₉)₂Si(OCH₃)₂, C₅H₁₁Si(CH₃)(OCH₃)₂, C₆H₁₃Si(CH₃)(OCH₃)₂, C₇H₁₅Si(CH₃)(OCH₃)₂, C₈H₁₇Si(CH₃)(OCH₃)₂, C₉H₁₉Si(CH₃)(OCH₃)₂, C₁₀H₂₁Si(CH₃)(OCH₃)₂, C₁₁H₂₃Si(CH₃)(OCH₃)₂, C₁₂H₂₅Si(CH₃)(OCH₃)₂, C₁₃H₂₇Si(CH₃)(OCH₃)₂, C₁₄H₂₉Si(CH₃)(OCH₃)₂, C₁₅H₃₁Si(CH₃)(OCH₃)₂, C₁₆H₃₃Si(CH₃)(OCH₃)₂, C₁₇H₃₅Si(CH₃)(OCH₃)₂, C₁₈H₃₇Si(CH₃)(OCH₃)₂, (CH₃)₃SiOCH₃, C₂H₅Si(CH₃)₂OCH₃, (C₂H₅)₂Si(CH₃)OCH₃, (C₂H₅)₃SiOCH₃, C₃H₇Si(CH₃)₂OCH₃, (C₃H₇)₂(CH₃)OCH₃, (C₃H₇)₃SiOCH₃, C₄H₉Si(CH₃)₂OCH₃, (C₄H₉)₃SiOCH₃, C₅H₁₁Si(CH₃)₂OCH₃, C₆H₁₃Si(CH₃)₂OCH₃, C₇H₁₅Si(CH₃)₂OCH₃, C₈H₁₇Si(CH₃)₂OCH₃, C₉H₁₉Si(CH₃)₂OCH₃, C₁₀H₂₁Si(CH₃)₂OCH₃, C₁₁H₂₃Si(CH₃)₂OCH₃, C₁₂H₂₅Si(CH₃)₂OCH₃, C₁₃H₂₇Si(CH₃)₂OCH₃, C₁₄H₂₉Si(CH₃)₂OCH₃, C₁₅H₃₁Si(CH₃)₂OCH₃, C₁₆H₃₃Si(CF₃)₂OCH₃, C₁₇H₃₅Si(CH₃)₂OCH₃, C₁₈H₃₇Si(CH₃)₂OCH₃, (CH₃)₂Si(H)OCH₃, CH₃Si(H)₂OCH₃, (C₂H₅)₂Si(H)OCH₃, C₂H₅Si(H)₂OCH₃, C₂H₅Si(CH₃)(H)OCH₃, (C₃H₇)₂Si(H)OCH₃ and the like; fluoroalkylmethoxysilanes such as CF₃CH₂CH₂Si(OCH₃)₃, C₂F₅CH₂CH₂Si(OCH₃)₃, C₃F₇CH₂CH₂Si(OCH₃)₃, C₄F₉CH₂C₂H₂Si(OCH₃)₃, C₅F₁₁CH₂CH₂Si(OCH₃)₃, C₆F₁₃CH₂CH₂Si(OCH₃)₃, C₇F₁₅CH₂CH₂Si(OCH₃)₃, C₈F₁₇CH₂CH₂Si(OCH₃)₃, CF₃CH₂, CH₂, Si(CH₃)(OCH₃)₂, C₂F₅CH₂CH₂Si(CH₃)(OCH₃)₂, C₃F₇CH₂CH₂Si(CH₃)(OCH₃)₂, C₄F₉CH₂CH₂Si(CH₃)(OCH₃)₂, C₅H₁₁CH₂CH₂Si(CH₃)(OCH₃)₂, C₆F₁₃CH₂CH₂Si(CH₃)(OCH₃)₂, C₇F₁₅CH₂CH₂Si(CH₃)(OCH₃)₂, C₈F₁₇CH₂CH₂Si(CH₃)(OCH₃)₂, CF₃CH₂CH₂Si(CH₃)₂OCH₃, C₂F₅CH₂CH₂Si(CH₃)₂OCH₃, C₃F₇CH₂CH₂Si(CH₃)₂OCH₃, C₄F₉CH₂CH₂(CH₃)₂OCH₃, C₅F₁₁CH₂CH₂Si(CH₃)₂OCH₃, C₆F₁₃CH₂CH₂Si(CH₃)₂OCH₃, C₇F₁₅CH₂CH₂Si(CH₃)₂OCH₃, C₈F₁₇CH₂CH₂Si(CH₃)₂OCH₃, CF₃CH₃CH₂Si(CH₃)(H)OCH₃ and the like; alkoxysilane compounds obtained by substituting a methyl group moiety of methoxy group of the above-mentioned alkylmethoxysilanes or fluoroalkylmethoxysilanes with a C₂-C₁₈ monovalent hydrocarbon group; and compounds obtained by substituting the methoxy group with —OC(CH₃)═CHCOCH₃, —OC(CH₃)═N—Si(CH₃)₃, —OC(CH₃)═N—Si(CH₃)₃, —O—CO—R²¹ (where R²¹ is a C₁-C₁₈ monovalent hydrocarbon group the hydrogen elements of which may partially or entirely be replaced with a fluorine element(s)), an alkyl sulfonate group the hydrogen elements of which may partially or entirely be replaced with a fluorine element(s), isocyanate group, amino group, dialkylamino group, isothiocyanate group, azide group, acetamide group, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, —NHC(O)—NH—Si(CH₃)₃, imidazole ring, oxazolidinone ring, morpholine ring, —NH—C(O)—Si(CH₃)₃, —(H)₂₋ⱼ(Si(H)ₖR²⁰₃₋ₖ)ⱼ (where R²⁰ is a C₁-C₁₈ monovalent hydrocarbon group the hydrogen elements of which may partially or entirely be replaced with a fluorine element(s), “j” is an integer of 1 or 2, and “k” is an integer of from 0 to 2), chloro group, bromo group, iodo group, nitrile group or —CO—NH—Si(CH₃)₃.

The number of X¹ the silylation reagent, which is represented by “4-a-b” in the general formula [1], is preferably 1 because the protective film can uniformly be formed thereby.

It is preferable that R¹ in the general formula [1] mutually independently represents at least one group selected from C₁-C₁₈ monovalent hydrocarbon groups the hydrogen elements of which may partially or entirely be replaced with a fluorine element(s) and more preferably at least one group selected from CₘH₂ₘ₊₁ (“m”=1-18) and CₙF₂ₙ₊₁CH₂CH₂ (“n”=1-8) because the wettability of the surface of the silicon element-containing wafer can be more reduced when the protective film is formed thereon, i.e., because a more excellent water-repellency can be imparted to the surface. Additionally, it is preferable that “m” is 1 to 12 and “n” is 1 to 8 because the protective film can be formed on the surface of the silicon element-containing wafer in a short time.

Furthermore, it is preferable that the acid is at least one selected from the group consisting of hydrogen chloride, sulfuric acid, perchloric acid, phosphoric acid, sulfonic acid represented by the general formula [2] and anhydride thereof, carboxylic acid represented by the general formula [3] and anhydride thereof, alkyl borate ester, aryl borate ester, boron tris(trifluoroacetate), trialkoxyboroxin, boron trifluoride and a silicon compound represented by the general formula [4].

Sulfonic acid represented by the general formula [2] and anhydride thereof are exemplified by methansulfonic acid, benzenesulfonic acid, p-toluenesulfonic acid, trifluoromethanesulfonic acid, trifluoromethanesulfonic anhydride and the like. Carboxylic acid represented by the general formula [3] and anhydride thereof are exemplified by acetic acid, trifluoroacetic acid, pentafluoropropionic acid, acetic anhydride, trifluoroacetic anhydride, pentafluoropropionic anhydride and the like. The silicon compound represented by the general formula [4] is preferably a chlorosilane, alkyl silyl alkyl sulfonate or alkyl silyl ester, and exemplified by trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl, trifluoroacetate, decyldimethylsilyl trifluoromethanesulfonate, dodecyldimethylsilyl trifluoroacetate, dodecyldimethylsilyl trifluoromethanesulfonate and the like.

Furthermore, it is preferable that the base is at least one selected from the group consisting of ammonia, N,N,N′,N′-tetramethylethylenediamine, triethylenediamine, dimethylaniline, alkylamine, dialkylamine, trialkylamine, pyridine, piperazine, N-alkylmorpholine and a silane compound represented by the general formula [5].

By virtue of the acid or base contained in the liquid chemical, the reaction between the silylation reagent and a silanol group serving as a reaction site of the surface of the silicon element-containing wafer is accelerated, so that it becomes possible to impart an excellent water-repellency to the surface of the silicon element-containing wafer by conducting a surface treatment in the use of the liquid chemical. Incidentally, the acid or base may constitute a part of the protective film.

With consideration given to a reaction-accelerating effect, it is preferable that the liquid chemical contains acid. Particularly, the acid is preferably; a strong acid (Brönsted acid) such as hydrogen chloride, sulfuric acid, perchloric acid and the like; an alkane sulfonic acid the hydrogen elements of which are partially or entirely replaced with a fluorine element(s) or acid anhydride thereof, such as trifluoromethanesulfonic acid, trifluoromethanesulfonic anhydride and the like; carboxylic acid the hydrogen elements of which are partially or entirely replaced with a fluorine element(s) or acid anhydride thereof, such as trifluoroacetic acid, trifluoroacetic anhydride, pentafluoropropionic acid and the like; chlorosilane; alkyl silyl alkyl sulfonate the hydrogen elements of which are partially or entirely replaced with a fluorine element(s); or alkyl silyl ester the hydrogen elements of which are partially or entirely replaced with a fluorine element(s). Incidentally, alkyl silyl ester is formed such that an alkyl group and —O—CO—R′ group (where is an alkyl group) are bonded to a silicon element. Moreover, the acid contained in the liquid chemical may be formed by a reaction; for example, it is acceptable to cause a reaction between an alkylchlorosilane and an alcohol to produce a liquid chemical containing the formed alkylalkoxysilane as a silylation reagent, the formed hydrochloric acid as the acid, and an alcohol not consumed by the reaction as a solvent. In this case, a step that ranges from mixing of alkylchlorosilane and alcohol to the acquirement of the liquid chemical is referred to as “a mixing step”.

As the solvent used in the first embodiment, there are preferably cited; hydrocarbons such as toluene, benzene, xylene, hexane, heptane, octane and the like; esters such as ethyl acetate, propyl acetate, butyl acetate, ethyl acetoacetate and the like; ethers such as diethyl ether, dipropyl ether, dibutyl ether, tetrahydrofuran, dioxane and the like; ketones such as acetone, acetylacetone, methyl ethyl ketone, methyl propyl ketone, methyl butyl ketone, cyclohexanone, isophorone and the like; halogen-containing solvents including perfluorocarbons such as perfluorooctane, perfluorononane, perfluorocyclopentane, perfluorocyclohexane, hexafluorobenzene and the like, hydrofluorocarbons such as 1,1,1,3,3-pentafluorobutane, octafluorocyclopentane, 2,3-dihydrodecafluoropentane, ZEORORA-H (produced by ZEON CORPORATION) and the like, hydrofluoroethers such as methyl perfluoroisobutyl ether, methyl perfluorobutyl ether, ethyl perfluorobutyl ether, ethyl perfluoroisobutyl ether, ASAHIKLIN AE-3000 (produced by Asahi Glass Co., Ltd.), Novec 7100, Novec 7200, Novec 7300, Novec 7600 (any of these are produced by 3M Limited) and the like, chlorocarbons such as tetrachloromethane and the like, hydrochlorocarbons such as chloroform and the like, chlorofluorocarbons such as dichlorodifluoromethane and the like, hydrochlorofluorocarbons such as 1,1-dichloro-2,2,3,3,3-pentafluoropropane, 1,3-dichloro-1,1,2,2,3-pentafluoropropane, 1-chloro-3,3,3-trifluoropropene, 1,2-dichloro-3,3,3-trifluoropropene and the like, perfluoroethers, perfluoropolyethers and the like; sulfoxide-based solvents such as dimethyl sulfoxide and the like; lactone-based solvents such as γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone and the like; carbonate-based solvents such as dimethyl carbonate, ethyl methyl carbonate, diethyl carbonate, propylene carbonate and the like; polyalcohol derivatives having no OH group, such as ethylene glycol dimethyl ether, ethylene glycol diethyl ether, ethylene glycol dibutyl ether, ethylene glycol monomethyl ether acetate, ethylene glycol monoethyl ether acetate, ethylene glycol monobutyl ether acetate, ethylene glycol diacetate, diethylene glycol dimethyl ether, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol dimethyl ether, propylene glycol diethyl ether, propylene glycol dibutyl ether, propylene glycol monomethyl ether acetate, propylene glycol monoethyl ether acetate, propylene glycol monobutyl ether acetate, propylene glycol diacetate, dipropylene glycol dimethyl ether, dipropylene glycol methyl propyl ether, dipropylene glycol diethyl ether, dipropylene glycol dibutyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol dimethyl ether, butylene glycol monomethyl ether acetate, butylene glycol diacetate, glycerine triacetate and the like; and nitrogen element-containing solvents having no N—H group, such as N,N-dimethylformamide, N,N-dimethylacetamide, N-methyl-2-pyrrolidone, diethylamine, triethylamine, pyridine and the like.

Additionally it is preferable to use a nonflammable solvent as a part or the entire of the solvent since the liquid chemical for forming a protective film becomes nonflammable or increases in flash point thereby reducing the risk of the liquid chemical. Most of the halogen-containing solvents are nonflammable, and such a halogen-containing nonflammable solvent can preferably be used as a nonflammable solvent.

Additionally, it is preferable, in view of safety under the fire protection law, to use a solvent having a flash point exceeding 70° C. as the solvent.

According to “Globally Harmonized System of Classification and Labelling of Chemicals; GHS”, a solvent having a flash, point of not higher than 93° C. is defined as “a flammable liquid”. Therefore, when a solvent having a flash point exceeding 93° C. is used as the solvent, the liquid chemical for forming a protective film tends to have a flash point exceeding 93° C. even if the solvent is not nonflammable one. Hence the liquid chemical hardly corresponds to “a flammable liquid” and therefore further preferable in view of safety.

Most of the lactone-based solvents, the carbonate-based solvents and the polyalcohol derivatives having no OH group have high flash point so as to be preferably used because the risk of the liquid chemical for forming a protective film can be lowered. In view of the safety, a solvent having a flash point exceeding 70° C. is more preferably used as the solvent, which is concretely exemplified by γ-butyrolactone, γ-valerolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone, propylene carbonate, ethylene glycol dibutyl ether, ethylene glycol monobutyl ether acetate, ethylene glycol diacetate, diethylene glycol ethyl methyl ether, diethylene glycol diethyl ether, diethylene glycol butyl methyl ether, diethylene glycol dibutyl ether, diethylene glycol monomethyl ether acetate, diethylene glycol monoethyl ether acetate, diethylene glycol monobutyl ether acetate, diethylene glycol diacetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol diacetate, dipropylene glycol methyl propyl ether, dipropylene glycol monomethyl ether acetate, dipropylene glycol monoethyl ether acetate, dipropylene glycol monobutyl ether acetate, dipropylene glycol diacetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol diacetate, glycerine triacetate and the like. It is further preferable to use a solvent having a flash point exceeding 93° C. as the solvent, which is concretely exemplified by γ-butyrolactone, γ-hexanolactone, γ-heptanolactone, γ-octanolactone, γ-nonanolactone, γ-decanolactone, γ-undecanolactone, γ-dodecanolactone, δ-valerolactone, δ-hexanolactone, δ-octanolactone, δ-nonanolactone, δ-decanolactone, δ-undecanolactone, δ-dodecanolactone, ε-hexanolactone, propylene carbonate, ethylene glycol diacetate, diethylene glycol butyl methyl ether, diethylene glycol dibutyl ether, diethylene glycol diacetate, diethylene glycol monomethyl ether acetate, diethylene glycol monoethyl ether acetate, diethylene glycol monobutyl ether acetate, triethylene glycol dimethyl ether, triethylene glycol diethyl ether, triethylene glycol dibutyl ether, triethylene glycol butyl methyl ether, triethylene glycol monomethyl ether acetate, triethylene glycol monoethyl ether acetate, triethylene glycol monobutyl ether acetate, triethylene glycol diacetate, tetraethylene glycol dimethyl ether, tetraethylene glycol diethyl ether, tetraethylene glycol dibutyl ether, tetraethylene glycol monomethyl ether acetate, tetraethylene glycol monoethyl ether acetate, tetraethylene glycol monobutyl ether acetate, tetraethylene glycol diacetate, propylene glycol diacetate, dipropylene glycol diacetate, dipropylene glycol monomethyl ether acetate, dipropylene glycol monoethyl ether acetate, dipropylene glycol monobutyl ether acetate, tripropylene glycol dimethyl ether, tripropylene glycol diethyl ether, tripropylene glycol dibutyl ether, tripropylene glycol monomethyl ether acetate, tripropylene glycol monoethyl ether acetate, tripropylene glycol monobutyl ether acetate, tripropylene glycol diacetate, tetrapropylene glycol dimethyl ether, tetrapropylene glycol monomethyl ether acetate, tetrapropylene glycol diacetate, butylene glycol diacetate, glycerine triacetate and the like.

Among the liquid chemicals prepared according to the first embodiment, it is preferable to use: one containing a mixture of 76 to 99.8999 mass % of at least one kind of solvent selected from the group consisting of hydrofluoroethers, hydrochlorofluorocarbons, polyalcohol derivatives having no OH group and lactone-based solvents, 0.1 to 20 mass % of at least one kind of silylation reagent selected from the group consisting of alkoxysilanes having CₓH₂ₓ₊₁ group (x=1-12) or C_{y}F_{2y+1}CH₂CH₂ group (y=1-8), trimethyldimethylaminosilane, trimethyldiethylaminosilane, butyldimethyl(dimethylamino)silane, butyldimethyl(diethylamino)silane, hexyldimethyl(dimethylamino)silane, hexyldimethyl(diethylamino)silane, octyldimethyl(dimethylamino)silane, octyldimethyl(diethylamino)silane, decyldimethyl(dimethylamino)silane, decyldimethyl(diethylamino)silane, dodecyldimethyl(dimethylamino)silane and dodecyldimethyl(diethylamino)silane and 0.0001 to 4 mass % of at least one kind of acid selected from the group consisting of trifluoroacetic acid, trifluoroacetic anhydride, trifluoromethanesulfonic acid, trifluoromethanesulfonic anhydride, trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl trifluoroacetate, decyldimethylsilyl trifluoromethanesulfonate, dodecyldimethylsilyl trifluoroacetate and dodecyldimethylsilyl trifluoromethanesulfonate, or one consisting only of the mixture.

It is also preferable to use: one containing a mixture of 76 to 99.8999 mass % of at least one kind of solvent selected from the group consisting of hydrofluoroethers, hydrochlorofluorocarbons and polyalcohol derivatives having no OH group, 0.1 to 20 mass % of at least one kind of silylation reagent selected from the group consisting of hexamethyl disilazane, tetramethyldisilazane, 1,3-dibutyltetramethyldisilazane, 1,3-dihexyltetramethyldisilazane, 1,3-dioctyltetramethyldisilazane, 1,3-didecyltetramethyldisilazane and 1,3-didodecyltetramethyldisilazane, and 0.0001 to 4 mass % of at least one kind of acid selected from the group consisting of trifluoroacetic acid, trifluoroacetic anhydride, trifluoromethanesulfonic acid, trifluoromethanesulfonic anhydride, trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifloromethanesulfonate, decyldimethylsilyl trifluoroacetate, decyldimethylsilyl trifluoromethanesulfonate, dodecyldimethylsilyl trifluoroacetate and dodecyldimethylsilyl trifluoromethanesulfonate; or one consisting only of the mixture.

A liquid chemical for forming a water-repellent protective film, obtained, according to a second embodiment of the present invention can form a water-repellent protective film on surfaces of recessed portions of an uneven pattern of a wafer having the uneven pattern at its surface and containing at least one kind of element among titanium, tungsten, aluminum, copper, tin, tantalum and ruthenium at least at the surfaces of the recessed portions (hereinafter, such a wafer may be referred, to as “a metallic element-containing wafer”). Hereinafter, the elements of titanium, tungsten, aluminum, copper, tin, tantalum and ruthenium may generically be referred to as “metallic element(s)”. Examples of the above-mentioned metallic element-containing wafer include a silicon wafer, a wafer formed of a plurality of components including silicon and/or silicon oxide (SiO₂), a silicon carbide wafer, a sapphire wafer, semiconductor wafers formed of various kinds of compounds, a plastic wafer or the like coated at these surfaces with a layer formed of a matter containing titanium element such as titanium, titanium nitride, titanium oxide and the like, a matter containing tungsten element such as tungsten, tungsten oxide and the like, a matter containing aluminum element such as aluminum and aluminum oxide and the like, a matter containing copper element such as copper and copper oxide and the like, a matter containing tin element such as tin and tin oxide and the like, a matter containing tantalum element such as tantalum nitride and tantalum oxide and the like or a matter containing ruthenium element such as ruthenium and ruthenium oxide and the like, and a wafer formed having a multilayer film at least one layer of which is a film formed of a matter containing the above-mentioned metallic element. The step of forming the uneven, pattern is conducted on a layer including a layer formed of a matter containing the above-mentioned metallic element. Additionally those in which at least a part of the surface of the uneven pattern serves as a matter containing at least one kind element of the above-mentioned metallic elements at the time of being formed with the uneven pattern are also included.

Also concerning a wafer formed of a plurality of components that include a matter containing at least one kind of the above-mentioned metallic elements, it is possible to form the protective film on the surface of the matter containing at least one kind of the above-mentioned metallic elements. The wafer formed of a plurality of components is exemplified by those in which the matter containing at least one kind of metallic element is formed at least at a part of the surfaces of the recessed portions and those in which at least a part of the surfaces of the recessed portions serves as the matter containing at least one kind of element of the above-mentioned metallic elements at the time of being formed with the uneven pattern. In the uneven pattern, where the liquid chemical obtained according to the second embodiment can form the protective film is on a surface of a moiety of the matter containing at least one kind of metallic element. Hence the protective film may be formed at least on a part of the surfaces of the recessed portions of the metallic element-containing wafer.

The formation of the water-repellent protective film on the surfaces of the recessed portions of the metallic element-containing wafer is accomplished in such a manner that a functional moiety (having compatibility with the matter containing the metallic element) of an agent for forming a protective film (which agent is contained in the liquid chemical obtained according to the second embodiment, and selected from compounds represented by the general formulas [6] to [13]) is physically adsorbed onto a surface of the matter containing the metallic element, and/or in such a manner that the functional moiety is reacted with the surface of the matter to form a chemical bond thereby causing chemical adsorption. Hereinafter, the above-mentioned “physical adsorption” and “chemical adsorption” may generically be referred to merely as “adsorption”. The above-mentioned functional moiety is: in the general formula [6], a group represented by P—OH and/or P═O; in the general formula [7], a group represented by —C(═O)—X⁴; in the general formula [8], a nitrogen element; in the general formula [9], a group represented by —C(═O)—X⁵—X⁶; in the general formula [10], a group represented by (X⁷)ₕ; in the general formula [11], a group represented by —X⁸; in the general formula [12], a group represented by ═C(═O)—X⁹—C(═O)—; and in the general formula [13], a group represented by P—OH and/or P═O. By the way “having compatibility” means that Van der Waals force, an electrostatic interaction and the like act between the surface of the matter containing the metallic element and the functional moiety of the agent for forming a protective film.

Additionally, R⁸ of the general formula [6], R^{10 of the general formula [}7], R¹¹ of the general formula [8], R¹⁴ of the general formula [9], R¹⁵ of the general formula [10], R¹⁶ of the general formula [11], R¹⁷ and R¹⁸ of the general formula [12] and R²⁴ of the general formula [13] are hydrophobic moieties that can reduce the surface energy of an article thereby decreasing the interaction between water or another liquid and the surface of the article (i.e., at the interface) such as hydrogen bond, intermolecular forces and the like. The effect of reducing the interaction is particularly exhibited against water, but it is also exhibited against a mixture liquid of water and a liquid other than water or against a liquid other than water. With this, the contact angle of the liquid to the article surface can be increased.

A hydrocarbon group contained in R⁹ of the general formula [6] is exemplified by an alkyl group, alkylene group, and those the hydrogen elements of which are partially or entirely replaced with a fluorine element(s). Additionally R⁹ is preferably —OR²² (where R²² is a C₁-C₃ hydrocarbon group). Moreover, it is preferable that R²² has a carbon number of 1, since a more excellent water-repellency is obtained thereby. It is further preferable that R²² is a straight-chained alkyl group.

A compound represented by the general formula is exemplified by CH₃P(O)(OH)₂, C₂H₅P(O)(OH)₂, C₃H₇P(O)(OH)₂, C₄H₉P(O)(OH)₂, C₅H₁₁P(O) (OH)₂, C₆H₁₃P(O)(OH)₂, C₇H₁₁P(O)(OH)₂, C₈H₁₇(O)(OH)₂, C₉H₁₉P(O)(OH)₂, C₁₀H₂₁P(O)(OH)₂, C₁₁H₂₃P(O)(OH)₂, C₁₂H₂₅P(O)(OH)₂, C₁₃H₂₇P(O)(OH)₂, C₁₄H₂₉P(O)(OH)₂, C₁₅H₃₁P(O)(OH)₂, C₁₆H₃₃P(O)(OH)₂, C₁₇H₃₅P(O)(OH)₂, C₁₈H₃₇P(O)(OH)₂, C₆H₅P(O)(OH)₂, CF₃P(O)(OH)₂, C₂F₅P(O)(OH)₂, C₃F₇P(O)(OH)₂, C₄F₉P(O)(OH)₂, C₅F₁₁P(O)(OH)₂, C₆F₁₃P(O)(OH)₂, C₇F₁₅P(O)(OH)₂, C₈F₁₇P(O)(OH)₂, CF₃C₂H₄P(O)(OH)₂, C₂F₅C₂H₄P(O)(OH)₂, C₃F₇C₂H₄P(O)(OH)₂, C₄F₉C₂H₄P(O)(OH)₂, C₅F₁₁C₂H₄P(O)(OH)₂, C₆F₁₃C₂H₄P(O)(OH)₂, C₇F₁₅C₂H₄P(O)(OH)₂, C₈F₁₇C₂H₄P(O)(OH)₂, those obtained by substituting —P(O)(OH)₂ group of these compounds with —P(O)(OH)OCH₃ group, —P(O)(OH)OC₂H₅ group, —P(O)(OCH₃)₂ group or —P(O)(OC₂H₅)₂ group, and the like.

In order that the compound represented by the general formula [6] provides more excellent water-repellency, it is preferable that “g” of the general formula [6] is 1 or 2, and it is more preferable that “g” is 2. Moreover, R⁸ of the general formula [6] is exemplified by an alkyl group, a phenyl group, a phenyl group the hydrogen elements of which are replaced with alkyl groups, a naphthyl group, these hydrocarbon groups the hydrogen elements of which are partially or entirely replaced with a fluorine element(s), and the like.

Additionally, R⁸ of the general formula [6] having a carbon number of from 2 to 16, particularly from 4 to 14 and more particularly from 6 to 14 are preferable because the water-repellency is more excellently obtained thereby. In addition, it is preferable that the hydrocarbon group the hydrogen elements of which may partially or entirely be replaced with a fluorine element(s) is an alkyl group, more preferably a straight-chained alkyl group. If a straight-chained alkyl group is used as the hydrocarbon group, hydrophobic moieties of the agent for forming a protective film tend to be arranged perpendicularly to the surface of the protective film at the time of forming the protective film thereby more excellently exhibiting a water-repellency-imparting effect, which is therefore further preferable. Moreover, R⁸ of the general formula [6] is preferably hydrocarbon groups whose hydrogen elements are partially or entirely substituted with a fluorine element(s), in order to impart a far better water-repellency.

Additionally, the agent for forming a protective film may exist in the form of a salt represented by the general formula [6]. The salt can be cited by ammonium salt, amine salt and the like.

Additionally it is preferable that R¹⁰ of the general formula [7], R¹¹ of the general formula [8], R¹⁴ of the general formula [9], R¹⁵ of the general formula [10], R¹⁶ of the general formula [11], and R¹⁷ and R¹⁸ of the general formula [12] are C₁-C₁₈ monovalent hydrocarbon groups each of which hydrogen elements may partially or entirely be replaced with a fluorine element(s), and more preferably, CₘH₂ₘ₊₁ (m=1-18), CₙF₂ₙ₊₁CH₂CH₂ (n=1-8), CₚF₂ₚ₊₁CH₂ (p=1-8) and C_{q}F_{2q+1}(q=1-8). Furthermore, R²⁴ of the general formula [13] is preferably or CᵥF₂ᵥ₊₁ (v=4-8)(CH₂)ₛ— group (r=4-8, s=0-2).

A compound represented by the general formula [7] is exemplified by CH₃COCl, C₂H₅COCl, C₃H₇COCl, C₄H₉COCl, C₅H₁₁COCl, C₆H₁₃COCl, C₇H₁₅COCl, C₈H₁₇COCl, C₉H₁₉COCl, C₁₀H₂₁COCl, C₁₁H₂₃COCl, C₁₂H₂₅COCl, C₄H₂₇COCl, C₁₄H₂₉COCl, C₁₅H₃₁COCl, C₁₆H₃₃COCl, C₁₇H₃₅COCl, C₁₈H₃₇COCl, C₆H₅COCl, CF₃COCl, C₂F₅COCl, C₃F₇COCl, C₅H₁₁COCl, C₆F₁₃COCl, C₇F₁₅COCl, C₈F₁₇COCl, compounds obtained by substituting —Cl group of the above compounds with —F group, —Br group or —I group, and the like.

In view of the compatibility with a matter containing metallic element and the water-repellency-imparting effect onto the surface of the metallic element-containing wafer, the particularly preferable examples of the above compounds are C₈H₁₇COCl, C₉H₁₉, C₁₀H₂₁, C₁₁H₂₃COCl, C₁₂H₂₅COCl, C₁₃H₂₇COCl, C₁₄H₂₉COCl, C₁₅H₃₁COCl, C₁₆H₃₃COCl, C₁₇H₃₅COCl, C₁₈H₃₇COCl, C₄F₉COCl, C₅H₁₁COCl, C₆F₁₃COCl, C₇F₁₅COCl, C₈F₁₇COCl, compounds obtained by substituting —Cl group of the above compounds with —F group, —Br group or —I group, and the like.

A compound represented by the general formula [8] is exemplified by compounds such as C₅H₁₁NH₂, C₆H₁₃NH₂, C₇H₁₅NH₂, C₁₈H₁₇NH₂, C₉H₁₉NH₂, C₁₀H₂₁NH₂, C₁₁H₂₃NH₂, C₁₂H₂₅NH₂, C₁₃H₂₇NH₂, C₁₄H₂₉NH₂, C₁₅H₃₁NH₂, C₁₆H₃₃NH₂, C₁₇H₃₅NH₂, C₁₈H₁₃NH₂, CF₃NH₂, CF₃C₂H₄NH₂, C₂F₅NH₂, C₂F₅C₂H₄NH₂, C₃F₇NH₂, C₃F₇C₂H₄NH₂, C₄F₉NH₂, C₄F₉C₂H₄NH₂, C₄F₉CH₂NH₂, C₅H₁₁NH₂, C₅F₁₁C₂H₄NH₂, C₅F₁₁CH₂NH₂, C₆F₁₃NH₂, C₆F₁₃C₂H₄NH₂, C₆F₁₃CH₂NH₂, C₇F₁₅NH₂, C₇F₁₅C₂H₄NH₂, C₇F₁₅CH₂NH₂, C₈F₁₇NH₂, C₈F₁₇C₂H₄NH₂, C₈F₁₇CH₂NH₂, C₄F₇H₂NH₂, C₆F₁₁H₂NH₂, C₈F₁₅H₂NH₂, (C₃H₇)₂NH, (C₄H₉)₂NH, (C₅H₁₁)₂NH, (C₆H₁₃)₂NH, (C₇H₁₅)₂NH, (C₈H₁₇)₂NH, (C₉H₁₉)₂NH, (C₁₀H₂₁)₂NH, (C₁₁H₂₃)₂NH, (C₁₂H₂₅)₂NH, (C₁₃H₂₇)₂NH, (C₁₄H₂)₂NH, (C₁₅H₃₁)₂NH, (C₁₆H₃₃)₂NH, (C₁₇H₃₅)₂NH, (C₁₈H₃₇)₂NH, (CF₃)₂NH, (C₂F₅)₂NH, (C₃F₇)₂NH, (C₄F₉)₂NH, (C₅F₁₁)₂NH, (C₆F₁₃)₂NH, (C₇F₁₅)₂NH, (C₈F₁₇)₂NH, (C₄F₇H₂)₂NH, (C₆F₁₁H₂)₂NH, (C₈F₁₅H₂)₂NH, (C₂H₅)₃N, (C₃H₇)₃N, (C₄H₉)₃N, (C₅H₁₁)₃N, (C₆H₁₃)₃N, (C₇H₁₅)₃N, (C₈H₁₇)₃N, (C₉H₁₉)₃N, (C₁₀H₂₁)₃N, (C₁₁H₂₃)₃N, (C₁₂H₂₅)₃N, (C₁₃H₂₇)₃N, (C₁₄H₂₉)₃N, (C₁₅H₃₁)₃N, (C₁₆H₃₃)₃N, (C₁₇H₃₅)₃N, (C₁₈H₃₇)₃N, (CF₃)₃N, (C₂F₃)₃N, (C₃F₇)₃N, (C₄F₉)₃N, (C₅F₁₁)₃N, (C₆F₁₃)₃N, (C₇F₁₅)₃N, (C₈F₁₇)₃N, (C₄F₇H₂)₃N, (C₆F₁₁H₂)₃N, (C₈F₁₅H₂)₃N, (C₅H₁₁)(CH₃)NH, (C₆H₁₃)(CH₃)NH, (C₇F₁₅)(CH₃)NH, (C₈H₁₇)(CH₃)NH, (C₉H₁₉)(CH₃)NH, (C₁₀H₂₁)(CH₂)NH, (C₁₁H₂₃)(CH₃)NH, (C₁₂H₂₅)(CH₃)NH, (C₁₃H₂₇)(CH₃)NH, (C₁₄H₂₉)(CH₃)NH, (C₁₅H₃₁)(CH₃)NH, (C₁₆H₃₃)(CH₃)NH, (C₁₇H₃₅)(CH₃)NH, (C₁₈H₃₇)(CH₃)NH, (CF₃)(CH₃)NH, (C₂F₅)(CH₃)NH, (C₃F₇)(CH₃)NH, (C₄F₉)(CH₃)NH, (C₅F₁₁)(CH₃)NH, (C₆F₁₃)(CH₃)NH, (C₇F₁₅)(CH₃)NH, (C₈F₁₇)(CH₃)NH, (C₃H₇)(CH₃)₂N, (C₄H₉)(CH₃)₂N, (C₅H₁₁)(CH₃)₂N, (C₆H₁₃)(CH₃)₂N, (C₇H₁₅)(CH₃)₂N, (C₈H₁₇)(CH₃)₂N, (C₉H₁₉)(CH₃)₂N, (C₁₀H₂₁)(CH₃)₂N, (C₁₁H₂₃)(CH₃)₂N, (C₁₂H₂₅)(CH₃)₂N, (C₁₃H₂₇)(CH₃)₂N, (C₁₄H₂₉)(CH₃)₂N, (C₁₅H₃₁)(CH₃)₂N, (C₁₆H₃₃)(CH₃)₂N, (C₁₇H₃₅)(CH₃)₂N, (C₁₈H₃₇)(CH₃)₂N, (CF₃)(CH₃)₂N, (C₂F₅)(CH₃)₂N, (C₃F₇)(CH₃)₂N, (C₄F₉)(CH₃)₂N, (C₅F₁₁)(CH₃)₂N, (C₆F₁₃)(CH₃)₂N, (C₇F₁₅)(CH₃)₂N, (C₈F₁₇)(CH₃)₂N and the like. In addition, the agent for forming a protective film may exist in the form of a salt of the general formula [8]. It is possible to exemplify the salt by inorganic acid salts such as carbonate, hydrochloride, sulfate, nitrate and the like, and organic acid salts such as acetate, propionate, butyrate, phthalate and the like.

In consideration of the compatibility with a matter containing metallic element and the water-repellency-imparting effect onto the surface of the metallic element-containing wafer, the particularly preferable examples of the above compounds are compounds such as C₆H₁₃NH₂, C₇H₁₅NH₂, C₈H₁₇NH₂, C₉H₁₉NH₂, C₁₀H₂₁NH₂, C₁₁H₂₃NH₂, C₁₂H₂₅NH₂, C₁₃H₂₇NH₂, C₁₄H₂₉NH₂, C₁₅H₃₁NH₂, C₁₆H₃₃NH₂, C₁₇H₃₅NH₂, C₁₈H₃₇NH₂, (C₄H₉)₂NH, (C₅H₁₁)₂NH, (C₆H₁₃)₂NH, (C₇H₁₅)₂NH, (C₈H₁₇)₂NH, (C₉H₁₉)₂NH, (C₁₀H₂₁)₂NH, (C₁₁H₂₃)₂NH, (C₁₂H₂₅)₂NH, (C₁₃H₂₇)₂NH, (C₁₄H₂₉)₂NH, (C₁₅H₃₁)₂NH, (C₁₆H₃₃)₂NH, (C₁₇H₃₅)₂NH, (C₁₈H₃₇)₂NH, (C₄H₉)₃N, (C₅H₁₁)₃N, (C₆H₁₃)₃N, (C₇H₁₅)₃N, (C₈H₁₇)₃N, (C₉H₁₉)₃N, (C₁₀H₂₁)₃N, (C₁₁H₂₃)₃N, (C₁₂H₂₅)₃N, (C₁₃H₂₇)₃N, (C₁₄H₂₉)₃N, (C₁₅H₃₁)₃N, (C₁₆H₃₃)₃N, (C₁₇H₃₅)₃N, (C₁₈H₃₇)₃N, (C₅H₁₁)(CH₃)₂N, (C₆H₁₃)(CH₃)₂N, (C₇H₁₅)(CH₃)NH, (C₈H₁₇(CH₃)NH, (C₉H₁₉)(CH₃)NH, (C₁₀H₂₁)(CH₃)NH, (C₁₁H₂₃)(CH₃)₂N, (C₁₂H₂₅)(CH₃)₂N, (C₁₃H₂₇)(CH₃)NH, (C₁₄H₂₉)(CH₃)NH, (C₁₅H₃₁)(CH₃)₂N, (C₁₆H₃₃)(CH₃)NH, (C₁₇H₃₅)(CH₃)NH, (C₁₈H₃₇)(C₃)NH, (C₄H₉)(CH₃)₂N, (C₅H₁₁)(CH₃)₂N, (C₆H₁₁)(CH₃)₂N, (C₇H₁₅)(CH₃)₂N, (C₈H₁₇)(CH₃)₂N, (C₉H₁₉)(CH₃)₂N, (C₁₀H₂₁)(CH₃)₂N, (C₁₁H₂₃)(CH₃)₂N, (C₁₂H₂₅)(CH₃)₂N, (C₁₃H₂₇)(CH₃)₂N, (C₁₄H₂₉)(CH₃)₂N, (C₁₅H₃₁)(CH₃)₂N, (C₁₆H₃₃)(CH₃)₂N, (C₁₇H₃₅)(CH₃)₂N, (C₁₈H₃₇)(CH₃)₂N, C₄F₉NH₂, C₄F₉C₂H₄NH₂, C₄F₉CH₂NH₂, C₅F₁₁NH₂, C₅F₁₁C₂H₄NH₂, C₅F₁₁CH₂NH₂, C₆F₁₃NH₂, C₆F₁₃C₂H₄NH₂, C₆F₁₃CH₂NH₂, C₇F₁₅NH₂, C₇F₁₅C₂H₄NH₂, C₇F₁₅CH₂NH₂, C₈F₁₇NH₂, C₈F₁₇C₂H₄NH₂, C₈F₁₇CH₂NH₂ and the like, inorganic acid salts thereof such as carbonate, hydrochloride, sulfate, nitrate and the like, and organic acid salts thereof such as acetate, propionate, butyrate, phthalate and the like.

A compound represented by the general formula [9] is exemplified by compounds such as C₅H₁₁COOH, C₆H₁₃COOH, C₇H₁₅COOH, C₈H₁₇COOH, C₉H₁₉COOH, C₁₀H₂₁COOH, C₁₁H₂₃COOH, C₁₂H₂₅COOH, C₁₃H₂₇COOH, C₁₄H₂₉COOH, C₁₅H₃₁COOH, C₁₆H₃₃COOH, C₁₇H₃₅COOH, C₁₈H₃₇COOH, C₆H₅COOH, C₅H₁₁COOH, C₆F₁₃COOH, C₇F₁₅COOH, C₈F₁₇COOH and the like, compounds obtained by substituting —COOH group of the above compounds with —COOCH₃ group, —COOC₂H₅ group, —COOC₆H₅ group, —COSH group or —COSCH₃ group, and the like.

In consideration of the compatibility with a matter containing metallic element and the water-repellency-imparting effect onto the surface of the metallic element-containing wafer, the particularly preferable examples of the above compounds are compounds such as C₅H₁₁COOH, C₆H₁₃COOH, C₇H₁₅COOH, C₈H₁₇COOH, C₉H₁₉COOH, C₁₀H₂₁COOH, C₁₁H₂₃COOH, C₁₂H₂₅COOH, C₁₃H₂₇COOH, C₁₄H₂₉COOH, C₁₅H₃₁COOH, C₁₆H₃₃COOH, C₁₇H₃₅COOH, C₁₈H₃₇COOH, C₄H₉COOCH₃, C₅H₁₁COOCH₃, C₆H₁₃COOCH₃, C₇H₁₅COOCH₃, C₈H₁₇COOCH₃, C₉H₁₉COOCH₃, C₁₀H₂₁COOCH₃, C₁₁H₂₃COOCH₃, C₁₂H₂₅COOCH₃, C₁₃H₂₇COOCH₃, C₁₄H₂₉COOCH₃, C₁₅H₃₁COOCH₃, C₁₆H₃₃COOCH₃, C₁₇H₃₅COOCH₃, C₁₈H₃₇COOCH₃, C₄H₉COOC₂H₅, C₅H₁₁COOC₂H₅, C₆H₁₃COOC₂H₅, C₇H₁₅COOC₂H₅, C₈H₁₇COOC₂H₅, C₉H₁₉COOC₂H₅, C₁₀H₂₁COOC₂H₅, C₁₁H₂₃COOC₂H₅, C₁₂H₂₅COOC₂H₅, C₁₃H₂₇COOC₂H₅, C₁₄H₂₉COOC₂H₅, C₁₅H₃₁COOC₂H₅, C₁₆H₃₃COOC₂H₅, C₁₇H₃₅COOC₂H₅, C₁₈H₃₇COOC₂H₅, C₄H₉COOC₆H₅, C₅H₁₁COOC₆H₅, C₆H₁₃COOC₆H₅, C₇H₁₅COOC₆H₅, H₈H₁₇COOC₆H₅, C₉H₁₉COOC₆H₅, C₁₀H₂₁COOC₆H₅, C₁₁H₂₃COOC₆H₅, C₁₂H₂₅COOC₆H₅, C₁₃H₂₇COOC₆H₅, C₁₄H₂₉COOC₆H₅, C₁₅H₃₁COOC₆H₅, C₁₆H₃₃COOC₆H₅, C₁₇H₃₅COOC₆H₅, C₁₈H₃₇COOC₆H₅, C₅H₁₁COSH, C₆H₁₃COSH, C₇H₁₅COSH, C₈H₁₇COSH, C₉H₁₉COSH, C₁₀H₂₁COSH, C₁₁H₂₃COSH, C₁₂H₂₅COSH, C₁₃H₂₇COSH, C₁₄H₂₉COSH, C₁₅H₃₁COSH, C₁₆H₃₃COSH, C₁₇H₃₅COSH, C₁₈H₃₇COSH, C₄H₉COSCH₃, C₅H₁₁COSCH₃, C₆H₁₃COSCH₃, C₇H₁₅COSCH₃, C₈H₁₇COSCH₃, C₉H₁₉COSCH₃, C₁₀H₂₁COSCH₃, C₁₁H₂₃COSCH₃, C₁₂H₂₅COSCH₃, C₁₃H₂₇COSCH₃, C₁₄H₂₉COSCH₃, C₁₅H₃₁COSCH₃, C₁₆H₃₃COSCH₃, C₁₇H₃₅COSCH₃, C₁₈H₃₇COSCH₃ and the like.

A compound represented by the general formula [10] is exemplified by: isocyanate compounds such as C₂H₅NCO, C₃H₇NCO, C₄H₉NCO, C₅H₁₁NCO, C₆H₁₃NCO, C₇H₁₅NCO, C₈F₁₇NCO, C₉H₁₉NCO, C₁₁H₂₃NCO, C₁₂H₂₅NCO, C₁₃H₂₇NCO, C₁₄H₂₉NCO, C₁₅H₃₁NCO, C₁₆H₃₃NCO, C₁₇H₃₅NCO, C₁₈H₃₇NCO, CF₃NCO, CF₃CH₂NCO, CF₃C₂H₄NCO, C₂H₅NCO, C₂F₅CH₃NCO, C₂F₅C₂H₄NCO, C₃F₇NCO, C₃F₇CH₂NCO, C₃F₇C₂H₄NCO, C₄F₉NCO, C₄F₉CH₂NCO, C₄F₉C₂H₄NCO, C₅H₁₁NCO, C₅H₁₁CH₂NCO, C₅F₁₁C₂H₄NCO, C₆F₁₃NCO, C₆F₁₃CH₂NCO, C₆F₁₃C₂H₄NCO, C₇F₁₅NCO, C₇F₁₅CH₂NCO, C₇F₁₅C₂H₄NCO, C₈F₁₇NCO, C₈F₁₇CH₂NCO, C₈F₁₇C₂H₄NCO, C₂H₄(NCO)₂, C₃H₆(NCO)₂, C₄H₈(NCO)₂, C₅H₁₀(NCO)₂, C₆H₁₂(NCO)₂, C₇H₁₄(NCO)₂, C₈H₁₆(NCO)₂, C₉H₁₈(NCO)₂, C₁₀H₂₀(NCO)₂, C₁₁H₂₂(NCO)₂, C₁₂H₂₄(NCO)₂, C₁₃H₂₆(NCO)₂, C₁₄H₂₈(NCO)₂, C₁₅H₃₀(NCO)₂, C₁₆H₃₂(NCO)₂, C₁₇H₃₄(NCO)₂, C₁₈H₃₆(NCO)₂, (NCO)C₂H₄NCO, (NCO)C₃F₁₆NCO, (NCO)C₄H₈NCO, (NCO)C₅H₁₀NCO, (NCO)C₆H₁₂NCO, (NCO)C₇H₁₄NCO, (NCO)C₈H₁₆NCO, (NCO)C₉H₁₈NCO, (NCO)C₁₀H₂₀NCO, (NCO) C₁₁H₂₂NCO, (NCO)C₁₂H₂₄NCO, (NCO)C₁₃H₂₆NCO, (NCO)C₁₄H₂₈NCO, (NCO)C₁₅H₃₀NCO, (NCO)C₁₆H₃₂NCO, (NCO)C₁₇H₃₄NCO, (NCO)C₁₈H₃₆NCO, C₂H₃(NCO)₃, C₃H₅(NCO)₃, C₄H₇(NCO)₃, C₅H₉(NCO)₃, C₆H₁₁(NCO)₃, C₇H₁₃(NCO)₃, C₈H₁₅(NCO)₃, C₉H₁₇(NCO)₃, C₁₀H₁₉(NCO)₃, C₁₁H₁₂(NCO)₃, C₁₂H₂₃(NCO)₃, C₁₃H₂₅(NCO)₃, C₁₄H₂₇(NCO)₃, C₁₅H₂₉(NCO)₃, C₁₆H₃₁(NCO)₃, C₁₇H₃₃(NCO)₃, C₁₈H₃₅(NCO)₃, C(NCO)₄, (NCO)₂C₂H₂(NCO)₂, (NCO)₂C₃H₄(NCO)₂, (NCO)₂C₄H₆(NCO)₂, (NCO)₂C₅H₈(NCO)₂, (NCO)₂C₆H₁₀(NCO)₂, (NCO)₂C₇H₁₂(NCO)₂, (NCO)₂C₈H₁₄(NCO)₂, (NCO)₂C₉H₁₆(NCO)₂, (NCO)₂C₁₀H₁₈(NCO)₂, (NCO)₂C₁₁H₂₀(NCO)₂, (NCO)₂C₁₂H₂₂(NCO)₂, (NCO)₂C₁₃H₂₄(NCO)₂, (NCO)₂C₁₄H₂₆(NCO)₂, (NCO)₂C₁₅H₂₃(NCO)₂, NCO)₂C₁₆H₃₀(NCO)₂, (NCO)₂C₁₇H₃₂(NCO)₂, (NCO)₂C₁₈H₃₄(NCO)₂ and the like; compounds obtained by substituting an isocyanate group (—NCO group) of the above isocyanate compounds with —SH group, —CHO group, —CONHOH group or a nitrogen element-containing, cyclic structure such as an imidazoline ring (the following formula [18]); and the like.

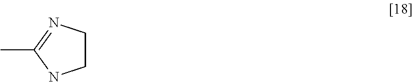

In consideration of the compatibility with a matter containing metallic element and the water-repellency-imparting effect onto the surface of the metallic element-containing wafer, the particularly preferable examples of the above compounds are isocyanate compounds such as C₄H₉NCO, C₅H₁₁NCO, C₆H₁₃NCO, C₇H₁₅NCO, C₈H₁₇NCO, C₉H₁₉NCO, C₁₀H₂₁NCO, C₁₁H₂₃NCO, C₁₂H₂₅NCO, C₁₃H₂₇NCO, C₁₄H₂₉NCO, C₁₅H₃₁NCO, C₁₆H₃₃NCO, C₁₇H₃₅NCO, C₁₈H₃₇NCO, C₃F₇CH₂NCO, C₃F₇C₂H₄NCO, C₄F₉NCO, C₄F₉CH₉NCO, C₄F₉C₂H₄NCO, C₅H₁₁NCO, C₅H₁₁CH₂NCO, C₅F₁₁C₂H₄NCO, C₆F₁₃NCO, C₆F₁₃CH₂NCO, C₆F₁₃C₂H₄NCO, C₇F₁₅NCO, C₇F₁₅CH₂NCO, C₇F₁₅C₂H₄NCO, C₈F₁₇NCO, C₈F₁₇CH₉NCO, C₈F₁₇C₂H₄NCO and the like; compounds obtained by substituting an isocyanate group (—NCO group) of the above isocyanate compounds with —SH group, —CHO group, —CONHOH group or a nitrogen element-containing, cyclic structure such as an imidazoline ring; and the like.

A compound represented by the general formula [11] is exemplified by compounds such as CH₃C₄H₃S, C₂H₅C₄H₃S, C₃H₇C₄H₃S, C₄H₉C₄H₃S, C₅H₁₁C₄H₃S, C₆H₁₃C₄H₃S, C₇H₁₅C₄H₃S, C₈H₁₇C₄H₃S, C₉H₁₉C₄H₃S, C₁₀H₂₁C₄H₃S, C₁₁H₂₃C₄H₃S, C₁₂H₂₅C₄H₃S, C₁₃H₂₇C₄H₃S, C₁₄H₂₉C₄H₃S, C₁₅H₃₁C₄H₃S, C₁₀H₃₃C₄H₃S, C₁₇H₃₅C₄H₃S, C₁₈H₃₇C₄H₃S, C₃H₃NS, CH₃C₃H₂NS, C₂H₅C₃H₂NS, C₃H₇C₃H₂NS, C₄H₉C₃H₂NS, C₅H₁₁C₃H₂NS, C₆H₁₃C₃H₂NS, C₇H₁₅C₃H₂NS, C₈H₁₇C₃H₂NS, C₉H₁₉C₃H₂NS, C₁₀H₂₁C₃H₂NS, C₁₁H₂₃C₃H₂NS, C₁₂H₂₅C₃H₂NS, C₁₃H₂₇C₃H₂NS, C₁₄H₂₉C₃H₂NS, C₁₅H₃₁C₃H₂NS, C₁₆H₃₃C₃H₂NS, C₁₇H₃₅C₃H₂NS, and C₁₈H₃₇C₃H₂NS. Incidentally, C₄H₃S represents a thiophene ring, C₃H₃NS represents thiazole, and C₃H₉NS represents a thiazole ring.

A compound represented by the general formula [12] is exemplified by compounds such as CH₃COOCOCH₃, C₂H₅COOCOC₂H₁₅, C₃H₇COOCOC₃H₇, C₄H₉COOCOC₄H₉, C₅H₁₁COOCOC₅H₁₁, C₆H₁₃COOCOC₆H₁₃, C₇H₁₅COOCOC₇H₁₅, C₈H₁₇COOCOC₈H₁₇, C₉H₁₉COOCOC₉H₁₉, C₁₀H₂₁COOCOC₁₀H₂₁, C₁₁H₂₃COOCOC₁₁H₂₃, C₁₂H₂₅COOCOC₁₂H₂₅, C₁₃H₂₇COOCOC₁₃H₂₇, C₁₄H₂₉COOCOC₁₄H₂₉, C₁₅H₃₁COOCOC₁₅H₃₁, C₁₆H₃₃COOCOC₁₆H₃₃, C₁₇H₃₅COOCOC₁₇H₃₅, C₁₈H₃₇COOCOC₁₈H₃₇, C₆H₅COOCOC₆H₅, CF₃COOCOCF₃, C₂F₅COOCOC₂F₅, C₃F₇COOCOC₃F₇, C₄F₉COOCOC₄F₉, C₅H₁₁COOCOC₅F₁₁, C₆F₁₃COOCOC₆F₁₃, C₇F₁₅COOCOC₇F₁₅, and C₈F₁₇COOCOC₈F₁₇.

A compound represented by the general formula [13] is exemplified by: compounds such as C₄H₉O(C₂H₄O)P(O)(OH)₂, C₅H₁₁O(C₂H₄O)P(O)(OH)₂, C₆H₁₃O(C₂H₄O)P(O)(OH)₂, C₇H₁₅O(C₂H₄O)P(O)(OH)₂, C₈H₁₇O(C₂H₄O)P(O)(OH)₂, C₉H₁₉O(C₂H₄O)P(O)(OH)₂, C₁₀H₂₁O(C₂H₄O)P(O)(OH)₂, C₁₂H₂₅O(C₂H₄O)P(O)(OH)₂, C₁₄H₂₉O(C₂H₄O)P(OH)₂, C₁₆H₃₃O(C₂H₄O)P(O)(OH)₂, C₁₈H₃₇O(C₂H₄O)P(O)(OH)₂, C₆H₅O(C₂H₄O)P(O)H)₂, C₄F₉O(C₂H₄O)P(O)(OH)₂, C₅F₁₁O(C₂H₄O)P(O)(OH)₂, C₆F₁₃O(C₂H₄O)P(O)(OH)₂, C₇F₁₅O(C₂H₄O)P(O)(OH)₂, C₈F₁₇O(C₂H₄O)P(O)(OH)₂, C₃F₇C₂H₄(C₂H₄O)P(O)(OH)₂, C₄F₉C₂H₄O(C₂H₄O)P(O)(OH)₂, C₅F₁₁C₂H₄O(C₂H₄O)P(O)(OH)₂, C₆F₁₃C₂H₄O(C₂H₄O)P(O)(OH)₂, C₇F₁₅C₂H₄O(C₂H₄O)P(O)(OH)₂, C₈H₁₅C₂H₄O(C₂H₄O)P(O)(OH)₂, {C₄H₉O(C₂H₄O)}₂P(O)OH, {C₅H₁₁O(C₂H₄O)}₂P(O)OH, {C₆H₁₃O(C₂H₄O)}₂P(O)OH, {C₇H₁₅O(C₂H₄O)}₂P(O)OH, {C₈H₁₇O(C₂H₄O)}₂P(O)OH, {C₉H₁₉O(C₂H₄O)}₂P(O)OH, {C₁₀H₂₁O(C₂H₄O)}₂P(O)OH, {C₁₂H₂₅O(C₂H₄O)}₂P(O)OH, {C₁₄H₂₉O(C₂H₁O)}₂P(O)OH, {C₁₆H₃₃O(C₂H₄O)}₂P(O)OH, {C₁₈H₃₇O(C₂H₄O)}₂P(O)OH, {C₆H₅O(C₂H₄O)}₂P(O)OH, {C₄F₉O(C₂H₄O)}₂P(O)OH, {C₅F₁₁O(C₂H₄O)}₂P(O)OH, {C₈F₁₃O(C₂H₄O)}₂P(O)OH, {C₇F₁₅O(C₂H₄O)}₂P(O)OH, {C₈F₁₇O(C₂H₄O)}₂P(O)OH, {C₄F₉C₉H₄O(C₂H₄O)}₂P(O)OH, {C₅F₁₁C₂H₄O(C₂H₄O)}₂P(O)OH, {C₆F₁₃C₂H₄O(C₂H₄O)}₂P(O)OH, {C₇F₁₅C₂H₄O(C₂H₄O)}₂P(O)OH, {C₈F₁₇C₂H₄O(C₂H₄O)}₂P(O)OH and the like; compounds obtained by substituting —O(C₂H₄O)— group of the above compounds with —O— group, —O(C₂H₄O)_{w}— group (w=2-10) or —O(C₃H₆O)_{z}— group (z=1-10); and the like. In addition, the agent for forming a protective film may exist in the form of a salt represented by the general formula [13]. The salt can be cited by ammonium salt, amine salt and the like.

Moreover, it is preferable that the agent for forming a protective film which agent is selected from compounds represented by the general formulas [6] to [13] and salt compounds thereof has an HLB value (according to Griffin's method) of from 0.001 to 10, because such a compound can impart better water repellency to the surface of the metallic element-containing wafer.

Additionally, it is preferable that the agent for forming a protective film which agent is selected from compounds represented by the general formulas [6] to [13] and salt compounds thereof is a compound represented by the Mowing general formula [19] or a salt compound thereof, because such a compound can impart better water-repellency to the surface of the metallic element-containing wafer.

R²³—X¹¹ [19]

[in the formula [19], X¹¹ represents at least one selected from the group consisting of —P(O)(OH)₂, —NH₂ group, —N═C═O group, —SH group, —CONHOH group and an imidazoline ring. R²³ represents a C₄-C₁₈ hydrocarbon group or CᵣF₂ᵣ₊₁—(CH₂)ₛ— group (r=4-8, s=0-2).]

The solvent used in the second embodiment is concretely exemplified by the solvent as discussed in the first embodiment, such as hydrocarbons, esters, ethers, ketones, halogen element-containing solvents, sulfoxide-based solvents, lactone-based solvents, carbonate-based solvents, polyalcohol derivatives having no OH group and nitrogen element-containing solvents having no N—H group. Additionally, it is also possible to cite; water; alcohols such as methanol, ethanol, propanol, butanol, pentanol, hexanol, heptanol, octanol, ethylene glycol, diethylene glycol, 1,3-propanediol, 1,2-propanediol, dipropylene glycol, 1,2-butanediol, 1,3-butanediol, triethylene glycol, tripropylene glycol, tetraethylene glycol, tetrapropylene glycol, glycerine and the like; polyalcohol derivatives having OH group, such as ethylene glycol monomethyl ether, ethylene glycol monoethyl ether, ethylene glycol monopropyl ether, ethylene glycol monobutyl ether, diethylene glycol monomethyl ether, diethylene glycol monoethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether, butylene glycol monomethyl ether and the like; and nitrogen element-containing solvents having N—H group, such as formamide.

Additionally it is preferable to use a nonflammable solvent as a part or the entire of the solvent, since the liquid chemical for forming a protective film becomes nonflammable or increases in flash point thereby reducing the risk of the liquid chemical. Most of the halogen-containing solvents are nonflammable, and such a halogen-containing nonflammable solvent can preferably be used as a nonflammable solvent. Furthermore, water can also be used as the nonflammable solvent.

Additionally it is preferable, in view of safety under the fire protection law, to use a solvent having a flash point exceeding 70° C. as the solvent.

According to “Globally Harmonized System of Classification and Labelling of Chemicals; GHS”, a solvent having a flash point of not higher than 93° C. is defined as “a flammable liquid”. Therefore, when a solvent having a flash point exceeding 93° C. is used as the solvent, the liquid chemical for forming a protective film tends to have a flash point exceeding 93° C. even if the solvent is not nonflammable one. Hence the liquid chemical hardly corresponds to “a flammable liquid” and therefore further preferable in view of safety.

Additionally, most of the lactone-based solvents, carbonate-based solvents and the polyalcohol derivatives have a high flash point; therefore, it is preferable to use these solvents because the risk of the liquid chemical for forming a protective film can be reduced. In view of the safety, it is preferable to use: the solvents as discussed in the first embodiment to have a flash point exceeding 70° C.; or solvents having a flash point exceeding 70° C. and concretely exemplified by ethylene glycol, diethylene glycol, 1,2-propanediol, 1,3-propanediol, dipropylene glycol, 1,2-butanediol, 1,3-butanediol, 1,4-butanediol, triethylene glycol, tripropylene glycol, tetraethylene glycol, tetrapropylene glycol, glycerine, diethylene glycol monomethyl ether, diethylene glycol monoethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether and the like. It is much more preferable to use the solvents as discussed in the first embodiment to have a flash point exceeding 93° C.; or a solvent having a flash point exceeding 93° C. and concretely exemplified by ethylene glycol, diethylene glycol, 1,2-propanediol, 1,3-propanediol, dipropylene glycol, 1,2-butanediol, 1,3-butanediol, 1,4-butanediol, triethylene tripropylene glycol, tetraethylene glycol, tetrapropylene glycol, glycerine, diethylene glycol monomethyl ether, diethylene glycol monopropyl ether, diethylene glycol monobutyl ether, triethylene glycol monomethyl ether, triethylene glycol monoethyl ether, triethylene glycol monopropyl ether, triethylene glycol monobutyl ether, tetraethylene glycol monomethyl ether, tetraethylene glycol monoethyl ether, tetraethylene glycol monopropyl ether, tetraethylene glycol monobutyl ether, dipropylene glycol monopropyl ether, dipropylene glycol monobutyl ether, tripropylene glycol monomethyl ether, tripropylene glycol monoethyl ether, tripropylene glycol monopropyl ether, tripropylene glycol monobutyl ether, tetrapropylene glycol monomethyl ether and the like.

Among the liquid chemicals prepared according to the second embodiment, it is preferable to use: one containing a mixture of 85 to 99.9995 mass % of at least one kind of solvent selected from the group consisting of ketones, polyalcohol derivatives, water and alcohols and 15 to 0.0005 mass % of a compound represented by the following general formula [19]; or one consisting only of the mixture.

R²³—X^{11[}19]

[In the formula [19]. X¹¹ represents at least one selected from the group consisting of —P(O)(OH)₂, —NH₂ group, —N═C═O group, group, —CONHOH group and an imidazoline ring. R²³ represents a C₄-C₁₈ hydrocarbon group or CᵣF₂ᵣ₊₁—(CH₂)— group (r=4-8, s=0-2).]

A liquid chemical kit (a treatment liquid (A) and a treatment liquid (B)) for forming a water-repellent protective film, obtained according to a third and a fourth embodiment of the present invention can provide a liquid chemical for forming a water-repellent protective film by mixing the treatment liquids (A) and (B) thereby allowing the formation of a water-repellent protective film on the surfaces of the recessed portions of a silicon element-containing wafer.

The formation of the water-repellent protective film on the surfaces of the recessed portions of the silicon element-containing wafer is achieved: by causing a reaction between a reactive moiety of a silylation reagent contained in the treatment liquid (A) and a silanol group that serves as a reaction site of the silicon element-containing wafer thereby chemically bonding the silylation reagent to a silicon element of the silicon element-containing wafer through a siloxane bond; or by causing a reaction between a reaction product (obtained between a silylation reagent contained in the treatment liquid (A) and an acid or base contained in the treatment liquid (B)) and a silanol group that serves as a reaction site of the silicon element-containing wafer thereby chemically bonding the reaction product to a silicon element of the silicon element-containing wafer through a siloxane bond. The reaction moiety is a group represented by in general formula [1].

In addition, R¹ of the general formula [1] serves as a hydrophobic moiety which decreases a surface energy of an article to reduce the interaction caused between water or another liquid and the article surface (i.e., at the interface), such as hydrogen bond, intermolecular forces and the like. The effect of reducing the interaction is particularly exhibited with water, but the effect of reducing the interaction is exhibited also with a mixture liquid of water and a liquid, other than water or with a liquid other than water. With this, the contact angle of the liquid to the article surface can be increased.

A silylation agent represented by the general formula [1] can be concretely exemplified by the same as discussed in the first embodiment.

As the above mentioned silylation reagent, it is preferable to use a silicon compound represented by the general formula [14], since water repellency can sufficiently and easily be provided even onto a wafer the surface of which is low in number of silanol groups that serve as a reaction site in the silicon element-containing wafer, e.g. silicon nitride. Incidentally X¹⁰ in the general formula [14] represents the reactive moiety and R¹⁹ represents the hydrophobic moiety.

Examples of the silicon compound represented by the general formula [14] are: chlorosilane-based compounds such as C₄H₉(CH₃)₂SiCl, C₅H₁₁(CH₃)₂SiCl, C₆H₁₃(CH₃)₂SiCl, C₇H₁₅(CH₃)₂SiCl, C₈H₁₇(CH₃)₂SiCl, C₉H₁₉(CH₃)₂SiCl, C₁₀H₂₁(CH₃)₂SiCl, C₁₁H₂₃(CH₃)₂SiCl, C₁₂H₂₅(CH₃)₂SiCl, C₁₃H₂₇(CH₃)₂SiCl, C₁₄F₂₉(CH₃)₂SiCl, C₁₅H₃₁(CH₃)₂SiCl, C₁₆H₃₃(CH₃)₂SiCl, C₁₇H₃₅(CH₃)₂SiCl, C₁₈H₃₇(CH₃)₂SiCl, C₅H₁₁(CH₃)HSiCl, C₆H₁₃(CH₃)HSiCl, C₇H₁₅(CH₃)HSiCl, C₈H₁₇(CH₃)HSiCl, C₉H₁₉(CH₃)HSiCl, C₁₀H₂₁(CH₃)HSiCl, C₁₁H₂₃(CH₃)HSiCl, C₁₄H₂₉(CH₃)HSiCl, C₁₅H₃₁(CH₃)HSiCl, C₁₆H₃₃(CH₃)HSiCl, C₁₇H₃₅(CH₃)HSiCl, C₁₈H₃₇(CH₃)HSiCl, C₂F₅C₂H₄(CH₃)₂SiCl, C₃F₇C₂H₄(CH₃)₂SiCl, C₄F₉C₂H₄(CH₃)₂SiCl, C₅F₁₁C₂H₄(CH₃)₂SiCl, C₆F₁₃C₂H₄(CH₃)₂SiCl, C₇F₁₅C₂H₄(CH₃)₂SiCl, C₈H₁₇C₂H₄(CH₃)₂SiCl, (C₂H₅)₃SiCl, C₃H₇(C₂H₅)₂SiCl, C₄H₉(C₂H₅)₂SiCl, C₅H₁₁(C₂H₅)₂SiCl, C₆H₁₃C₂H₅)₂SiCl, C₇F₁₅(C₂H₅)₂SiCl, C₈H₁₇(C₂H₅)₂SiCl, C₉H₁₉(C₂H₅)₂SiCl, C₁₀H₂₁(C₂H₅)₂SiCl, C₁₁H₂₃(C₂H₅)₂SiCl, C₁₂H₂₅(C₂H₅)SiCl, C₁₃H₂₇(C₂H₅)₂SiCl, C₁₄H₂₉(C₂H₅)₂SiCl, C₁₅H₃₁(C₂H₅)₂SiCl, C₁₆H₃₃(C₂H₅)₂SiCl, C₁₇H₃₅(C₂H₅)₂SiCl, C₁₈H₃₇(C₂H₅)₂SiCl, (C₄H₉)₃SiCl, C₅H₁₁(C₄H₅)₂SiCl, C₆H₁₃(C₄H₉)₂SiCl, C₇H₁₅(C₄H₉)₂SiCl, C₈H₁₇(C₄H₉)₂SiCl, C₉H₁₉(C₄H₉)₂SiCl, C₁₀H₂₁(C₄H₉)₂SiCl, C₁₁H₂₃(C₄H₉)₂SiCl, C₁₂H₂₅(C₄H₉)₂SiCl, C₁₃H₂₇(C₁H₉)₂SiCl, C₁₄H₂₉(C₄H₉)₂SiCl, C₁₅H₃₁(C₄H₉)₂SiCl, C₁₆H₃₃(C₄H₉)₂SiCl, C₁₇H₃₅(C₄H₉)₂SiCl, C₁₈H₃₇(C₄H₉)₂SiCl, CF₃C₂H₄(C₄H₉)₂SiCl, C₂F₅C₂H₄(C₄H₉)₂SiCl, C₃F₇C₂H₄(C₄H₉)₂SiCl, C₄F₉C₂H₄(C₄H₉)₂SiCl, C₅F₁₁C₂H₄(C₄H₉)₂SiCl, C₆F₁₃C₂H₄(C₄H₉)₂SiCl, C₇F₁₅C₂H₄(C₄H₉)₂SiCl, C₈F₁₇C₂H₄(C₄H₉)₂SiCl, C₅H₁₁(CH₃)SiCl₂, C₆H₁₃(CH₃)SiCl₂, C₇H₁₅(CH₃)SiCl₂, C₈H₁₇(CH₃)SiCl₂, C₉H₁₉(CH₃)SiCl₂, C₁₀H₂₁(CH₃)SiCl₂, C₁₁H₂₃(CH₃)SiCl₂, C₁₁H₂₅(CH₃)SiCl₂, C₁₃H₂₇(CH₃)SiCl₂, C₁₄H₂₉(CH₃)SiCl₂, C₁₅H₃₁(CH₃)SiCl₂, C₁₆H₃₃(CH₃)SiCl₂, C₁₇H₃₅(CH₃)SiCl₂, C₁₈H₃₇(CH₃)SiCl₂, C₃F₇C₂H₄(CH₃)SiCl₂, C₄F₉C₂H₄(CH₃)SiCl₂, C₅F₁₁C₂H₄(CH₃) SiCl₂, C₆F₁₃C₂H₄(CH₃)SiCl₂, C₇F₁₅C₂H₄(CH₃)SiCl₂, C₈F₁₇C₂H₄(CH₃)SiCl₂, C₆H₁₃SiCl₃, C₇H₁₅SiCl₃, C₈H₁₇SiCl₃, C₉H₁₉SiCl₃, C₁₀H₂₁SiCl₃, C₁₁H₂₃SiCl₃, C₁₂H₂₅SiCl₃, C₁₃H₂₇SiCl₃, C₁₄H₂₉SiCl₃, C₁₅H₃₁SiCl₃, C₁₆H₃₃SiCl₃, C₁₇H₃₅SiCl₃, C₁₈H₃₇SiCl₃, C₄F₉C₂H₄SiCl₃, C₅F₁₁C₂H₄SiCl₃, C₆F₁₃C₂H₄SiCl₃, C₇F₁₅C₂H₄SiCl₃, C₈H₁₇C₂H₄SiCl₃ and the like; a compound obtained by substituting the chloro (Cl) group of the above-mentioned chlorosilanes with alkoxy group, —OC(CH₃)═CHCOCH₃, —OC(CH₃)═N—Si(CH₃)₃, —OC(CF₃)═N—Si(CH₃)₃, —O—CO—R²¹ (where R²¹ is a C₁-C₁₈ monovalent hydrocarbon group the hydrogen elements of which may partially or entirely be replaced with a fluorine element(s)), an alkyl sulfonate group the hydrogen elements of which may partially or entirely be replaced with a fluorine element(s), isocyanate group, amino group, dialkylamino group, isothiocyanate group, azide group, acetamide group, —N(CH₃)C(O)CH₃, —N(CH₃)C(O)CF₃, —N═C(CH₃)OSi(CH₃)₃, —N═C(CF₃)OSi(CH₃)₃, —NHC(O)—OSi(CH₃)₃, imidazole ring, oxazolidinone ring, morpholine ring. —NH—C(O)—Si(CH₃)₃, —N(H)₂₋ⱼ(Si(H)ₖR²⁰₃₋ₖ)ⱼ(where R²⁰ is a C₁-C₁₈ monovalent hydrocarbon group the hydrogen elements of which may partially or entirely be replaced with a fluorine element(s), “j” is an integer of 1 or 2, and “k” is an integer of from 0 to 2), bromo group, iodo group, nitrile group or —CO—NH—Si(CH₃)₃; and the like.

Additionally “i” in the general formula [14] is required only to be an integer of from 1 to 3; however, when “i” is 1 or 2 and when a liquid chemical obtained from the liquid chemical kit is preserved for a long period of time, there is a possibility of causing polymerization of silicon compound due to the contamination of water content and the like to shorten a possible preservation period. In view of this, it is preferable that “i” in the general formula [14] is 3.

Moreover, among the silicon compounds represented by the general formula [14], those in which one R¹⁹ is a C₄-C₁₈ monovalent hydrocarbon group the hydrogen elements of which may partially or entirely be replaced with a fluorine element(s) and the other R¹⁹ consist of two methyl groups are preferable since the rate of reaction against OH groups resident on the surface of the silicon element-containing wafer is accelerated thereby. This is because steric hindrance due to hydrophobic group has a great influence upon the reaction rate and because it is preferable that an alkyl chain to be bonded to silicon element has the longest chain and two other shorter chains, in a reaction between OH group resident on the surface of the silicon element-containing wafer and the silicon compound.

An acid which may be contained in the treatment liquid (B) can be exemplified by the same acids as those discussed in the first embodiment. Moreover, a base which may be contained in the treatment liquid (B) can be exemplified by the same as those discussed in the first embodiment. Furthermore, a nonaqueous organic solvent used in the third and fourth preparation method of the present invention can concretely be exemplified by the same solvents as discussed in the first embodiment.

Additionally, the present invention is a liquid chemical kit for forming a water-repellent protective film, prepared according to the method for preparing a liquid chemical kit for forming a water-repellent protective film as discussed in any of the above. As the treatment liquid (A) of the liquid chemical kit, it is preferable to use: one containing a mixture of 60 to 99.8 mass % of at least one kind of nonaqueous organic solvent selected from the group consisting of hydrofluoroethers, hydrochlorofluorocarbons, polyalcohol derivatives having no OH group and lactone-based solvents, and 0.2 to 40 mass % of at least one kind of silylation reagent selected from the group consisting of alkoxysilanes having CₓH₂ₓ₊₁ group (x=1-12) or C_{y}F_{2y+1}CH₂CH₂ group (y=1-8), trimethyldimethylaminosilane, trimethyldimethylaminosilane, trimethyldiethylaminosilane, dimethyldimethylaminosilane, dimethyldiethylaminosilane, butyldimethyl(dimethylamino)silane, butyldimethyl(diethylamino)silane, hexyldimethyl(dimethylamino)silane, hexyldimethyl(diethylamino)silane, octyldimethyl(dimethylamino)silane, octyldimethyl(diethylamino)silane, decyldimethyl(dimethylamino)silane, decyldimethyl(diethylamino)silane, dodecyldimethyl(dimethylamino)silane and dodecyldimethyl(diethylamino)silane; or one consisting only of the mixture. Meanwhile, as the treatment liquid (B) of the liquid chemical kit, it is preferable to use: one containing a mixture of 60 to 99.9998 mass % of at least one kind of nonaqueous organic solvent selected from the group consisting of hydrofluoroethers, hydrochlorofluorocarbons, polyalcohol derivatives having no OH group and lactone-based solvents, and 0.0002 to 40 mass % of at least one kind of acid selected from the group consisting of trifluoroacetic acid, trifluoroacetic anhydride, trifluoromethanesulfonic acid, trifluoromethanesulfonic anhydride, trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl trifluoroacetate, decyldimethylsilyl trifluoromethanesulfonate, dodecyldimethylsilyl trifluoroacetate and dodecyldimethylsilyl trifluoromethanesulfonate; or one consisting only of the mixture. Incidentally, at the time of preparing the liquid chemical for forming a water-repellent protective film by mixing the treatment liquid (A) and the treatment liquid (B), it is preferable to mix the nonaqueous organic solvent, the silylation reagent and the acid in an amount of 76 to 99.8999 mass %), 0.1 to 20 mass % and 0.0001 to 4 mass %, respectively, relative to the total amount of 100 mass % of the liquid chemical after preparation.

As the treatment liquid (A) of the liquid chemical kit, it is preferable to use one containing a mixture of 60 to 99.8 mass % of at least one kind of nonaqueous organic solvent selected from the group consisting of hydrofluoroethers, hydrochlorofluorocarbons and polyalcohol derivatives having no OH group and 0.2 to 40 mass % of at least one kind of silylation reagent selected from the group consisting of hexamethyldisilazane, tetramethyldisilazane, 1,3-dibutyltetramethyldisilazane, 1,3-dihexyltetramethyldisilazane, 1,3-dioctyltetramethyldisilazane, 1,3-didecyltetramethyldisilazane and 1,3-didodecyltetramethyldisilazane; or one consisting only of the mixture. Furthermore, as the treatment liquid (B) of the liquid chemical kit, it is preferable to use: one containing a mixture of 60 to 99.9998 mass % of at least one kind of nonaqueous organic solvent selected from the group consisting of hydrofluoroethers, hydrochlorofluorocarbons polyalcohol derivatives having no OH group and 0.0002 to 40 mass % of at least one kind of acid selected from the group consisting of trifluoroacetic acid, trifluoroacetic anhydride, trifluoromethanesulfonic acid, trifluoromethanesulfonic anhydride, trimethylsilyl trifluoroacetate, trimethylsilyl trifluoromethanesulfonate, dimethylsilyl trifluoroacetate, dimethylsilyl trifluoromethanesulfonate, butyldimethylsilyl trifluoroacetate, butyldimethylsilyl trifluoromethanesulfonate, hexyldimethylsilyl trifluoroacetate, hexyldimethylsilyl trifluoromethanesulfonate, octyldimethylsilyl trifluoroacetate, octyldimethylsilyl trifluoromethanesulfonate, decyldimethylsilyl trifluoroacetate, decyldimethylsilyl trifluoromethanesulfonate, dodecyldimethylsilyl trifluoroacetate and dodecyldimethylsilyl trifluoromethanesulfonate; or one consisting only of the mixture. Incidentally, at the time of preparing the liquid chemical for forming a water-repellent protective film by mixing the treatment liquid (A) and the treatment liquid (B), it is preferable mix the nonaqueous organic solvent, the silylation reagent and the acid in an amount of 76 to 99.8999 mass %, 0.1 to 20 mass % and 0.0001 to 4 mass %, respectively, relative to the total amount of 100 mass % of the liquid chemical after preparation.

The liquid chemical for forming a protective film and a liquid chemical kit for forming a protective film, according to the present invention may contain another additive and the like within a range not affecting the scope of the present invention. As the additive, it is possible to cite oxidizing agents such as hydrogen peroxide, ozone and the like, surfactants and the like.

In the liquid chemical obtained by the method of preparing a liquid chemical of the present invention or in the liquid chemical kit (a treatment liquid) obtained by the method of preparing a liquid chemical kit of the present invention, metal impurities and particles contained in the liquid chemical or the liquid chemical kit (the treatment liquid) may be eliminated by using a particle-eliminating membrane and an ion exchange resin membrane. Furthermore, the elimination of metal impurities and particles with use of the particle-eliminating membrane and the ion exchange resin membrane may be carried out at some time throughout the mixing step for the liquid chemical, the step of preparing a treatment liquid (A) for the liquid chemical and the step of preparing a treatment liquid (B) for the liquid chemical.

The liquid chemical for forming a protective film and the liquid chemical kit for forming a protective film, Obtained according to the present invention are required to be low in metal impurity concentration. Hence a portion brought into contact with a liquid (e.g. the liquid chemical, the treatment liquid (A), the treatment liquid (B) and a feedstock solvent) at the time of preparing the liquid chemical or the liquid chemical kit and exemplified by a pipe brought into contact with a liquid to lead the liquid, a mixing bath and a storage bath is preferably formed of a resinous material not causing metal elution. Concrete examples of the resinous material are high-density polyethylene (HDPE), high-density polypropylene (PP), nylon-6,6, tetrafluoroethylene (PTFE), a copolymer of tetrafluoroethylene and perfluoroalkylvinylether (PEA), polychlorotrifluoroethylene (PCTFE), ethylene chlorotrifluoroethylene copolymer (ECTFE), ethylene tetrafluoroethylene (ETFE), tetrafluoroethylene hexapropylene copolymer (FEP) and the like. In addition, a liquid (e.g. the liquid chemical, the treatment liquid (A), the treatment liquid (B) and a feedstock solvent) is sometimes refined by filtration through a particle-eliminating resinous membrane and an ion exchange resin membrane, at the time of preparing the liquid chemical or the liquid chemical kit. In this case, the charge electric potential of the liquid is sometimes increased by the contact between the liquid and the resin so as to increase the risk of causing static electricity disasters. Particularly in the case of a liquid containing a large amount of nonaqueous organic solvent, the charge electric potential tends to increase.

When conducting a discharge step of the present invention on the liquid (e.g. the liquid chemical, the treatment liquid (A), the treatment liquid (B) and a feedstock solvent) which is charged as above, the step is performed in such a manner as to bring the liquid into contact with an electrically conductive material which is grounded. The electrically conductive material can be exemplified by steel, cast iron, maraging steel, stainless steel, nickel and alloys thereof, cobalt and alloys thereof, aluminum, magnesium and alloys thereof, copper and alloys thereof, titanium, zirconium, tantalum, niobium and alloys thereof, lead and alloys thereof, noble metals such as gold, silver, platinum, palladium, rhodium, iridium, ruthenium and osmium and alloys thereof, diamond, glassy carbon and the like. The electrically conductive material is preferably one which is low in amount of metal elution into the liquid. For example, under such a condition that a charged liquid (e.g. a liquid chemical, a treatment liquid (A), a treatment liquid (B) and a feedstock solvent) is in contact with an electrically conductive material at 45° C. for 700 hours, an immersion test using the liquid and a test piece of the electrically conductive material. Then, the elution amount of each of the elements Na, Mg, K, Ca, Mn, Fe, Cu, Li, Al, Cr, Ni, Zn and Ag per unit area of the test piece in the immersion test is determined. The elution amount is converted into the concentration while adapting practical facility conditions (a contacting area formed between the liquid and the electrically conductive material and the throughput of the liquid) thereto. It is preferable to select an electrically conductive material in which the thus obtained concentration of each of the elements Na, Mg, K, Ca, Mn, Fe, Cu, Li, Al, Cr, Ni, Zn and Ag in the liquid is less than 0.01 mass ppb, or less than the minimum determination limit concerning elements having a minimum determination limit of not less than 0.01 mass ppb. The above-mentioned “less than the minimum determination limit” means a value less than a minimum determination limit, prescribed by a larger one of: a concentration obtained by determining a standard deviation among concentrations detected by six times of blank test measurement and multiplying the standard deviation by 10; and a concentration that corresponds to the response accounting for live times the noise of an inductively coupled plasma mass spectroscope. Furthermore, one having a higher electric conductivity is more preferable. In view of the above, it is particularly preferable that the electrically conductive material is stainless steel, gold, platinum, diamond, glassy carbon and the like.

As a method for bringing an electrically charged liquid (e.g. the liquid chemical, the treatment liquid (A), the treatment liquid (B) and a feedstock solvent) into contact with the electrically conductive material in the discharge step, it is possible to bring the liquid into contact with the electrically conductive material by disposing the electrically conductive material inside a pipe for leading the liquid (in such a manner as to put the electrically conductive material into the pipe), for example. Thus, a discharging method carried out in-line so as not to be contacted with the human body is preferable in view of safety. The time during which the liquid and the electrically conductive material are contacted is preferably long in view of reducing the charge electric potential; meanwhile, in view of metal elution associated with the electrically conductive material being corroded by the liquid, the contact time is preferably short. From the above viewpoint, the contact time is preferably 0.001 to 1 second, more preferably 0.01 to 0.1 second. It is also possible to dispose two or more sections where the electrically charged liquid and the electrically conductive material are contacted, at the time of preparing the liquid chemical or the liquid chemical kit.

### EXAMPLES

### Example 1

A first refinement step was performed by the so-called one-pass filtration system where propylene glycol monomethyl ether acetate (PGMEA) was permeated through an ion exchange resin membrane (ION CLEAN SL No. DFA1SRPESW44 produced by Pall Corporation, Surface area: 1100 cm², Number of filter: 1) and a particle-eliminating membrane having a particle-eliminating diameter of 0.05 μm (Optimizer D600 produced by Nihon. Entegris K.K., Surface area: 600 cm², Number of filter: 1) at a flow rate of 0.6 L/min one time, thereby eliminating metal impurities from the solvent. In a mixing step, 1000 g of hexamethyldisilazane as a silylation reagent [HMDS: (CH₃)₃SiNHSi(CH₃)₃] and 36 g of acid (trifluoroacetic anhydride [(CF₃CO)₂O]) as an agent for forming a water-repellent protective film were added to 18964 g of PGMEA of after the first refinement step. Furthermore, a second refinement step was conducted by one-pass filtration system where the liquid chemical of after the mixing step was permeated through an ion exchange resin membrane (ION CLEAN SL No. DFA1SRPESW44 produced by Pall Corporation, Surface area: 1100 cm², Number of filter: 2) and a particle-eliminating membrane having a particle-eliminating diameter of 0.05 μm (Optimizer D600 produced by Nihon Entegris K.K. Surface area: 600 cm², Number of filter: 2) at a flow rate of 0.3 L/min, thereby obtaining a liquid chemical for forming a protective film from which metal impurities and particles had been eliminated. The conditions for preparing the liquid chemical are shown in Table 1. As a result of measuring the metal impurity concentration of each of the elements Na, Mg, K, Ca, Mn, Fe, Cu, Li, Al, Cr, Ni, Zn and Ag relative to the total amount of the obtained liquid chemical by using an inductively coupled plasma mass spectroscope (Agilent 7500cs model produced by Yokogawa Analytical Systems Inc.), it was confirmed to be as follows: Na=0.02 mass ppb, Mg=less than 0.03 mass ppb, K=less than 0.03 mass ppb, Ca=less than 0.08 mass ppb, Mn=less than 0.001 mass ppb, Fe=0.02 mass ppb, Cu=0.005 mass ppb, Li=less than 0.001 mass ppb, Al=less than 0.03 mass ppb, Cr=less than 0.05 mass ppb, Ni=less than 0.002 mass ppb, Zn=less than 0.04 mass ppb and Ag=less than 0.004 mass ppb (wherein “less than” means a value less than a minimum determination limit prescribed by a larger one of: a concentration obtained by determining a standard deviation among concentrations detected by six times of blank test measurement and multiplying the standard deviation by 10; and a concentration that corresponds to the response accounting for five times the noise of an inductively coupled plasma mass spectroscope. As a result of conducting particle measurement in a liquid phase by a laser light-scattering type detector or measuring the number of particles of larger than 0.2 μm by using a laser light-scattering type measuring apparatus (KS-42AF model produced by RION Co., Ltd.), the number of particles of larger than 0.2 μm was 5 per 1 mL of the liquid chemical. The results of evaluating the obtained liquid chemical are shown in Table 2.

TABLE 1

| | | | | | Second or Third Refinement | | Remarks |
|---|---|---|---|---|---|---|---|
| | Silylation | | Embodi- | First Refinement Step | Step (Liquid Chemical | Preparation | (Number of |
| | Reagent | Solvent | ment | (Solvent Refinement Method) | Refinement Method) | Method | Filters) |
| Example 1 | HMDS | PGMEA | 1st | One-pass refinement using ion | One-pass refinement using ion | 1st | 1st Refinement: |
| | | | | exchange resin membrane and | exchange resin membrane and particle- | | 1 each |
| | | | | particle-eliminating membrane | eliminating membrane | | 2nd Refinement: |
| | | | | | | | 2 each |
| Example 2 | HMDS | PGMEA | 1st | Reduced-pressure distillation | One-pass refinement using ion | 1st | 2nd Refinement: |
| | | | | | exchange resin membrane and particle- | | 2 each |
| | | | | | eliminating membrane | | |
| Example 3 | TMSDMA | PGMEA | 1st | One-pass refinement using ion | One-pass refinement using ion | 1st | 1st Refinement: |
| | | | | exchange resin membrane and | exchange resin membrane and particle- | | 1 each |
| | | | | particle-eliminating membrane | eliminating membrane | | 2nd Refinement: |
| | | | | | | | 2 each |
| Example 4 | TMDS | PGMEA | 1st | One-pass refinement using ion | One-pass refinement using ion | 1st | 1st Refinement: |
| | | | | exchange resin membrane and | exchange resin membrane and particle- | | 1 each |
| | | | | particle-eliminating membrane | eliminating membrane | | 2nd Refinement: |
| | | | | | | | 2 each |
| Example 5 | TMDS | PGMEA | 1st | Reduced-pressure distillation | One-pass refinement using ion | 1st | 2nd Refinement: |
| | | | | | exchange resin membrane and particle- | | 2 each |
| | | | | | eliminating membrane | | |
| Example 6 | HMDS | PGMEA | 1st | One-pass refinement using ion | One-pass refinement using ion | 1st | 1st Refinement: |
| | | | | exchange resin membrane and | exchange resin membrane and particle- | | 2 each |
| | | | | particle-eliminating membrane | eliminating membrane | | 2nd Refinement: |
| | | | | | | | 4 each |
| Example 7 | HMDS | PGMEA | 1st | One-pass refinement using ion | One-pass refinement using ion | 1st | 1st Refinement: |
| | | | | exchange resin membrane and | exchange resin membrane and particle- | | 1 each |
| | | | | particle-eliminating membrane | eliminating membrane | | 2nd Refinement: |
| | | | | | | | 1 each |
| Example 8 | HMDS | PGMEA | 1st | — | Circulation refinement using ion | 2nd | 3rd Refinement: |
| | | | | | exchange resin membrane and particle- | | 2 each |
| | | | | | eliminating membrane | | |
| Example 9 | HMDS | PGMEA | 1st | — | Circulation refinement using ion | 2nd | 3rd Refinement: |
| | | | | | exchange resin membrane and particle- | | 4 each |
| | | | | | eliminating membrane | | |
| Comparative | HMDS | PGMEA | — | One-pass refinement using ion | — | — | 1st Refinement: |
| Example 1 | | | | exchange resin membrane and | | | 1 each |
| | | | | particle-eliminating membrane | | | |
| Comparative | HMDS | PGMEA | — | — | — | — | — |
| Example 2 | | | | | | | |

TABLE 2

| | | | | | | | | | | | | | | Number of |
|---|---|---|---|---|---|---|---|---|---|---|---|---|---|---|
| | Metal impurity Concentration (mass ppb) | | | | | | | | | | | | | Particles |
| | Na | Mg | K | Ca | Mn | Fe | Cu | Li | Al | Cr | Ni | Zn | Ag | (per 1 mL) |
| Example 1 | 0.02 | <0.03 | <0.03 | <0.08 | <0.001 | 0.02 | 0.005 | <0.001 | <0.03 | <0.05 | <0.002 | <0.04 | <0.004 | 5 |
| Example 2 | 0.04 | <0.03 | <0.03 | <0.08 | <0.001 | 0.04 | 0.02 | <0.001 | <0.03 | <0.05 | <0.002 | <0.04 | <0.004 | 12 |
| Example 3 | 0.02 | <0.03 | <0.03 | <0.08 | <0.001 | 0.02 | <0.003 | <0.001 | <0.03 | <0.05 | <0.002 | <0.04 | <0.004 | 7 |
| Example 4 | 0.02 | <0.03 | <0.03 | <0.08 | <0.001 | 0.02 | <0.003 | <0.001 | <0.03 | <0.05 | <0.002 | <0.04 | <0.004 | 8 |
| Example 5 | 0.04 | <0.03 | <0.03 | <0.08 | <0.001 | 0.04 | 0.025 | <0.001 | <0.03 | <0.05 | <0.002 | <0.04 | <0.004 | 15 |
| Example 6 | <0.02 | <0.03 | <0.03 | <0.08 | <0.001 | <0.02 | <0.003 | <0.001 | <0.03 | <0.05 | <0.002 | <0.04 | <0.004 | 4 |
| Example 7 | 0.04 | <0.03 | <0.03 | <0.08 | <0.001 | 0.03 | 0.016 | <0.001 | <0.03 | <0.05 | <0.002 | <0.04 | <0.004 | 6 |
| Example 8 | 0.08 | <0.03 | 0.08 | <0.08 | 0.003 | 0.09 | 0.012 | <0.001 | <0.03 | <0.05 | <0.002 | <0.04 | <0.004 | 5 |
| Example 9 | 0.06 | <0.03 | 0.06 | <0.08 | <0.001 | 0.07 | 0.009 | <0.001 | <0.03 | <0.05 | <0.002 | <0.04 | <0.004 | 4 |
| Comparative | 0.06 | <0.03 | 0.05 | <0.08 | <0.001 | 0.07 | 0.008 | <0.001 | <0.03 | <0.05 | <0.002 | <0.04 | <0.004 | 240 |
| Example 1 | | | | | | | | | | | | | | |
| Comparative | 0.58 | 0.12 | 0.28 | 0.37 | 0.024 | 0.42 | 0.078 | 0.007 | <0.03 | 0.06 | 0.008 | <0.04 | <0.004 | 800 |
| Example 2 | | | | | | | | | | | | | | |

### Example 2

The procedure of Example 1 was repeated with the exception that the first refinement step was carried out by distilling PGMEA under a condition of 80° C. and under a reduced pressure of 10 kPa to eliminate metal impurities the solvent, thereby obtaining a liquid chemical for forming a protective film. The conditions for preparing the liquid chemical are shown in Table 1 and the results of evaluating the obtained liquid chemical are shown in Table 2.

### Examples 3-5

The agent for forming a water-repellent protective film used in Example 1 and the first refinement step conducted in Example 1 were modified thereby obtaining a liquid chemical for forming a protective film. Incidentally, “Reduced-pressure distillation” indicated in Tables means the same operations as the reduced-pressure distillation conducted in Example 2. The conditions for preparing the liquid chemical are shown in Table 1 and the results of evaluating the obtained liquid chemical are shown in Table 2.

By the way, “TMSDMA” means trimethylsilyl dimethylamine [(CH₃)₃SiN(CH₃)₂], and “TMDS” means tetramethyldisilazane [(CH₃)₂Si(H)NHSi(H)(CH₃)₂].

### Example 6

The procedure of Example 1 was repeated with the exception that an ion exchange resin membrane (ION CLEAN SL No. DFA1SRPESW44 produced by Pall Corporation, Surface area: 1100 cm². Number of filter: 2) and a particle-eliminating membrane having a particle-eliminating diameter of 0.05 μm (Optimizer D600 produced by Nihon Entegris K.K., Surface area: 600 cm², Number of capsule filter: 2) were used in the first refinement step while an ion exchange resin membrane (ION CLEAN SL No. DFA1SRPESW44 produced by Pall Corporation, Surface area: 1100 cm². Number of filter: 4) and a particle-eliminating membrane having a particle-eliminating diameter of 0.05 μm (Optimizer D600 produced by Nihon. Entegris K.K., Surface area: 600 cm², Number of filter: 4) were used in the second refinement step, thereby obtaining a liquid chemical for forming a protective film. The conditions for preparing the liquid chemical are shown in Table 1 and the results of evaluating the obtained liquid chemical are shown in Table 2.

### Example 7

The procedure of Example 1 was repeated with the exception that an ion exchange resin membrane (ION CLEAN SL No. DFA1SRPESW44 produced by Pall Corporation, Surface area: 1100 cm², Number of filter: 1) and a particle-eliminating membrane having a particle-eliminating diameter of 0.05 μm (Optimizer D600 produced by Nihon Entegris K.K., Surface area: 600 cm², Number of filter: 1) were used in the second refinement step, thereby obtaining a liquid chemical for forming a protective film. The conditions for preparing the liquid chemical are shown in Table 1 and the results of evaluating the Obtained liquid chemical are shown in Table 2.

### Example 8

The first refinement step of Example 1 was not performed. In a third refinement step, a liquid chemical of after the mixing step was refined by being permeated through the same ion exchange resin membrane and particle-eliminating membrane as those used in the second refinement step of Example 1. However, metal impurities contained in the liquid chemical were not sufficiently eliminated only by permeating the liquid through one-pass system; therefore the liquid chemical was circulated to be permeated through the membrane two or more times, thereby eliminating the metal impurities sufficiently from the liquid chemical. With the exception of the above, the procedure of Example 1 was repeated thereby obtaining a liquid chemical for forming a protective film from which metal impurities and particles have been eliminated. The conditions for preparing the liquid chemical are shown in Table 1 and the results of evaluating the obtained liquid chemical are shown in Table 2.

### Example 9

The procedure of Example 8 was repeated with the exception that an ion exchange resin membrane (ION CLEAN SL No. DFA1SRPESW44 produced by Pall Corporation, Surface area: 1100 cm², Number of filter: 4) and a particle-eliminating membrane having a particle-eliminating diameter of 0.05 μm (Optimizer D600 produced by Nihon. Entegris K.K. Surface area: 600 cm², Number of filter: 4) were used in the third refinement step, thereby obtaining a liquid chemical for forming a protective film. The conditions for preparing the liquid chemical are shown in Table 1 and the results of evaluating the obtained liquid chemical are shorn in Table 2.

### Comparative Example 1

The procedure of Example 1 was repeated with the exception that the second refinement step was not performed, thereby obtaining a liquid chemical for forming a protective film. The conditions for preparing the liquid chemical are shown in Table 1 and the results of evaluating the obtained liquid chemical are shown in Table 2.

### Comparative Example 2

The procedure of Example 1 was repeated with the exception that the first and second refinement step were not performed, thereby obtaining a liquid chemical for forming a protective film. The conditions for preparing the liquid chemical are shown in Table 1 and the results of evaluating the obtained liquid chemical are shown in Table 2.

### Example 10

A first refinement step was performed by one-pass filtration system where isopropanol (iPA) was permeated through an ion exchange resin membrane (ION CLEAN SL No. DFA1SRPESW44 produced by Pall Corporation, Surface area: 1100 cm², Number of filter: 1) and a particle-eliminating membrane having a particle-eliminating diameter of 0.05 μm (Optimizer D600 produced by Nihon Entegris K.K., Surface area: 600 cm², Number of filter: 1) at a flow rate of 0.6 L/min, thereby eliminating metal impurities from the solvent. Likewise, a first refinement step was performed by one-pass filtration system where diethylene glycol monoethyl ether acetate (DGEEA) was permeated through an ion exchange resin membrane (ION CLEAN SL No. DEA1SRPESW44 produced by Pall Corporation, Surface area: 1100 cm², Number of filter: 1) and a particle-eliminating membrane having a particle-eliminating diameter of 0.05 μm (Optimizer D600 produced by Nihon. Entegris K.K., Surface area: 600 cm², Number of filter: 1) at a flow rate of 0.6 L/min, thereby eliminating metal impurities from the solvent. In a mixing step, 9 g of iPA of after the first refinement step, 9990 g of DGEEA of after the first refinement step and 1 g of 2-(perfluorohexyl)ethyl phosphonic acid. [FHEPA: CF₃(CF₂)₅(CH₂)₂P(O)(OH)₂] as an agent for forming a water-repellent protective film were mixed. Furthermore, a second refinement step was conducted by one-pass filtration system where the liquid chemical of after the mixing step was permeated through an ion exchange resin membrane (ION CLEAN SL No. DFA1SRPESW44 produced by Pall Corporation, Surface area 1100 cm², Number of filter: 2) and a particle-eliminating membrane having a particle-eliminating diameter of 0.05 μm (Optimizer D600 produced by Nihon Entegris K.K., Surface area: 600 cm², Number of filter: 2) at a flow rate of 0.3 thereby obtaining a liquid chemical for forming a protective film from which metal impurities and particles had been eliminated. The conditions for preparing the liquid chemical are shown in Table 3 and the results of evaluating the obtained liquid, chemical are shown in Table 4.

TABLE 3

| | | | | | Second or Third Refinement | | Remarks |
|---|---|---|---|---|---|---|---|
| | Silylation | | Embodi- | First Refinement Step | Step (Liquid Chemical | Preparation | (Number of |
| | Reagent | Solvent | ment | (Solvent Refinement Method) | Refinement Method) | Method | Filters) |
| Example 10 | FHEPA | IPA | 2nd | One-pass refinement using ion | One-pass refinement using ion | 1st | 1st Refinement: |
| | | DGEEA | | exchange resin membrane and | exchange resin membrane and | | 1 each |
| | | | | particle-eliminating membrane | particle-eliminating membrane | | 2nd Refinement: |
| | | | | | | | 2 each |
| Example 11 | FHEPA | IPA | 2nd | Atmospheric-pressure distillation | One-pass refinement using ion | 1st | 2nd Refinement: |
| | | DGEEA | | (IPA) | exchange resin membrane and | | 2 each |
| | | | | Reduced-pressure distillation | particle-eliminating membrane | | |
| | | | | (DGEEA) | | | |
| Example 12 | FHEPA | PGME | 2nd | One-pass refinement using ion | One-pass refinement using ion | 1st | 1st Refinement: |
| | | DGEEA | | exchange resin membrane and | exchange resin membrane and | | 1 each |
| | | | | particle-eliminating membrane | particle-eliminating membrane | | 2nd Refinement: |
| | | | | | | | 2 each |
| Example 13 | FHEPA | Water | 2nd | One-pass refinement using ion | One-pass refinement using ion | 1st | 1st Refinement: |
| | | DGEEA | | exchange resin membrane and | exchange resin membrane and | | 1 each |
| | | | | particle-eliminating membrane | particle-eliminating membrane | | 2nd Refinement: |
| | | | | | | | 2 each |
| Example 14 | FHEPA | IPA | 2nd | One-pass refinement using ion | One-pass refinement using ion | 1st | 1st Refinement: |
| | | PGDA | | exchange resin membrane and | exchange resin membrane and | | 1 each |
| | | | | particle-eliminating membrane | particle-eliminating membrane | | 2nd Refinement: |
| | | | | | | | 2 each |
| Example 15 | FHEPA | IPA | 2nd | One-pass refinement using ion | One-pass refinement using ion | 1st | 1st Refinement: |
| | | DPGMEA | | exchange resin membrane and | exchange resin membrane and | | 1 each |
| | | | | particle-eliminating membrane | particle-eliminating membrane | | 2nd Refinement: |
| | | | | | | | 2 each |
| Example 16 | FHEPA | IPA | 2nd | One-pass refinement using ion | One-pass refinement using ion | 1st | 1st Refinement: |
| | | 13BGDA | | exchange resin membrane and | exchange resin membrane and | | 1 each |
| | | | | particle-eliminating membrane | particle-eliminating membrane | | 2nd Refinement: |
| | | | | | | | 2 each |
| Example 17 | OPA | IPA | 2nd | One-pass refinement using ion | One-pass refinement using ion | 1st | 1st Refinement: |
| | | DGEEA | | exchange resin membrane and | exchange resin membrane and | | 1 each |
| | | | | particle-eliminating membrane | particle-eliminating membrane | | 2nd Refinement: |
| | | | | | | | 2 each |
| Example 18 | FHEPA | IPA | 2nd | One-pass refinement using ion | One-pass refinement using ion | 1st | 1st Refinement: |
| | | DGEEA | | exchange resin membrane and | exchange resin membrane and | | 2 each |
| | | | | particle-eliminating membrane | particle-eliminating membrane | | 2nd Refinement: |
| | | | | | | | 4 each |
| Example 19 | FHEPA | IPA | 2nd | One-pass refinement using ion | One-pass refinement using ion | 1st | 1st Refinement: |
| | | DGEEA | | exchange resin membrane and | exchange resin membrane and | | 1 each |
| | | | | particle-eliminating membrane | particle-eliminating membrane | | 2nd Refinement: |
| | | | | | | | 1 each |
| Example 20 | FHEPA | IPA | 2nd | — | Circulation refinement using ion | 2nd | 3rd Refinement: |
| | | DGEEA | | | exchange resin membrane and | | 2 each |
| | | | | | particle-eliminating membrane | | |
| Example 21 | FHEPA | IPA | 2nd | — | Circulation refinement using ion | 2nd | 3rd Refinement: |
| | | DGEEA | | | exchange resin membrane and | | 4 each |
| | | | | | particle-eliminating membrane | | |
| Example 22 | ED-200 | IPA | 2nd | One-pass refinement using ion | One-pass refinement using ion | 1st | 1st Refinement: |
| | | DGEEA | | exchange resin membrane and | exchange resin membrane and | | 1 each |
| | | | | particle-eliminating membrane | particle-eliminating membrane | | 2nd Refinement: |
| | | | | | | | 2 each |
| Comparative | FHEPA | IPA | — | One-pass refinement using ion | — | — | 1st Refinement: |
| Example 3 | | DGEEA | | exchange resin membrane and | | | 1 each |
| | | | | particle-eliminating membrane | | | |
| Comparative | FHEPA | IPA | — | — | — | — | — |
| Example 4 | | DGEEA | | | | | |

TABLE 4

| | | | | | | | | | | | | | | Number of |
|---|---|---|---|---|---|---|---|---|---|---|---|---|---|---|
| | Metal impurity Concentration (mass ppb) | | | | | | | | | | | | | Particles |
| | Na | Mg | K | Ca | Mn | Fe | Cu | Li | Al | Cr | Ni | Zn | Ag | (per 1 mL) |
| Example 10 | 0.04 | <0.03 | <0.03 | <0.08 | <0.001 | 0.03 | <0.003 | <0.001 | <0.03 | <0.05 | <0.002 | <0.04 | <0.004 | 6 |
| Example 11 | 0.05 | <0.03 | <0.03 | <0.08 | <0.001 | 0.04 | <0.003 | <0.001 | <0.03 | <0.05 | <0.002 | <0.04 | <0.004 | 16 |
| Example 12 | 0.02 | <0.03 | <0.03 | <0.08 | <0.001 | 0.02 | <0.003 | <0.001 | <0.03 | <0.05 | <0.002 | <0.04 | <0.004 | 8 |
| Example 13 | 0.02 | <0.03 | <0.03 | <0.08 | <0.001 | 0.02 | <0.003 | <0.001 | <0.03 | <0.05 | <0.002 | <0.04 | <0.004 | 4 |
| Example 14 | 0.02 | <0.03 | <0.03 | <0.08 | <0.001 | 0.02 | <0.003 | <0.001 | <0.03 | <0.05 | <0.002 | <0.04 | <0.004 | 3 |
| Example 15 | 0.02 | <0.03 | <0.03 | <0.08 | <0.001 | 0.02 | <0.003 | <0.001 | <0.03 | <0.05 | <0.002 | <0.04 | <0.004 | 9 |
| Example 16 | 0.03 | <0.03 | <0.03 | <0.08 | <0.001 | 0.03 | <0.003 | <0.001 | <0.03 | <0.05 | <0.002 | <0.04 | <0.004 | 11 |
| Example 17 | 0.02 | <0.03 | <0.03 | <0.08 | <0.001 | 0.02 | <0.003 | <0.001 | <0.03 | <0.05 | <0.002 | <0.04 | <0.004 | 5 |
| Example 18 | 0.02 | <0.03 | <0.03 | <0.08 | <0.001 | <0.02 | <0.003 | <0.001 | <0.03 | <0.05 | <0.002 | <0.04 | <0.004 | 5 |
| Example 19 | 0.06 | <0.03 | 0.04 | <0.08 | <0.001 | 0.05 | <0.003 | <0.001 | <0.03 | <0.05 | <0.002 | <0.04 | <0.004 | 9 |
| Example 20 | 0.08 | <0.03 | 0.08 | 0.08 | 0.005 | 0.07 | 0.027 | <0.001 | <0.03 | <0.05 | <0.002 | <0.04 | <0.004 | 7 |
| Example 21 | 0.07 | <0.03 | 0.07 | <0.08 | 0.003 | 0.05 | 0.019 | <0.001 | <0.03 | <0.05 | <0.002 | <0.04 | <0.004 | 9 |
| Example 22 | 0.04 | <0.03 | <0.03 | <0.08 | <0.001 | 0.03 | <0.003 | <0.001 | <0.03 | <0.05 | <0.002 | <0.04 | <0.004 | 7 |
| Comparative | 0.07 | <0.03 | 0.06 | <0.08 | 0.002 | 0.06 | 0.018 | <0.001 | <0.03 | <0.05 | <0.002 | <0.04 | <0.004 | 360 |
| Example 3 | | | | | | | | | | | | | | |
| Comparative | 0.56 | 0.25 | 0.3 | 0.38 | 0.021 | 0.38 | 0.091 | <0.001 | <0.03 | 0.07 | <0.002 | <0.04 | <0.004 | 900 |
| Example 4 | | | | | | | | | | | | | | |

### Example 11

The first refinement step was carried out by distilling iPA under a condition of 120° C. and 760 kPa under atmospheric pressure to eliminate metal impurities from the solvent. Likewise, the first refinement step was carried out by distilling DGEEA under a condition of 160° C. and under a reduced pressure of 5 kPa to eliminate metal impurities from the solvent. In a mixing step, 9 g of iPA of after the first refinement step, 9990 g of DGEEA of after the first refinement step and 1 g of FHEPA as an agent for forming a water-repellent protective film were mixed. Furthermore, a second refinement step was conducted by one-pass filtration system where the liquid chemical of after the mixing step was permeated through an ion exchange resin membrane (ION CLEAN SL No. DFA1SRPESW44 produced by Pall Corporation, Surface area: 1100 cm², Number of filter: 2) and a particle-eliminating membrane having a particle-eliminating diameter of 0.05 μm (Optimizer D600 produced by Nihon Entegris K.K., Surface area: 600 cm², Number of filter: 2) at a flow rate of 0.3 L/min, thereby obtaining a liquid chemical for forming a protective film from which metal impurities and particles had been eliminated. The conditions for preparing the liquid chemical are shown in Table 3 and the results of evaluating the obtained liquid chemical are shown in Table 4.

### Examples 12-17

The agent for forming a water-repellent protective film and the solvents, used in Example 10 were modified thereby obtaining a liquid chemical for forming a protective film. The conditions for preparing the liquid chemical are shown in Table 3 and the results of evaluating the obtained liquid chemical are shown in Table 4.

Incidentally, “PGME” means propylene glycol monomethyl ether, “PGDA” means propylene glycol diacetate, “DPGMEA” means dipropylene glycol monomethyl ether acetate, “13BGDA” means 1,3-butylene glycol diacetate, and “OPA” means octylphosphonic acid. In the case where two kinds of solvents were used, it can be known from the section “Solvent” of the table that one indicated in the upper line was used in an amount of 9 g and the other indicated in the lower line was used in an amount of 9990 g.

### Example 18

The procedure of Example 10 was repeated with the exception that an ion exchange resin membrane (ION CLEAN SL No. DFA1SRPESW44 produced by Pall Corporation, Surface area: 1100 cm², Number of filter: 2) and a particle-eliminating membrane having a particle-eliminating diameter of 0.05 μm (Optimizer D600 produced by Nihon Entegris K.K., Surface area: 600 cm², Number of capsule filter: 2) were used in the first refinement step while an ion exchange resin membrane (ION CLEAN SL No. DFA1SRPESW44 produced by Pall Corporation, Surface area: 1100 cm², Number of filter: 4) and a particle-eliminating membrane having a particle-eliminating diameter of 0.05 μm (Optimizer D600 produced by Nihon Entegris K.K. Surface area: 600 cm², Number of filter: 4) were used in the second refinement step, thereby obtaining a liquid chemical for forming a protective film. The conditions for preparing the liquid chemical are shown in Table 3 and the results of evaluating the obtained liquid chemical are shown in Table 4.

### Example 19

The procedure of Example 10 was repeated with the exception that an ion exchange resin membrane (ION CLEAN SL No. DFA1SRPESW44 produced by Pall Corporation, Surface area: 1100 cm², Number of filter: 1) and a particle-eliminating membrane having a particle-eliminating diameter of 0.05 μm (Optimizer D600 produced by Nihon Entegris K.K., Surface area: 600 cm², Number of filter: 1) were used in the second refinement step, thereby obtaining a liquid chemical for forming a protective film. The conditions for preparing the liquid chemical are shown in Table 3 and the results of evaluating the obtained liquid chemical are shown in Table 4.

### Example 20

The first refinement step of Example 10 was not performed. In a third refinement step, a liquid chemical of after the mixing step was refined by being permeated through the same ion exchange resin membrane and particle-eliminating membrane as those used in the second refinement step of Example 10. However, metal impurities contained in the liquid chemical were not sufficiently eliminated only by permeating the liquid through one-pass system; therefore the liquid chemical was circulated to be permeated through the membrane two or more times, thereby eliminating the metal impurities sufficiently from the liquid chemical. With the exception of the above, the procedure of Example 10 was repeated thereby obtaining a liquid chemical for forming a protective film from which metal impurities and particles have been eliminated. The conditions for preparing the liquid chemical are shown in Table 3 and the results of evaluating the obtained liquid chemical are shown in Table 4.

### Example 21

The procedure of Example 20 was repeated with the exception that an ion exchange resin membrane (ION CLEAN SL No. DFA1SRPESW44 produced by Pall Corporation, Surface area: 1100 cm², Number of filter: 4) and a particle-eliminating membrane having a particle-eliminating diameter of 0.05 μm (Optimizer D600 produced by Nihon Entegris K.K., Surface area: 600 cm², Number of filter: 4) were used in the third refinement step, thereby obtaining a liquid chemical for forming a protective film. The conditions for preparing the liquid chemical are shown in Table 3 and the results of evaluating the Obtained liquid chemical are shown in Table 4.

### Example 22

The procedure of Example 10 was repeated with the exception that polyoxyethylene octyl ether phosphate ED-200 (a mixture of C₈H₁₇OC₂H₄OP(═O)(OH)₂ and {C₈H₁₇OC₂H₄O}₂P(═O)OH, produced by TOHO Chemical Industry Co., Ltd.) was used as the agent for forming a water-repellent protective film, thereby obtaining a liquid chemical for forming a protective film. The conditions for preparing the Liquid chemical are shown in Table 3 and the results of evaluating the obtained liquid chemical are shown in Table 4.

### Comparative Example 3

The procedure of Example 10 was repeated with the exception that the second refinement step was not performed, thereby obtaining a liquid chemical far forming a protective film. The conditions for preparing the liquid chemical are shown in Table 3 and the results of evaluating the obtained liquid chemical are shown in Table 4.

### Comparative Example 4

The procedure of Example 10 was repeated with the exception that the first and second refinement step were not performed, thereby obtaining a liquid chemical for forming a protective film. The conditions for preparing the liquid chemical are shown in Table 3 and the results of evaluating the obtained liquid chemical are shown in Table 4.

### Example 23

A fourth refinement step was performed by one-pass filtration system where PGMEA was permeated through an ion exchange resin membrane (ION CLEAN Si, No. DFA1SRPESW44 produced by Pall Corporation, Surface area: 1100 cm², Number of filter: 1) and a particle-eliminating membrane having a particle-eliminating diameter of 0.05 μm (Optimizer D600 produced by Nihon Entegris K.K., Surface area: 600 cm², Number of filter: 1) at a flow rate of 0.6 L/min, thereby eliminating metal impurities from the nonaqueous organic solvent. In a step of preparing a treatment liquid (A), 9000 g of PGMEA of after the fourth refinement step and 1000 g of octyl(dimethyl)dimethylaminosilane [ODMAS: C₈H₁₇(CH₃)₂Si—N(CH₃)₂] as a silylation reagent were mixed. Furthermore, a fifth refinement step was conducted by one-pass filtration system where the treatment liquid (A) of after the mixing step was permeated through an ion exchange resin membrane (ION CLEAN SL No. DFA1SRPESW44 produced by Pall Corporation, Surface area: 1100 cm², Number of filter: 2) and a particle-eliminating membrane having a particle-eliminating diameter of 0.05 μm (Optimizer D600 produced by Nihon Entegris K.K., Surface area: 600 cm², Number of filter: 2) at a flow rate of 0.3 L/min, thereby obtaining a treatment liquid (A) from which metal impurities and particles had been eliminated. In a step of preparing a treatment liquid (B), 9712 g of PGMEA of after the fourth refinement step and 288 g of trifluoroacetic anhydride [(CF₃CO)₂O]) as acid were mixed. Furthermore, a fifth refinement step was conducted by one-pass filtration system where the treatment liquid (B) of after the mixing step was permeated through an ion exchange resin membrane (ION CLEAN SL No. DFA1SRPESW44 produced by Pall Corporation, Surface area: 1100 cm², Number of filter: 2) and a particle-eliminating membrane having a particle-eliminating diameter of 0.05 μm (Optimizer D600 produced by Nihon Entegris K.K., Surface area: 600 cm², Number of filter: 2) at a flow rate of 0.3 L/min, thereby obtaining a treatment liquid (B) from which metal impurities and particles had been eliminated. Then, 1000 g of the treatment liquid (A) and 1000 g of the treatment liquid (B) were mixed thereby obtaining a liquid chemical for forming a water-repellent protective film. The conditions for preparing the treatment liquids (A) and (B) are shown in Table 5 and the results of evaluating the obtained treatment liquids (A) and (B) and liquid chemical are shown in Table 6.

TABLE 5

| | | Nonaqueous Organic | | | | | |
|---|---|---|---|---|---|---|---|
| | | Solvent | | Fourth Refinement Step | Fifth or Sixth Refinement Step | | Remarks |
| | Silylation | Treatment | Treatment | (Nonaqueous Organic Solvent | (Treatment Liquid Refinement | Preparation | (Number of |
| | Reagent | Liquid (A) | Liquid (B) | Refinement Method) | Method) | Method | Filters) |
| Example 23 | ODMAS | PGMEA | PGMEA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 24 | ODMAS | PGMEA | PGMEA | Reduced-pressure distillation | One-pass refinement using ion | 3rd | 5th Refinement: |
| | | | | | exchange resin membrane and | | 2 each |
| | | | | | particle-eliminating membrane | | |
| Example 25 | ODMAS | DGEEA | DGEEA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 26 | ODMAS | PGDA | PGDA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 27 | ODMAS | DPGMEA | DPGMEA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 28 | ODMAS | DPGMPE | DPGMPE | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 29 | ODMAS | 13BGDA | 13BGDA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 30 | ODMAS | 14BGDA | 14BGDA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 31 | ODMAS | 14BGDA | 14BGDA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 32 | ODMAS | PGMEA | GBL | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 33 | BDMAS | PGDA | PGDA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 34 | DOTMDS | PGDA | PGDA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 2 each |
| Example 35 | ODMAS | PGMEA | PGMEA | One-pass refinement using ion | One-pass refinement using ion | 3rd | 4th Refinement: |
| | | | | exchange resin membrane and | exchange resin membrane and | | 2 each |
| | | | | particle-eliminating membrane | particle-eliminating membrane | | 5th Refinement: |
| | | | | | | | 4 each |
| Example 36 | ODMAS | PGMEA | PGMEA | One-pass refinement using ion | One-pass refinement using ion | 3rd | 4th Refinement: |
| | | | | exchange resin membrane and | exchange resin membrane and | | 1 each |
| | | | | particle-eliminating membrane | particle-eliminating membrane | | 5th Refinement: |
| | | | | | | | 1 each |
| Example 37 | ODMAS | PGMEA | PGMEA | — | Circulation refinement using ion | 4th | 6th Refinement: |
| | | | | | exchange resin membrane and | | 2 each |
| | | | | | particle-eliminating membrane | | |
| Example 38 | ODMAS | PGMEA | PGMEA | — | Circulation refinement using ion | 4th | 6th Refinement: |
| | | | | | exchange resin membrane and | | 4 each |
| | | | | | particle-eliminating membrane | | |
| Comparative | ODMAS | PGMEA | PGMEA | One-pass refinement using ion | — | — | 4th Refinement: |
| Example 5 | | | | exchange resin membrane and | | | 1 each |
| | | | | particle-eliminating membrane | | | |
| Comparative | ODMAS | PGMEA | PGMEA | — | — | — | — |
| Example 6 | | | | | | | |

TABLE 6

| | | | | | | | | | | | | | | | Number of |
|---|---|---|---|---|---|---|---|---|---|---|---|---|---|---|---|
| | | Metal impurity Concentration (mass ppb) | | | | | | | | | | | | | Particles |
| | | Na | Mg | K | Ca | Mn | Fe | Cu | Li | Al | Cr | Ni | Zn | Ag | (per 1 mL) |
| Example | Treatment Liquid (A) | 0.05 | <0.03 | <0.03 | <0.08 | <0.001 | 0.03 | <0.003 | <0.001 | <0.03 | <0.05 | <0.002 | <0.04 | <0.004 | 4 |
| 23 | Treatment Liquid (B) | 0.03 | <0.03 | <0.03 | <0.08 | <0.001 | 0.04 | <0.003 | <0.001 | <0.03 | <0.05 | <0.002 | <0.04 | <0.004 | 6 |
| | Liquid Chemical | 0.04 | <0.03 | <0.03 | <0.08 | <0.001 | 0.04 | <0.003 | <0.001 | <0.03 | <0.05 | <0.002 | <0.04 | <0.004 | 6 |
| Example | Treatment Liquid (A) | 0.07 | <0.03 | <0.03 | 0.08 | <0.001 | 0.05 | <0.003 | <0.001 | <0.03 | <0.05 | <0.002 | <0.04 | <0.004 | 21 |
| 24 | Treatment Liquid (B) | 0.03 | <0.03 | <0.03 | <0.08 | <0.001 | 0.03 | <0.003 | <0.001 | <0.03 | <0.05 | <0.002 | <0.04 | <0.004 | 17 |
| | Liquid Chemical | 0.05 | <0.03 | <0.03 | <0.08 | <0.001 | 0.04 | <0.003 | <0.001 | <0.03 | <0.05 | <0.002 | <0.04 | <0.004 | 20 |
| Example | Treatment Liquid (A) | 0.06 | <0.03 | <0.03 | <0.08 | <0.001 | 0.04 | <0.003 | <0.001 | <0.03 | <0.05 | <0.002 | <0.04 | <0.004 | 8 |
| 25 | Treatment Liquid (B) | 0.03 | <0.03 | <0.03 | <0.08 | <0.001 | 0.04 | <0.003 | <0.001 | <0.03 | <0.05 | <0.002 | <0.04 | <0.004 | 6 |
| | Liquid Chemical | 0.04 | <0.03 | <0.03 | <0.08 | <0.001 | 0.04 | <0.003 | <0.001 | <0.03 | <0.05 | <0.002 | <0.04 | <0.004 | 7 |
| Example | Treatment Liquid (A) | 0.05 | <0.03 | <0.03 | <0.08 | <0.001 | 0.05 | <0.003 | <0.001 | <0.03 | <0.05 | <0.002 | <0.04 | <0.004 | 12 |
| 26 | Treatment Liquid (B) | 0.03 | <0.03 | <0.03 | <0.08 | <0.001 | 0.03 | <0.003 | <0.001 | <0.03 | <0.05 | <0.002 | <0.04 | <0.004 | 17 |
| | Liquid Chemical | 0.04 | <0.03 | <0.03 | <0.08 | <0.001 | 0.04 | <0.003 | <0.001 | <0.03 | <0.05 | <0.002 | <0.04 | <0.004 | 15 |
| Example | Treatment Liquid (A) | 0.05 | <0.03 | <0.03 | <0.08 | <0.001 | 0.03 | <0.003 | <0.001 | <0.03 | <0.05 | <0.002 | <0.04 | <0.004 | 9 |
| 27 | Treatment Liquid (B) | 0.03 | <0.03 | <0.03 | <0.08 | <0.001 | 0.04 | <0.003 | <0.001 | <0.03 | <0.05 | <0.002 | <0.04 | <0.004 | 17 |
| | Liquid Chemical | 0.04 | <0.03 | <0.03 | <0.08 | <0.001 | 0.04 | <0.003 | <0.001 | <0.03 | <0.05 | <0.002 | <0.04 | <0.004 | 14 |
| Example | Treatment Liquid (A) | 0.04 | <0.03 | <0.03 | <0.08 | <0.001 | 0.03 | <0.003 | <0.001 | <0.03 | <0.05 | <0.002 | <0.04 | <0.004 | 5 |
| 28 | Treatment Liquid (B) | 0.03 | <0.03 | <0.03 | <0.08 | <0.001 | 0.03 | <0.003 | <0.001 | <0.03 | <0.05 | <0.002 | <0.04 | <0.004 | 18 |
| | Liquid Chemical | 0.04 | <0.03 | <0.03 | <0.08 | <0.001 | 0.03 | <0.003 | <0.001 | <0.03 | <0.05 | <0.002 | <0.04 | <0.004 | 12 |
| Example | Treatment Liquid (A) | 0.04 | <0.03 | <0.03 | <0.08 | <0.001 | 0.04 | <0.003 | <0.001 | <0.03 | <0.05 | <0.002 | <0.04 | <0.004 | 10 |
| 29 | Treatment Liquid (B) | 0.04 | <0.03 | <0.03 | <0.08 | <0.001 | 0.03 | <0.003 | <0.001 | <0.03 | <0.05 | <0.002 | <0.04 | <0.004 | 16 |
| | Liquid Chemical | 0.04 | <0.03 | <0.03 | <0.08 | <0.001 | 0.04 | <0.003 | <0.001 | <0.03 | <0.05 | <0.002 | <0.04 | <0.004 | 14 |
| Example | Treatment Liquid (A) | 0.06 | <0.03 | <0.03 | <0.08 | <0.001 | 0.04 | <0.003 | <0.001 | <0.03 | <0.05 | <0.002 | <0.04 | <0.004 | 10 |
| 30 | Treatment Liquid (B) | 0.04 | <0.03 | <0.03 | <0.08 | <0.001 | 0.04 | <0.003 | <0.001 | <0.03 | <0.05 | <0.002 | <0.04 | <0.004 | 16 |
| | Liquid Chemical | 0.05 | <0.03 | <0.03 | <0.08 | <0.001 | 0.04 | <0.003 | <0.001 | <0.03 | <0.05 | <0.002 | <0.04 | <0.004 | 14 |
| Example | Treatment Liquid (A) | 0.06 | <0.03 | <0.03 | <0.08 | <0.001 | 0.04 | <0.003 | <0.001 | <0.03 | <0.05 | <0.002 | <0.04 | <0.004 | 12 |
| 31 | Treatment Liquid (B) | 0.04 | <0.03 | <0.03 | <0.08 | <0.001 | 0.03 | <0.003 | <0.001 | <0.03 | <0.05 | <0.002 | <0.04 | <0.004 | 19 |
| | Liquid Chemical | 0.05 | <0.03 | <0.03 | <0.08 | <0.001 | 0.04 | <0.003 | <0.001 | <0.03 | <0.05 | <0.002 | <0.04 | <0.004 | 17 |
| Example | Treatment Liquid (A) | 0.05 | <0.03 | <0.03 | <0.08 | <0.001 | 0.04 | <0.003 | <0.001 | <0.03 | <0.05 | <0.002 | <0.04 | <0.004 | 13 |
| 32 | Treatment Liquid (B) | 0.04 | <0.03 | <0.03 | <0.08 | <0.001 | 0.03 | <0.003 | <0.001 | <0.03 | <0.05 | <0.002 | <0.04 | <0.004 | 18 |
| | Liquid Chemical | 0.05 | <0.03 | <0.03 | <0.08 | <0.001 | 0.04 | <0.003 | <0.001 | <0.03 | <0.05 | <0.002 | <0.04 | <0.004 | 15 |
| Example | Treatment Liquid (A) | 0.06 | <0.03 | <0.03 | <0.08 | <0.001 | 0.04 | <0.003 | <0.001 | <0.03 | <0.05 | <0.002 | <0.04 | <0.004 | 12 |
| 33 | Treatment Liquid (B) | 0.03 | <0.03 | <0.03 | <0.08 | <0.001 | 0.04 | <0.003 | <0.001 | <0.03 | <0.05 | <0.002 | <0.04 | <0.004 | 17 |
| | Liquid Chemical | 0.04 | <0.03 | <0.03 | <0.08 | <0.001 | 0.04 | <0.003 | <0.001 | <0.03 | <0.05 | <0.002 | <0.04 | <0.004 | 15 |
| Example | Treatment Liquid (A) | 0.06 | <0.03 | <0.03 | <0.08 | <0.001 | 0.05 | <0.003 | <0.001 | <0.03 | <0.05 | <0.002 | <0.04 | <0.004 | 28 |
| 34 | Treatment Liquid (B) | 0.05 | <0.03 | <0.03 | <0.08 | <0.001 | 0.03 | <0.003 | <0.001 | <0.03 | <0.05 | <0.002 | <0.04 | <0.004 | 13 |
| | Liquid Chemical | 0.05 | <0.03 | <0.03 | <0.08 | <0.001 | 0.04 | <0.003 | <0.001 | <0.03 | <0.05 | <0.002 | <0.04 | <0.004 | 22 |
| Example | Treatment Liquid (A) | 0.03 | <0.03 | <0.03 | <0.08 | <0.001 | 0.02 | <0.003 | <0.001 | <0.03 | <0.05 | <0.002 | <0.04 | <0.004 | 8 |
| 35 | Treatment Liquid (B) | <0.02 | <0.03 | <0.03 | <0.08 | <0.001 | 0.03 | <0.003 | <0.001 | <0.03 | <0.05 | <0.002 | <0.04 | <0.004 | 3 |
| | Liquid Chemical | 0.02 | <0.03 | <0.03 | <0.08 | <0.001 | 0.03 | <0.003 | <0.001 | <0.03 | <0.05 | <0.002 | <0.04 | <0.004 | 6 |
| Example | Treatment Liquid (A) | 0.06 | <0.03 | <0.03 | <0.08 | <0.001 | 0.05 | <0.003 | <0.001 | <0.03 | <0.05 | <0.002 | <0.04 | <0.004 | 9 |
| 36 | Treatment Liquid (B) | 0.05 | <0.03 | <0.03 | <0.08 | <0.001 | 0.05 | <0.003 | <0.001 | <0.03 | <0.05 | <0.002 | <0.04 | <0.004 | 5 |
| | Liquid Chemical | 0.06 | <0.03 | <0.03 | <0.08 | <0.001 | 0.05 | <0.003 | <0.001 | <0.03 | <0.05 | <0.002 | <0.04 | <0.004 | 8 |
| Example | Treatment Liquid (A) | 0.09 | <0.03 | 0.06 | 0.09 | <0.001 | 0.08 | <0.003 | <0.001 | <0.03 | <0.05 | <0.002 | <0.04 | <0.004 | 4 |
| 37 | Treatment Liquid (B) | 0.08 | <0.03 | 0.05 | 0.09 | <0.001 | 0.09 | <0.003 | <0.001 | <0.03 | <0.05 | <0.002 | <0.04 | <0.004 | 8 |
| | Liquid Chemical | 0.09 | <0.03 | 0.06 | 0.09 | <0.001 | 0.09 | <0.003 | <0.001 | <0.03 | <0.05 | <0.002 | <0.04 | <0.004 | 5 |
| Example | Treatment Liquid (A) | 0.07 | <0.03 | 0.04 | <0.08 | <0.001 | 0.06 | <0.003 | <0.001 | <0.03 | <0.05 | <0.002 | <0.04 | <0.004 | 3 |
| 38 | Treatment Liquid (B) | 0.07 | <0.03 | 0.04 | 0.08 | <0.001 | 0.07 | <0.003 | <0.001 | <0.03 | <0.05 | <0.002 | <0.04 | <0.004 | 5 |
| | Liquid Chemical | 0.07 | <0.03 | 0.04 | <0.08 | <0.001 | 0.07 | <0.003 | <0.001 | <0.03 | <0.05 | <0.002 | <0.04 | <0.004 | 5 |
| Compar- | Treatment Liquid (A) | 0.07 | <0.03 | 0.05 | 0.08 | <0.001 | 0.07 | <0.003 | <0.001 | <0.03 | <0.05 | <0.002 | <0.04 | <0.004 | 320 |
| ative | Treatment Liquid (B) | 0.06 | <0.03 | 0.05 | <0.08 | <0.001 | 0.06 | <0.003 | <0.001 | <0.03 | <0.05 | <0.002 | <0.04 | <0.004 | 480 |
| Example | Liquid Chemical | 0.07 | <0.03 | 0.05 | <0.08 | <0.001 | 0.07 | <0.003 | <0.001 | <0.03 | <0.05 | <0.002 | <0.04 | <0.004 | 400 |
| 5 | | | | | | | | | | | | | | | |
| Compar- | Treatment Liquid (A) | 0.62 | 0.28 | 0.37 | 0.48 | <0.001 | 0.51 | <0.003 | <0.001 | <0.03 | <0.05 | <0.002 | <0.04 | <0.004 | 750 |
| ative | Treatment Liquid (B) | 0.32 | 0.17 | 0.23 | 0.28 | <0.001 | 0.62 | <0.003 | <0.001 | <0.03 | <0.05 | <0.002 | <0.04 | <0.004 | 900 |
| Example | Liquid Chemical | 0.47 | 0.24 | 0.31 | 0.38 | <0.001 | 0.58 | <0.003 | <0.001 | <0.03 | <0.05 | <0.002 | <0.04 | <0.004 | 840 |
| 6 | | | | | | | | | | | | | | | |

### Example 24

The procedure of Example 23 was repeated with the exception that the fourth refinement step was carried out by distilling PGMEA under a condition of 80° C. and under a reduced pressure of 10 kPa to eliminate metal impurities from the nonaqueous organic solvent, thereby obtaining treatment liquids (A) and (B). Additionally, 1.000 g of the treatment liquid (A) and 1000 g of the treatment liquid (B) were mixed thereby obtaining a liquid chemical for forming a water-repellent protective film. The conditions for preparing the treatment liquids (A) and (B) are shown in Table 5 and the results of evaluating the obtained treatment liquids (A) and (B) and liquid chemical are shown in Table 6.

### Examples 25-34

The procedure of Example 23 was repeated upon modifying the agent for forming a water-repellent protective film and the nonaqueous organic solvent, thereby obtaining treatment liquids (A) and (B). Moreover, a liquid chemical for forming a protective film was obtained from the treatment liquids (A) and (B). The conditions for preparing the treatment liquids (A) and (B) are shown in Table 5 and the results of evaluating the obtained treatment liquids (A) and (B) and liquid chemical are shown in Table 6.

By the way, “DPGMPE” means dipropylene glycol methyl propyl ether, “14BGDA” means 1,4-butylene glycol diacetate, “GBL” means γ-butyrolactone, “BDMAS” means butyl(dimethyl)dimethylaminosilane [C₄H₉(CH₃)₂Si—N(CH₃)₂], “DOTMDS” means 1,3-dioctyltetramethyldisilazane [C₈H₇(CH₃)₂SiNHSi(CH₃)₂C₈H₁₇].

### Example 35

The procedure of Example 23 was repeated with the exception that an ion exchange resin membrane (ION CLEAN SL No. DFA1SRPESW44 produced by Pall Corporation, Surface area: 1100 cm², Number of filter: 2) and a particle-eliminating membrane having a particle-eliminating diameter of 0.05 μm (Optimizer D600 produced by Nihon. Entegris K.K. Surface area: 600 cm², Number of capsule filter: 2) were used in the fourth refinement step while an ion exchange resin membrane (ION CLEAN SL No. DFA1SRPESW44 produced by Pall Corporation, Surface area: 1100 cm², Number of filter: 4) and a particle-eliminating membrane having a particle-eliminating diameter of 0.05 μm (Optimizer D600 produced by Nihon Entegris K.K., Surface area: 600 cm², Number of filter: 4) were used in the fifth refinement step, thereby obtaining treatment liquids (A) and (B). Additionally; from the treatment liquids (A) and (B), a liquid chemical for forming a protective film was obtained. The conditions for preparing the treatment liquids (A) and (B) are shown in Table 5 and the results of evaluating the obtained treatment liquids (A) and (B) and liquid chemical are shown in Table 6.

### Example 36

The procedure of Example 23 was repeated with the exception that an ion exchange resin membrane (ION CLEAN SL No. DFA1SRPESW44 produced by Pall Corporation, Surface area: 1100 cm², Number of filter: 1) and a particle-eliminating membrane having a particle-eliminating diameter of 0.05 μm (Optimizer D600 produced by Nihon Entegris K.K., Surface area: 600 cm², Number of capsule filter: 1) were used in the fifth refinement step, thereby obtaining treatment liquids (A) and (B). Additionally from the treatment liquids (A) and (B), a liquid, chemical for forming a protective film was obtained. The conditions for preparing the treatment liquids (A) and (B) are shown in Table 5 and the results of evaluating the obtained treatment liquids (A) and (B) and liquid chemical are shown in Table 6.

### Example 37

The fourth refinement step of Example 23 was not performed. In a sixth refinement step, a treatment liquid (A) of after the step for preparing a treatment liquid (A) and a treatment liquid (B) of after the step for preparing a treatment liquid (B) were refined by being independently permeated through the same ion exchange resin membrane and particle-eliminating membrane as those used in the fifth refinement step of Example 23. However, metal impurities contained in the treatment liquids were not sufficiently eliminated only by permeating them through one-pass system; therefore the treatment liquids were circulated to be permeated through the membrane two or more times, thereby eliminating the metal impurities sufficiently from the treatment, liquids. With the exception of the above, the procedure of Example 23 was repeated thereby obtaining treatment liquids (A) and (B). Additionally, from the treatment liquids (A) and (B), a liquid chemical for forming a protective film was obtained. The conditions for preparing the treatment liquids (A) and (B) are shown in Table 5 and the results of evaluating the obtained treatment liquids (A) and (B) and liquid chemical are shown in Table 6.

### Example 38

The procedure of Example 37 was repeated with the exception that an ion exchange resin membrane (ION CLEAN SL No. DFA1SRPESW44 produced by Pall Corporation, Surface area: 1100 cm², Number of filter: 4) and a particle-eliminating membrane having a particle-eliminating diameter of 0.05 μm (Optimizer D600 produced by Nihon Entegris K.K., Surface area: 600 cm², Number of filter: 4) were used in the sixth refinement step, thereby obtaining treatment liquids (A) and (B). Additionally, from the treatment liquids (A) and (B), a liquid, chemical for forming a protective film was obtained. The conditions for preparing the treatment liquids (A) and (B) are shown in Table 5 and the results of evaluating the obtained, treatment liquids (A) and (B) and liquid chemical are shown in Table 6.

### Comparative Example 5

The procedure of Example 23 was repeated with the exception that the fifth refinement step was not performed, thereby obtaining treatment liquids (A) and (B). Additionally, from the treatment liquids (A) and (B), a liquid chemical for forming a protective film was obtained. The conditions for preparing the treatment liquids (A) and (B) are shown in Table 5 and the results of evaluating the obtained treatment liquids (A) and (B) and liquid chemical are shown in Table 6.

### Comparative Example 6

The procedure of Example 23 was repeated with the exception that the fourth and fifth refinement step were not performed, thereby obtaining treatment, liquids (A) and (B). Additionally from the treatment liquids (A) and (B), a liquid chemical for forming a protective film, was obtained. The conditions for preparing the treatment liquids (A) and (B) are shown in Table 5 and the results of evaluating the obtained treatment liquids (A) and (B) and liquid chemical are shown in Table 6.

### Example 39

A first refinement step was performed by one-pass filtration system where PGMEA was permeated through an ion exchange resin membrane with particle-eliminating membrane having a particle-eliminating diameter of 0.05 μm (Protego Plus LTX No. PRLZ02PQ1K produced by Nihon Entegris K.K., Surface area: 1.38 m², Number of filter: 4) at a flow rate of 20 L/min, thereby eliminating metal impurities from the solvent. In a mixing step, 1,910 kg of hexamethyldisilazane as a silylation reagent [HMDS: (CH₃SiNHSi(CH₃)₃] and 69 kg of acid (trifluoroacetic anhydride [(CF₃CO)₂O]) as an agent for forming a water-repellent protective film were added to 36,200 kg of PGMEA of after the first refinement step. Furthermore, a second refinement step was conducted by one-pass filtration system where the liquid chemical of after the mixing step was permeated through an ion exchange resin membrane with particle-eliminating membrane having a particle-eliminating diameter of 0.05 μm (Protego Plus LTX No. PRLZ02PQ1K produced by Nihon Entegris K.K., Surface area: 1.38 m², Number of filter: 8) at a flow rate of 30 L/min, thereby obtaining a liquid chemical for forming a protective film from which metal impurities and particles had been eliminated. As the material of a portion of a pipe for leading a liquid after the mixing step which portion is to be brought into contact with the liquid, a copolymer of tetrafluoroethylene and perfluoroalkylvinylether (PFA) was employed. As a result of measuring the charged electric potential of the obtained liquid chemical by using an explosion-proof type digital static meter (KSD-0180 model produced by KASUGA DENKI, Inc.), the charged electric potential of the liquid chemical was 30 kV. The conditions for preparing the liquid chemical are shown in Table 7 and the results of evaluating the obtained liquid chemical are shown in Table 8.

TABLE 7

| | | | | | Second or Third Refinement Step | Prep- | | Remarks |
|---|---|---|---|---|---|---|---|---|
| | Silylation | | Embodi- | First Refinement Step | (Liquid Chemical Refinement | aration | Discharge | (Number of |
| | Reagent | Solvent | ment | (Solvent Refinement Method) | Method) | Method | Step | Filters) |
| Example | HMDS | PGMEA | 1st | One-pass refinement using ion | One-pass refinement using ion | 1st | Not | 1st Refinement: |
| 39 | | | | exchange resin membrane and | exchange resin membrane and | | Performed | 4 each |
| | | | | particle-eliminating membrane | particle-eliminating membrane | | | 2nd Refinement: |
| | | | | | | | | 8 each |
| Example | HMDS | PGMEA | 1st | — | Circulation refinement using ion | 2nd | Not | 3rd Refinement: |
| 40 | | | | | exchange resin membrane and | | Performed | 8 each |
| | | | | | particle-eliminating membrane | | | |
| Example | HMDS | PGMEA | 1st | One-pass refinement using ion | One-pass refinement using ion | 1st | Performed | 1st Refinement: |
| 41 | | | | exchange resin membrane and | exchange resin membrane and | | | 4 each |
| | | | | particle-eliminating membrane | particle-eliminating membrane | | | 2nd Refinement: |
| | | | | | | | | 8 each |
| Example | HMDS | PGMEA | 1st | One-pass refinement using ion | One-pass refinement using ion | 1st | Performed | 1st Refinement: |
| 42 | | | | exchange resin membrane and | exchange resin membrane and | | | 4 each |
| | | | | particle-eliminating membrane | particle-eliminating membrane | | | 2nd Refinement: |
| | | | | | | | | 8 each |
| Example | HMDS | PGMEA | 1st | One-pass refinement using ion | One-pass refinement using ion | 1st | Performed | 1st Refinement: |
| 43 | | | | exchange resin membrane and | exchange resin membrane and | | | 4 each |
| | | | | particle-eliminating membrane | particle-eliminating membrane | | | 2nd Refinement: |
| | | | | | | | | 8 each |
| Example | HMDS | PGMEA | 1st | Reduced-pressure distillation | One-pass refinement using ion | 1st | Performed | 2nd Refinement: |
| 44 | | | | | exchange resin membrane and | | | 8 each |
| | | | | | particle-eliminating membrane | | | |
| Example | HMDS | PGMEA | 1st | One-pass refinement using ion | One-pass refinement using ion | 1st | Performed | 1st Refinement: |
| 45 | | | | exchange resin membrane and | exchange resin membrane and | | | 4 each |
| | | | | particle-eliminating membrane | particle-eliminating membrane | | | 2nd Refinement: |
| | | | | | | | | 4 each |
| Example | HMDS | PGMEA | 1st | — | Circulation refinement using ion | 2nd | Performed | 3rd Refinement: |
| 46 | | | | | exchange resin membrane and | | | 8 each |
| | | | | | particle-eliminating membrane | | | |
| Example | HMDS | PGMEA | 1st | — | Circulation refinement using ion | 2nd | Performed | 3rd Refinement: |
| 47 | | | | | exchange resin membrane and | | | 12 each |
| | | | | | particle-eliminating membrane | | | |
| Example | FHEPA | IPA | 2nd | One-pass refinement using ion | One-pass refinement using ion | 1st | Not | 1st Refinement: |
| 48 | | DGEEA | | exchange resin membrane and | exchange resin membrane and | | Performed | 4 each |
| | | | | particle-eliminating membrane | particle-eliminating membrane | | | 2nd Refinement: |
| | | | | | | | | 8 each |
| Example | FHEPA | IPA | 2nd | — | Circulation refinement using ion | 2nd | Not | 3rd Refinement: |
| 49 | | DGEEA | | | exchange resin membrane and | | Performed | 8 each |
| | | | | | particle-eliminating membrane | | | |
| Example | FHEPA | IPA | 2nd | One-pass refinement using ion | One-pass refinement using ion | 1st | Performed | 1st Refinement: |
| 50 | | DGEEA | | exchange resin membrane and | exchange resin membrane and | | | 4 each |
| | | | | particle-eliminating membrane | particle-eliminating membrane | | | 2nd Refinement: |
| | | | | | | | | 8 each |
| Example | FHEPA | IPA | 2nd | Atmospheric-pressure distillation | One-pass refinement using ion | 1st | Performed | 2nd Refinement: |
| 51 | | DGEEA | | (IPA) | exchange resin membrane and | | | 8 each |
| | | | | Reduced-pressure distillation | particle-eliminating membrane | | | |
| | | | | (DGEEA) | | | | |
| Example | FHEPA | IPA | 2nd | One-pass refinement using ion | One-pass refinement using ion | 1st | Performed | 1st Refinement: |
| 52 | | DGEEA | | exchange resin membrane and | exchange resin membrane and | | | 4 each |
| | | | | particle-eliminating membrane | particle-eliminating membrane | | | 2nd Refinement: |
| | | | | | | | | 4 each |
| Example | FHEPA | IPA | 2nd | — | Circulation refinement using ion | 2nd | Performed | 3rd Refinement: |
| 53 | | DGEEA | | | exchange resin membrane and | | | 8 each |
| | | | | | particle-eliminating membrane | | | |
| Example | FHEPA | IPA | 2nd | — | Circulation refinement using ion | 2nd | Performed | 3rd Refinement: |
| 54 | | DGEEA | | | exchange resin membrane and | | | 12 each |
| | | | | | particle-eliminating membrane | | | |

TABLE 8

| | | | | | | | | | | | | | | | Charged |
|---|---|---|---|---|---|---|---|---|---|---|---|---|---|---|---|
| | | | | | | | | | | | | | | Number of | Potential of |
| | Metal impurity Concentration (mass ppb) | | | | | | | | | | | | | Particles | Liquid |
| | Na | Mg | K | Ca | Mn | Fe | Cu | Li | Al | Cr | Ni | Zr | Ag | (per 1 mL) | Chemical [kV] |
| Example 39 | 0.03 | <0.03 | <0.03 | <0.08 | <0.001 | 0.04 | 0.008 | <0.001 | <0.03 | <0.05 | <0.002 | <0.04 | <0.004 | 5 | 30 |
| Example 40 | 0.09 | <0.03 | 0.06 | 0.08 | 0.009 | 0.07 | 0.024 | <0.001 | <0.03 | <0.05 | 0.021 | <0.04 | <0.004 | 6 | 36 |
| Example 41 | 0.03 | <0.03 | <0.03 | <0.08 | <0.001 | 0.05 | 0.015 | <0.001 | <0.03 | <0.05 | 0.008 | <0.04 | <0.004 | 8 | 0.4 |
| Example 42 | 0.02 | <0.03 | <0.03 | <0.08 | <0.001 | 0.06 | 0.011 | <0.001 | <0.03 | <0.05 | 0.005 | <0.04 | <0.004 | 10 | 0.6 |
| Example 43 | 0.02 | <0.03 | <0.03 | <0.08 | <0.001 | 0.05 | <0.003 | <0.001 | <0.03 | <0.05 | <0.002 | <0.04 | <0.004 | 9 | 0.8 |
| Example 44 | 0.04 | <0.03 | <0.03 | <0.08 | <0.001 | 0.06 | 0.021 | <0.001 | <0.03 | <0.05 | <0.002 | <0.04 | <0.004 | 18 | 0.3 |
| Example 45 | 0.06 | <0.03 | <0.03 | <0.08 | <0.001 | 0.07 | 0.023 | <0.001 | <0.03 | 0.06 | 0.013 | <0.04 | <0.004 | 11 | 0.4 |
| Example 46 | 0.08 | <0.03 | 0.06 | <0.08 | 0.015 | 0.08 | 0.028 | <0.001 | <0.03 | <0.05 | 0.022 | <0.04 | <0.004 | 13 | 0.2 |
| Example 47 | 0.07 | <0.03 | 0.04 | <0.08 | 0.007 | 0.06 | 0.016 | <0.001 | <0.03 | 0.06 | 0.015 | <0.04 | <0.004 | 8 | 0.2 |
| Example 48 | 0.04 | <0.03 | <0.03 | <0.08 | <0.001 | 0.03 | <0.003 | <0.001 | <0.03 | <0.05 | <0.002 | <0.04 | <0.004 | 11 | 18 |
| Example 49 | 0.07 | <0.03 | 0.05 | <0.08 | 0.016 | 0.08 | 0.021 | <0.001 | <0.03 | <0.05 | <0.002 | <0.04 | <0.004 | 7 | 23 |
| Example 50 | 0.05 | <0.03 | <0.03 | <0.05 | <0.001 | 0.05 | <0.003 | <0.001 | <0.03 | <0.05 | 0.011 | <0.04 | <0.004 | 13 | 0.5 |
| Example 51 | 0.05 | <0.03 | <0.03 | <0.08 | <0.001 | 0.06 | 0.009 | <0.001 | <0.03 | <0.05 | 0.008 | <0.04 | <0.004 | 9 | 0.6 |
| Example 52 | 0.06 | <0.03 | <0.03 | <0.08 | 0.009 | 0.06 | 0.007 | <0.001 | <0.03 | <0.05 | 0.015 | <0.04 | <0.004 | 12 | 0.5 |
| Example 53 | 0.08 | <0.03 | 0.07 | <0.08 | 0.012 | 0.09 | 0.026 | <0.001 | <0.03 | <0.05 | 0.024 | <0.04 | <0.004 | 8 | 0.6 |
| Example 54 | 0.07 | <0.03 | 0.05 | <0.08 | 0.007 | 0.07 | 0.016 | <0.001 | <0.03 | <0.05 | 0.018 | <0.04 | <0.004 | 5 | 0.5 |

### Example 40

The first refinement step of Example 39 was not performed. In a third refinement step, a liquid chemical of after the mixing step was refined by being permeated through the same ion exchange resin membrane with particle-eliminating membrane as that used in the second refinement step of Example 39. However, metal impurities contained in the liquid chemical were not sufficiently eliminated only by permeating the liquid through one-pass system; therefore the liquid chemical was circulated to be permeated through the membrane two or more times, thereby eliminating the metal impurities sufficiently from the liquid chemical. With the exception of the above, the procedure of Example 39 was repeated thereby obtaining a liquid chemical for forming a protective film from which metal impurities and particles have been eliminated. The conditions for preparing the liquid chemical are shown in Table 7 and the results of evaluating the obtained liquid chemical are shown in Table 8.

### Example 41

The procedure of Example 39 was repeated with the exception that the liquid chemical of after the second refinement step was led in-line through a grounded electrically conductive pipe (Material: SUS316) having an outer diameter of 34.0 mm and a length of 50 min (wherein the time during which the electrically conductive material and the liquid chemical were contacted was 0.063 second), thereby obtaining a liquid chemical for forming a protective film from which metal impurities and particles have been eliminated. In an immersion test conducted by immersing a SUS316 test piece having a surface area of 14 cm² in 300 mL of a liquid chemical (the same as the liquid chemical obtained by this Example) at 45° C. for 700 hours, the elution amount of each of the elements Na, Mg, K, Ca, Mn, Fe, Cu, Li, Al, Cr, Ni, Zn and Ag was firstly determined. As a result of converting the elution amount into the concentration while adapting the conditions of this Example (Contacting area formed between the liquid chemical and the electrically conductive material: 32 cm², Throughput of the liquid chemical: 38,179 kg) thereto, the liquid chemical was confirmed to have a concentration of each of the elements Na, Mg, K, Ca, Mn, Fe, Cu, Li, Al, Cr, Ni, Zn and Ag of less than 0.01 mass ppb, or less than the minimum determination limit concerning elements having a minimum determination limit of not less than 0.01 mass ppb. Accordingly, SUS316 was employed as the electrically conductive pipe. As the material of a portion of a pipe for leading a liquid after the mixing step, other than the electrically conductive pipe, PFA was employed. The charged electric potential of the obtained liquid chemical was 0.4 kV. The conditions for preparing the liquid chemical are shown in Table 7 and the results of evaluating the obtained liquid chemical are shown in Table 8.

### Example 42

The procedure of Example 41 was repeated with the exception that an electrically conductive pipe having an outer diameter of 34.0 mm and a length of 24 mm (Material: SUS316, Time during which an electrically conductive material and a liquid chemical are contacted: 0.030 second) was used as an electrically conductive material, thereby obtaining a liquid chemical for forming a protective film. The charged electric potential of the obtained liquid chemical was 0.6 kV. The conditions for preparing the liquid chemical are shown in Table 7 and the results of evaluating the obtained liquid chemical are shown in Table 8.

### Example 43

The procedure of Example 41 was repeated with the exception that an electrically conductive pipe having an outer diameter of 34.0 mm and a length of 10 mm (Material: SUS316, Time during which an electrically conductive material and a liquid chemical are contacted: 0.013 second) was used as an electrically conductive material, thereby obtaining a liquid chemical for forming a protective film. The charged electric potential of the obtained liquid chemical was 0.8 kV. The conditions for preparing the liquid chemical are shown in Table 7 and the results of evaluating the obtained liquid chemical are shown in Table 8.

### Example 44

The procedure of Example 42 was repeated with the exception that the first refinement step was carried out by distilling PGMEA under a condition of 80° C., and under a reduced pressure of 1.0 kPa to eliminate metal impurities from the solvent, thereby obtaining a liquid chemical for forming a protective film. The charged electric potential of the obtained liquid chemical was 0.3 kV. The conditions for preparing the liquid chemical are shown in Table 7 and the results of evaluating the obtained liquid chemical are shown in Table 8.

### Example 45

The procedure of Example 41 was repeated with the exception that an ion exchange resin membrane with particle-eliminating membrane having a particle-eliminating diameter of 0.05 μm (Protego Plus LTX No PRLZ02PQ1K produced by Nihon Entegris K.K., Surface area: 1.38 m², Number of filter: 4) was used in the second refinement step, thereby obtaining a liquid chemical for forming a protective film. The conditions for preparing the liquid chemical are shown in Table 7 and the results of evaluating the obtained liquid chemical are shown in Table 8.

### Example 46

The first refinement step of Example 41 was not performed. In a third refinement step, a liquid chemical of after the mixing step was refined by being permeated through the same ion exchange resin membrane with particle-eliminating membrane as that used in the second refinement step of Example 41. However, metal impurities contained in the liquid chemical were not sufficiently eliminated only by permeating the liquid through one-pass system; therefore the liquid chemical was circulated to be permeated through the membrane two or more times, thereby eliminating the metal impurities sufficiently from the liquid chemical. With the exception of the above, the procedure of Example 41 was repeated thereby obtaining a liquid chemical for forming a protective film from which metal impurities and particles have been eliminated. The conditions for preparing the liquid chemical are shown in Table 7 and the results of evaluating the obtained liquid chemical are shown in Table 8.

### Example 47

The procedure of Example 46 was repeated with the exception that an ion exchange resin membrane with particle-eliminating membrane having a particle-eliminating diameter of 0.05 μm (Protego Plus LTX. No. PRLZ02PQ1K produced by Nihon Entegris K.K., Surface area: 1.38 m², Number of filter: 12) was used in the third refinement step, thereby obtaining a liquid chemical for forming a protective film. The conditions for preparing the liquid chemical are shown in Table 7 and the results of evaluating the obtained liquid chemical are shown in Table 8.

### Example 48

A first refinement step was performed by one-pass filtration system where iPA was permeated through an ion exchange resin membrane with particle-eliminating membrane having a particle-eliminating diameter of 0.05 μM (Protego Plus LTX No. PRLZ02PQ1K produced by Nihon Entegris K.K., Surface area: 1.38 m², Number of filter: 4) at a flow rate of 20 L/min, thereby eliminating metal impurities from the solvent. Likewise, a first refinement step was performed by one-pass filtration system where DGEEA was permeated through an on exchange resin membrane with particle-eliminating membrane having a particle-eliminating diameter of 0.05 μm (Protego Plus LTX No. PRLZ02PQ1K produced by Nihon Entegris K.K., Surface area: 1.38 m², Number of filter: 4) at a flow rate of 20 L/min, thereby eliminating metal impurities from the solvent. In a mixing step, 36 kg of iPA of after the first refinement, step, 39,960 kg of DGEEA of after the first refinement step and 4 kg of 2-(perfluorohexyl)ethyl phosphonic acid [FHEPA: CF₃(CF₂)₅(CH₂)₂P(O)(OH)₂] as an agent for forming a water-repellent protective film were mixed. Furthermore, a second refinement step was conducted by one-pass filtration system where the liquid chemical of after the mixing step was permeated through an ion exchange resin membrane with particle-eliminating membrane having a particle-eliminating diameter of 0.05 μm (Protege Plus LTX No. PRLZ02PQ1K produced by Nihon Entegris K.K., Surface area: 1.38 m², Number of filter: 8) at a flow rate of 30 L/min, thereby obtaining a liquid chemical for forming a protective film from which metal impurities and particles had been eliminated. As the material of a portion of a pipe for leading; a liquid after the mixing step which portion is to be brought into contact with the liquid, PFA was employed. The charged electric potential of the obtained liquid chemical was 18 kV. The conditions for preparing the liquid chemical are shown in Table 7 and the results of evaluating the Obtained liquid chemical are shown in Table 8.

### Example 49

The first refinement step of Example 48 was not performed. In a third refinement step, a liquid chemical of after the mixing step was refined by being permeated through the same ion exchange resin membrane with particle-eliminating membrane as that used in the second refinement step of Example 48. However, metal impurities contained in the liquid chemical were not sufficiently eliminated only by permeating the liquid, through one-pass system; therefore the liquid chemical was circulated to be permeated through the membrane two or more times, thereby eliminating the metal impurities sufficiently from the liquid chemical. With the exception of the above, the procedure of Example 48, was repeated thereby obtaining a liquid chemical for forming a protective film from which metal impurities and particles have been eliminated. The conditions for preparing the liquid chemical are shown in Table 7 and the results of evaluating the obtained liquid chemical are shown in Table 8.

### Example 50

The procedure of Example 48 was repeated with the exception that the liquid chemical of after the second refinement step was led in-line through a grounded electrically conductive pipe (Material: SUS316) having an outer diameter of 34.0 mm and a length of 24 mm (wherein the time during which the electrically conductive material and the liquid chemical were contacted was 0.030 second), thereby obtaining a liquid chemical for forming a protective film from which metal impurities and particles have been eliminated. In an immersion test conducted by immersing a SUS316 test piece having a surface area of 14 cm² in 300 mL of a liquid chemical (the same as the liquid chemical obtained by this Example) at 45° C. for 700 hours, the elution amount of each of the elements Na, Mg, K, Ca, Mn, Fe, Cu, Li, Al, Cr, Ni, Zn and Ag was firstly determined. As a result of converting the elution amount into the concentration while adapting the conditions of this Example (Contacting area formed between the liquid chemical and the electrically conductive material: 15 cm², Throughput of the liquid chemical: 39,996 kg) thereto, the liquid chemical was confirmed to have a concentration of each of the elements Na, Mg, K, Ca, Mn, Fe, Cu, Li, Al, Cr, Ni, Zn and Ag of less than 0.01 mass ppb, or less than the minimum determination limit concerning elements having a minimum determination limit of not less than 0.01 mass ppb. Accordingly, SUS316 was employed as the electrically conductive pipe. As the material of a portion of a pipe for leading a liquid after the mixing step, other than the electrically conductive pipe, PFA was employed. The charged electric potential of the obtained liquid chemical was 0.5 kV. The conditions for preparing the liquid chemical are shown in Table 7 and the results of evaluating the obtained liquid chemical are shown in Table 8.

### Example 51

The first refinement step was carried out by distilling iPA under a condition of 120° C. and 760 kPa under atmospheric pressure to eliminate metal impurities from the solvent. Likewise, the first refinement step was carried out by distilling DGEEA under a condition of 160° C. and under a reduced pressure of 5 kPa to eliminate metal impurities from the solvent. With the exception of the above, the procedure of Example 50 was repeated thereby obtaining a liquid chemical for forming a protective film from which metal purities and particles have been eliminated. The charged electric potential of the obtained liquid chemical was 0.6 kV. The conditions for preparing the liquid chemical are shown in Table 7 and the results of evaluating the obtained liquid chemical are shown in Table 8.

### Example 52

The procedure of Example 50 was repeated with the exception that an ion exchange resin membrane with particle-eliminating membrane having a particle-eliminating diameter of 0.05 μm (Protego Plus LTX No. PRLZ02PQ1K produced by Nihon Entegris K.K., Surface area 1.38 m², Number of filter: 4) was used in the second refinement step, thereby obtaining a liquid chemical for forming a protective film. The conditions for preparing the liquid chemical are shown in Table 7 and the results of evaluating the obtained liquid chemical are shown in Table 8.

### Example 53

The first refinement step of Example 50 was not performed. In a third refinement step, a liquid chemical of after the mixing step was refined by being permeated through the same ion exchange resin membrane with particle-eliminating membrane as that used in the second refinement step of Example 50. However, metal impurities contained in the liquid chemical were not sufficiently eliminated only by permeating the liquid through one-pass system; therefore the liquid chemical was circulated to be permeated through the membrane two or more times, thereby eliminating the metal impurities sufficiently from the liquid chemical. With the exception of the above, the procedure of Example 50 was repeated thereby obtaining a liquid chemical for forming a protective film from which metal impurities and particles have been eliminated. The conditions for preparing the liquid chemical are shown in Table 7 and the results of evaluating the obtained liquid chemical are shown in Table 8.

### Example 54

The procedure of Example 53 was repeated with the exception that an ion exchange resin membrane with particle-eliminating membrane having a particle-eliminating diameter of 0.05 μm (Protego Plus LTX No. PRLZ02PQ1K produced by Nihon Entegris K.K., Surface area: 1.38 m², Number of filter: 12) was used in the third refinement step, thereby obtaining a liquid chemical for forming a protective film. The conditions for preparing the liquid chemical are shown in Table 7 and the results of evaluating the obtained liquid chemical are shown in Table 8.

### Example 55

A fourth refinement step was performed by one-pass filtration system where PGMEA was permeated through an ion exchange resin membrane with particle-eliminating membrane having a particle-eliminating diameter of 0.05 μm (Protego Plus LTX No. PRLZ02PQ1K produced by Nihon Entegris K.K., Surface area: 1.38 m², Number of filter: 4) at a flow rate of 20 L/min, thereby eliminating metal impurities from the nonaqueous organic solvent. In a step of preparing a treatment liquid (A), 34,100 kg of PGMEA of after the fourth refinement step and 3,800 kg of octyl(dimethyl)dimethylaminosilane [ODMAS: C₈H₁₇(CH₃)₂Si—N(CH₃)₂] as a silylation reagent were mixed. Furthermore, a fifth refinement step was conducted by one-pass filtration system where the treatment liquid (A) of after the mixing step was permeated through an ion exchange resin membrane with particle-eliminating membrane having a particle-eliminating diameter of 0.05 μm (Protego Plus LTX No. PRLZ02PQ1K produced by Nihon Entegris K.K., Surface area 1.38 m², Number of filter: 8) at a flow rate of 30 L/min, thereby obtaining a treatment liquid (A) from which metal impurities and particles had been eliminated. In a step of preparing a treatment liquid (B), 38,000 kg of PGMEA of after the fourth refinement step and 1,130 kg of trifluoroacetic anhydride [(CF₃CO)₂]) as acid were mixed. Furthermore, a fifth refinement step was conducted by one-pass filtration system where the treatment liquid (B) of after the mixing step was permeated through an ion exchange resin membrane with particle-eliminating membrane having a particle-eliminating diameter of 0.05 μm (Protego Plus LTX No. PRLZ02PQ1K produced by Nihon Entegris K.K., Surface area: 1.38 my, Number of filter: 8) at a flow rate of 30 L/min, thereby obtaining a treatment liquid (B) from which metal impurities and particles bad been eliminated. As the material of a portion of a pipe for leading each of the treatment liquids after the step for preparing; a treatment liquid (A) and the step for preparing a treatment liquid (B), PEA was employed. The charged electric potential of the treatment liquid (A) was 37 kV while the charged electric potential of the treatment liquid (B) was 24 kV. Then, 1 kg of the treatment liquid (A) and 1 kg of the treatment liquid (B) were mixed thereby obtaining a liquid chemical for forming a water-repellent protective film. The conditions for preparing the treatment liquids (A) and (B) are shown in Table 9 and the results of evaluating the obtained treatment liquids (A) and (B) and liquid chemical are shown in Table 1.0.

TABLE 9

| | | Nonaqueous | | | | | | |
|---|---|---|---|---|---|---|---|---|
| | | Organic | | | | | | |
| | | Solvent | | | | | | |
| | | Treat- | Treat- | | | | | |
| | | ment | ment | Fourth Refinement Step | Fifth or Sixth Refinement Step | Prepa- | | Remarks |
| | Silylation | Liquid | Liquid | (Nonaqueous Organic Solvent | (Treatment Liquid Refinement | ration | | (Number of |
| | Reagent | (A) | (B) | Refinement Method | Method) | Method | Discharge Step | Filters) |
| Ex- | ODMAS | PGMEA | PGMEA | One-pass refinement using ion | One-pass refinement using ion | 3rd | Treatment Liquid | 4th Refinement: |
| ample | | | | exchange resin membrane and | exchange resin membrane and | | (A): Not Performed | 4 each |
| 55 | | | | particle-eliminating membrane | particle-eliminating membrane | | Treatment Liquid | 5th Refinement: |
| | | | | | | | (B): Not Performed | 8 each |
| | | | | | | | Liquid Chemical | |
| | | | | | | | — | |
| Ex- | ODMAS | PGMEA | PGMEA | — | Circulation refinement using ion | 4th | Treatment Liquid | 6th Refinement: |
| ample | | | | | exchange resin membrane and | | (A): Not Performed | 8 each |
| 56 | | | | | particle-eliminating membrane | | Treatment Liquid | |
| | | | | | | | (B): Not Performed | |
| | | | | | | | Liquid Chemical | |
| | | | | | | | — | |
| Ex- | ODMAS | PGMEA | PGMEA | One-pass refinement using ion | One-pass refinement using ion | 3rd | Treatment Liquid | 4th Refinement: |
| ample | | | | exchange resin membrane and | exchange resin membrane and | | (A): Performed | 4 each |
| 57 | | | | particle-eliminating membrane | particle-eliminating membrane | | Treatment Liquid | 5th Refinement: |
| | | | | | | | (B): Performed | 8 each |
| | | | | | | | Liquid Chemical | |
| | | | | | | | — | |
| Ex- | ODMAS | PGMEA | PGMEA | Reduced-pressure distillation | One-pass refinement using ion | 3rd | Treatment Liquid | 5th Refinement: |
| ample | | | | | exchange resin membrane and | | (A): Performed | 8 each |
| 58 | | | | | particle-eliminating membrane | | Treatment Liquid | |
| | | | | | | | (B): Performed | |
| | | | | | | | Liquid Chemical | |
| | | | | | | | — | |
| Ex- | ODMAS | PGMEA | PGMEA | One-pass refinement using ion | One-pass refinement using ion | 3rd | Treatment Liquid | 4th Refinement: |
| ample | | | | exchange resin membrane and | exchange resin membrane and | | (A): Performed | 4 each |
| 59 | | | | particle-eliminating membrane | particle-eliminating membrane | | Treatment Liquid | 5th Refinement: |
| | | | | | | | (B): Performed | 4 each |
| | | | | | | | Liquid Chemical | |
| | | | | | | | — | |
| Ex- | ODMAS | PGMEA | PGMEA | — | Circulation refinement using ion | 4th | Treatment Liquid | 6th Refinement: |
| ample | | | | | exchange resin membrane and | | (A): Performed | 8 each |
| 60 | | | | | particle-eliminating membrane | | Treatment Liquid | |
| | | | | | | | (B): Performed | |
| | | | | | | | Liquid Chemical | |
| | | | | | | | — | |
| Ex- | ODMAS | PGMEA | PGMEA | — | Circulation refinement using ion | 4th | Treatment Liquid | 6th Refinement: |
| ample | | | | | exchange resin membrane and | | (A): Performed | 12 each |
| 61 | | | | | particle-eliminating membrane | | Treatment Liquid | |
| | | | | | | | (B): Performed | |
| | | | | | | | Liquid Chemical | |
| | | | | | | | — | |

TABLE 10

| | | Metal impurity Concentration (mass ppb) | | | | | | | | |
|---|---|---|---|---|---|---|---|---|---|---|
| | | Na | Mg | K | Ca | Mn | Fe | Cu | Li | Al |
| Example | Treatment Liquid (A) | 0.04 | <0.03 | <0.03 | <0.08 | <0.001 | 0.03 | <0.003 | <0.001 | <0.03 |
| 55 | Treatment Liquid (B) | 0.04 | <0.03 | <0.03 | <0.08 | <0.001 | 0.04 | <0.003 | <0.001 | <0.03 |
| | Liquid Chemical | 0.04 | <0.03 | <0.03 | <0.08 | <0.001 | 0.04 | <0.003 | <0.001 | <0.03 |
| Example | Treatment Liquid (A) | 0.08 | <0.03 | 0.05 | 0.08 | <0.001 | 0.07 | <0.003 | <0.001 | <0.03 |
| 56 | Treatment Liquid (B) | 0.09 | <0.03 | 0.04 | 0.08 | <0.001 | 0.08 | <0.003 | <0.001 | <0.03 |
| | Liquid Chemical | 0.09 | <0.03 | 0.05 | 0.08 | <0.001 | 0.08 | <0.003 | <0.001 | <0.03 |
| Example | Treatment Liquid (A) | 0.06 | <0.03 | <0.03 | <0.08 | <0.001 | 0.04 | <0.003 | <0.001 | <0.03 |
| 57 | Treatment Liquid (B) | 0.03 | <0.03 | <0.03 | <0.08 | <0.001 | 0.03 | <0.003 | <0.001 | <0.03 |
| | Liquid Chemical | 0.05 | <0.03 | <0.03 | <0.08 | <0.001 | 0.04 | <0.003 | <0.001 | <0.03 |
| Example | Treatment Liquid (A) | 0.06 | <0.03 | <0.03 | 0.08 | <0.001 | 0.03 | <0.003 | <0.001 | <0.03 |
| 58 | Treatment Liquid (B) | 0.05 | <0.03 | <0.03 | <0.08 | <0.001 | 0.04 | <0.003 | <0.001 | <0.03 |
| | Liquid Chemical | 0.06 | <0.03 | <0.03 | <0.08 | <0.001 | 0.04 | <0.003 | <0.001 | <0.03 |
| Example | Treatment Liquid (A) | 0.07 | <0.03 | <0.03 | <0.08 | <0.001 | 0.06 | <0.003 | <0.001 | <0.03 |
| 59 | Treatment Liquid (B) | 0.05 | <0.03 | 0.04 | <0.08 | <0.001 | 0.04 | <0.003 | <0.001 | <0.03 |
| | Liquid Chemical | 0.06 | <0.03 | 0.03 | <0.08 | <0.001 | 0.05 | <0.003 | <0.001 | <0.03 |
| Example | Treatment Liquid (A) | 0.09 | <0.03 | 0.06 | <0.08 | <0.001 | 0.08 | <0.003 | <0.001 | <0.03 |
| 60 | Treatment Liquid (B) | 0.07 | <0.03 | 0.03 | 0.09 | <0.001 | 0.06 | <0.003 | <0.001 | <0.03 |
| | Liquid Chemical | 0.08 | <0.03 | 0.04 | 0.08 | <0.001 | 0.07 | <0.003 | <0.001 | <0.03 |
| Example | Treatment Liquid (A) | 0.08 | <0.03 | 0.05 | <0.08 | <0.001 | 0.07 | <0.003 | <0.001 | <0.03 |
| 61 | Treatment Liquid (B) | 0.06 | <0.03 | 0.04 | <0.08 | <0.001 | 0.05 | <0.003 | <0.001 | <0.03 |
| | Liquid Chemical | 0.07 | <0.03 | 0.04 | <0.08 | <0.001 | 0.06 | <0.003 | <0.001 | <0.03 |

| | | | | | | Number | Charged |
|---|---|---|---|---|---|---|---|
| | | | | | | of | Potential of |
| | | | | | | Particles | Treatment |
| | | Metal impurity Concentration (mass ppb) | | | | (per | Liquid |
| | | Cr | Ni | Zn | Ag | 1 mL) | [kV] |
| Example | Treatment Liquid (A) | <0.05 | <0.002 | <0.04 | <0.004 | 8 | 37 |
| 55 | Treatment Liquid (B) | <0.05 | <0.002 | <0.04 | <0.004 | 13 | 24 |
| | Liquid Chemical | <0.05 | <0.002 | <0.04 | <0.004 | 11 | — |
| Example | Treatment Liquid (A) | <0.05 | <0.002 | <0.04 | <0.004 | 10 | 32 |
| 56 | Treatment Liquid (B) | <0.05 | <0.002 | <0.04 | <0.004 | 14 | 21 |
| | Liquid Chemical | <0.05 | <0.002 | <0.04 | <0.004 | 12 | — |
| Example | Treatment Liquid (A) | <0.05 | <0.002 | <0.04 | <0.004 | 6 | 0.5 |
| 57 | Treatment Liquid (B) | <0.05 | <0.002 | <0.04 | <0.004 | 3 | 0.7 |
| | Liquid Chemical | <0.05 | <0.002 | <0.04 | <0.004 | 5 | — |
| Example | Treatment Liquid (A) | <0.05 | <0.002 | <0.04 | <0.004 | 13 | 0.6 |
| 58 | Treatment Liquid (B) | <0.05 | <0.002 | <0.04 | <0.004 | 16 | 0.5 |
| | Liquid Chemical | <0.05 | <0.002 | <0.04 | <0.004 | 15 | — |
| Example | Treatment Liquid (A) | <0.05 | <0.002 | <0.04 | <0.004 | 7 | 0.6 |
| 59 | Treatment Liquid (B) | <0.05 | <0.002 | <0.04 | <0.004 | 6 | 0.7 |
| | Liquid Chemical | <0.05 | <0.002 | <0.04 | <0.004 | 7 | — |
| Example | Treatment Liquid (A) | <0.05 | <0.002 | <0.04 | <0.004 | 7 | 0.6 |
| 60 | Treatment Liquid (B) | <0.05 | <0.002 | <0.04 | <0.004 | 11 | 0.6 |
| | Liquid Chemical | <0.05 | <0.002 | <0.04 | <0.004 | 9 | — |
| Example | Treatment Liquid (A) | <0.05 | <0.002 | <0.04 | <0.004 | 9 | 0.5 |
| 61 | Treatment Liquid (B) | <0.05 | <0.002 | <0.04 | <0.004 | 5 | 0.6 |
| | Liquid Chemical | <0.05 | <0.002 | <0.04 | <0.004 | 7 | — |

### Example 56

The fourth refinement step of Example 55 was not performed. In a sixth refinement step, the treatment liquid (A) of after the step of preparing a treatment liquid (A) and the treatment liquid (B) of after the step of preparing a treatment liquid (B) were refined by being independently permeated through the same ion exchange resin membrane with particle-eliminating membrane as that used in the fifth refinement step of Example 55. However, metal impurities contained in either of the treatment liquids were not sufficiently eliminated only by permeating the liquid through one-pass system; therefore the treatment liquids were circulated to be permeated through the membrane) or more times, thereby eliminating the metal impurities sufficiently from the treatment liquids. With the exception of the above, the procedure of Example 55 was repeated thereby obtaining treatment liquids (A) and (B). Additionally, from the treatment liquids (A) and (B), a liquid chemical for forming a protective film was obtained. The conditions for preparing the treatment liquids (A) and (B) are shown in Table 9 and the results of evaluating the obtained treatment liquids (A) and (B) and liquid chemical are shown in Table 10.

### Example 57

The procedure of Example 55 was repeated with the exception that the treatment liquid (A) of after the fifth refinement step was led in-line through a grounded electrically conductive pipe (Material: platinum) having an outer diameter of 34.0 mm and a length of 24 mm (wherein the time during which the electrically conductive material and the treatment liquid were contacted was 0.030 second), thereby obtaining a treatment liquid (A) from which metal impurities and particles have been eliminated. In addition, the procedure of Example 55 was repeated with the exception that the treatment liquid (B) of after the fifth refinement step was led in-line through a grounded electrically conductive pipe (Material: platinum) having an outer diameter of 34.0 mm and a length of 24 mm (wherein the time during which the electrically conductive material and the treatment liquid were contacted was 0.030 second), thereby obtaining a treatment liquid (B) from which metal impurities and particles have been eliminated. In an immersion test conducted by immersing a platinum test piece having a surface area of 14 cm² in 300 mL of each treatment liquid (the same as the treatment liquid (A) and the treatment liquid (B) obtained in this Example) at 45° C. for 700 hours, the elution amount of each of the elements Na, Mg, K, Ca, Mn, Fe, Cu, Li, Al, Cr, Ni, Zn and Ag was firstly determined. As a result of converting the elution amount into the concentration while adapting the conditions of this Example (Contacting area formed between the treatment liquid and the electrically conductive material: 15 cm², Throughput of the treatment liquid (A): 37,900 kg, Throughput of the treatment liquid (B): 39,130 kg) thereto, each of the treatment liquids was confirmed to have a concentration of each of the elements Na, Mg, K, Ca, Mn, Fe, Cu, Li, Al, Cr, Ni, Zn and Ag of less than 0.01 mass ppb, or less than the minimum determination limit concerning elements having a minimum determination limit of not less than 0.01 mass ppb. Accordingly, platinum was employed as the electrically conductive pipe. As the material of a portion of a pipe for leading each of the treatment liquids after the step for preparing a treatment liquid (A) and the step for preparing a treatment liquid (B), other than the electrically conductive pipe, PEA was employed. The charged electric potential of the obtained treatment liquid (A) was 0.5 kV while the charged electric potential of the treatment liquid (B) was 0.7 kV. Then, 1 kg of the treatment liquid (A) and 1 kg of the treatment liquid (B) were mixed thereby obtaining a liquid chemical for forming a water-repellent protective film. The conditions for preparing the treatment liquids (A) and (B) are shown in Table 9 and the results of evaluating the obtained treatment liquids (A) and (B) and liquid chemical are shown in Table 10.

### Example 58

The procedure of Example 57 was repeated with the exception that the fourth refinement step was carried out by distilling PGMEA under a condition of 80° C. and under a reduced pressure of 10 kPa to eliminate metal impurities from the nonaqueous organic solvent, thereby obtaining treatment liquids (A) and (B). The charged electric potential of the obtained treatment liquid (A) was 0.6 kV while the charged electric potential of the treatment liquid (B) was 0.5 kV. Then, 1 kg of the treatment liquid (A) and 1 kg of the treatment liquid (B) were mixed thereby obtaining a liquid chemical for forming a water-repellent protective film. The conditions for preparing the treatment liquids (A) and (B) are shown in Table 9 and the results of evaluating the obtained treatment liquids (A) and (B) and liquid chemical are shown in Table 10.

### Example 59

The procedure of Example 57 was repeated with the exception that an ion exchange resin membrane with particle-eliminating membrane having a particle-eliminating diameter of 0.05 μm (Protego Plus LTX. No. PRLZ02PQ1K produced by Nihon Entegris K.K., Surface area: 1.38 m², Number of filter: 4) was used in the fifth refinement step, thereby obtaining, treatment liquids (A) and (B). Additionally, from the treatment liquids (A) and (B), a liquid chemical for forming a protective film was obtained. The conditions for preparing the treatment liquids (A) and (B) are shown in Table 9 and the results of evaluating the obtained, treatment liquids (A) and (B) and liquid chemical are shown in Table 10.

### Example 60

The fourth refinement step of Example 57 was not performed. In a 9.5 sixth refinement step, the treatment liquid (A) of after the step of preparing a treatment liquid (A) and the treatment liquid (B) of after the step of preparing a treatment liquid (B) were refined by being independently permeated through the same ion exchange resin membrane with particle-eliminating membrane as that used in the fifth refinement step of Example 57. However, metal impurities contained in either of the treatment liquids were not sufficiently eliminated only by permeating the liquid through one-pass system; therefore the treatment liquids were circulated to be permeated through the membrane two or more times, thereby eliminating the metal impurities sufficiently from the treatment liquids. With the exception of the above, the procedure of Example 57 was repeated thereby obtaining treatment liquids (A) and KB). Additionally, from the treatment liquids (A) and (B), a liquid chemical for forming a protective film was obtained. The conditions for preparing the treatment liquids (A) and (B) are shown in Table 9 and the results of evaluating the obtained treatment liquids (A) and (B) and liquid chemical are shown in Table 10.

### Example 61

The procedure of Example 60 was repeated with the exception that an ion exchange resin membrane with particle-eliminating membrane having a particle-eliminating diameter of 0.05 μm (Protego Plus LTX No. PRLZ02PQ1K produced by Nihon Entegris K.K., Surface area: 1.38 m², Number of filter; 12) was used in the sixth refinement step, thereby obtaining treatment liquids (A) and (B). Additionally, from the treatment liquids (A) and (B), a liquid chemical for forming a protective film was obtained. The conditions for preparing the treatment liquids (A) and (B) are shown in Table 9 and the results of evaluating the obtained treatment liquids (A) and (B) and liquid chemical are shown in Table 10.

1. A method for preparing a liquid chemical for forming a water-repellant protective film, the liquid chemical having a solvent and an agent for forming a water-repellant protective film, the liquid chemical being for forming a water-repellent protective film at least on surfaces of recessed portions of an uneven pattern of a wafer having the uneven pattern at its surface, the method being characterized by comprising:
a first refinement step for eliminating the elements (metal impurities) Na, Mg, K, Ca, Mn, Fe, Cu, Li, Al, Cr, Ni, Zn and Ag in a solvent by distilling the solvent or by using a particle-eliminating membrane and an ion exchange resin membrane;
a mixing step for mixing the solvent of after the first refinement step and an agent for forming a water-repellant protective film; and
a second refinement step for eliminating particles in a liquid chemical of after the mixing step by using a particle-eliminating membrane.

2. A method for preparing a liquid chemical for forming a water-repellant protective film, as claimed in claim 1, characterized by further comprising a discharge step where at least one selected from the solvent of after the first refinement step and the liquid chemical for forming a water-repellent protective film which liquid chemical is obtained after the second refinement step is brought into contact with an electrically conductive material.

3. A method for preparing a liquid chemical for forming a water-repellant protective film, the liquid chemical having a solvent and an agent for forming a water-repellant protective film, the liquid chemical being for forming a water-repellent protective film at least on surfaces of recessed portions of an uneven pattern of a wafer having the uneven pattern at its surface, the method being characterized by comprising:
a mixing step for mixing a solvent and an agent for forming a water-repellant protective film; and
a third refinement step for eliminating the elements (metal impurities) Na, Mg, K, Ca, Mn, Fe, Cu, Li, Al, Cr, Ni, Zn and Ag and particles in a liquid chemical obtained after the mixing step, by using a particle-eliminating membrane and an ion exchange resin membrane.

4. A method for preparing a liquid chemical for forming a water-repellant protective film, as claimed in claim 3, characterized by further comprising a discharge step where the liquid chemical obtained after the third refinement step is brought into contact with an electrically conductive material.

5. A method for preparing a liquid chemical for forming a water-repellant protective film, as claimed in claim 1, characterized in that the agent for forming a water-repellant protective film comprises at least one agent selected from the group consisting of silylation reagents represented by the following general formula [1] and an acid or base,
(R¹)ₐSi(H)_{b}X¹_{4-a-b} [1],
wherein R¹ mutually independently represents a monovalent organic group having a C₁-C₁₈ monovalent hydrocarbon group the hydrogen elements of which may partially or entirely be replaced with a fluorine element(s);
X¹ mutually independently represents at least one selected from the group consisting of a monovalent functional group of which element to be bonded to a silicon element is nitrogen, a monovalent functional group of which element to be bonded to a silicon element is oxygen, a halogen group, a nitrile group and —CO—NH—Si(CH₃)₃ group;
“a” is an integer of from 1 to 3;
“b” is an integer of from 0 to 2; and
the total of “a” and “b” is 1 to 3.

6. A method for preparing a liquid chemical for forming a water-repellant protective film, as claimed in claim 5, characterized in that the acid comprises at least one selected from the group consisting of hydrogen chloride, sulfuric acid, perchloric acid, phosphoric acid, sulfonic acid represented by the following general formula [2] and anhydride thereof, carboxylic acid represented by the following general formula [3] and anhydride thereof, alkyl borate ester, aryl borate ester, boron tris(trifluoroacetate), trialkoxyboroxin, boron trifluoride and a silane compound represented by the following general formula [4]
R²S(O)₂OH [2]
wherein R² represents a C₁-C₁₈ monovalent hydrocarbon group the hydrogen elements of which may partially or entirely be replaced with a fluorine element(s);
R³COOH [3]
wherein R³ represents a C₁-C₁₈ monovalent hydrocarbon group the hydrogen elements of which may partially or entirely be replaced with a fluorine element(s);
(R⁴)_{c}Si(H)_{d}X²_{4-c-d} [4]
wherein R⁴ mutually independently represents a C₁-C₁₈ monovalent hydrocarbon group the hydrogen elements of which may partially or entirely be replaced with a fluorine element(s); X² mutually independently represents at least one selected from the group consisting of chloro group, —OCO—R⁵, wherein R⁵ is a C₁-C₁₈ monovalent hydrocarbon group the hydrogen elements of which may partially or entirely be replaced with a fluorine element(s), and —OS(O)₂—R⁶, wherein R⁶ is a C₁-C₁₈ monovalent hydrocarbon group the hydrogen elements of which may partially or entirely be replaced with a fluorine element(s);
“c” is an integer of from 1 to 3;
“d” is an integer of from 0 to 2;
and the total of “c” and “d” is 1 to 3.

7. A method for preparing a liquid chemical for forming a water-repellant protective film, as claimed in claim 5, characterized in that the base comprises at least one selected from the group consisting of ammonia, N,N,N′,N′-tetramethylethylenediamine, triethylenediamine, dimethylaniline, alkylamine, dialkylamine, trialkylamine, pyridine, piperazine, N-alkylmorpholine and a silane compound represented by the following general formula [5]
(R⁷)ₑSi(H)_{f}X³_{4-e-f} [5]
wherein R⁷ mutually independently represents a C₁-C₁₈ monovalent hydrocarbon group the hydrogen elements of which may partially or entirely be replaced with a fluorine element(s);
X³ mutually independently represents a monovalent functional group of which element to be bonded to a silicon element is nitrogen, the monovalent functional group possibly containing a fluorine element and/or a silicon element;
“e” is an integer of from 1 to 3;
“f” is an integer of from 0 to 2;
and the total of “e” and “f” is 1 to 3.

8. A method for preparing a liquid chemical for forming a water-repellant protective film, as claimed in claim 5, characterized in that the solvent comprises at least one selected from the group consisting of hydrocarbons, esters, ethers, ketones, halogen-containing solvents, sulfoxide-based solvents, lactone-based solvents, carbonate-based solvents, polyalcohol derivatives having no OH group, and nitrogen element-containing solvents having no N—H group.

9. A method for preparing a liquid chemical for forming a water-repellant protective film, as claimed in claim 1, characterized in that the agent for forming a water-repellant protective film comprises at least one kind selected from the group consisting of compounds represented by the following general formulas [6] to [13] and their salts;
R⁸—P(═O)(OH)_{g}(R⁹)_{2-g} [6]
wherein R⁸ represents a C₁-C₁₈ monovalent hydrocarbon group the hydrogen elements of which may partially or entirely be replaced with a fluorine element(s);
R⁹ mutually independently represents a monovalent organic group having a C₁-C₃ hydrocarbon group the hydrogen elements of which may partially or entirely be replaced with a fluorine element(s); and “g” is an integer of from 0 to 2;
R¹⁰—C(═O)—X⁴ [7]
wherein R¹⁰ represents a monovalent organic group having a C₁-C₁₈ hydrocarbon group or a monovalent organic group having a C₁-C₈ fluoroalkyl chain; X⁴ represents a group selected from the group consisting of fluoro group, chloro group, bromo group and iodo group;
R¹¹R¹²R¹³N [8]
wherein R¹¹ represents a monovalent organic group having a C₁-C₁₈ hydrocarbon group or a monovalent organic group having a C₁-C₈ fluoroalkyl chain; R¹² represents a hydrogen element, a monovalent organic group having a C₁-C₁₈ hydrocarbon group, or a monovalent organic group having a C₁-C₈ fluoroalkyl chain; R¹³ represents a hydrogen element, a monovalent organic group having a C₁-C₁₈ hydrocarbon group, or a monovalent organic group having a C₁-C₈ fluoroalkyl chain;
R¹⁴—C(═O)—X⁵—X⁶ [9]
wherein R¹⁴ represents a monovalent organic group having a C₁-C₁₈ hydrocarbon group or a monovalent organic group having a C₁-C₈ fluoroalkyl chain; X⁵ represents an oxygen element or sulfur element; X⁶ represents a group selected from the group consisting of a hydrogen element, alkyl group, aromatic group, pyridyl group, quinolyl group, succinimide group, maleimide group, benzoxazole group, benzothiazole group and benzotriazole group; and a hydrogen element(s) of these groups may be substituted with an organic group;
R¹⁵(X⁷)ₕ [10]
wherein formula [10] represents a compound where “h” hydrogen element(s) or fluorine element(s) of R¹⁵ representing a C₁-C₁₈ hydrocarbon the hydrogen elements of which may partially or entirely be replaced with a fluorine element(s) is mutually independently substituted with a group represented by X⁷, the group X⁷ being at least one selected from the group consisting of an isocyanate group, mercapto group, aldehyde group, —CONHOH group and a cyclic structure containing a nitrogen element, wherein “h” is an integer of from 1 to 6
R¹⁶—X⁸ 11]
wherein X⁸ represents a cyclic structure containing a sulfur element; R¹⁶ represents a monovalent organic group having a C₁-C₁₈ hydrocarbon group or a monovalent organic group having a C₁-C₈ fluoroalkyl chain;
R¹⁷—C(═O)—X⁹—C(═O)—R¹⁸ [12]
wherein R¹⁷ represents a monovalent organic group having a C₁-C₁₈ hydrocarbon group or a monovalent organic group having a C₁-C₈ fluoroalkyl chain; R¹⁸ represents a monovalent organic group having a C₁-C₁₈ hydrocarbon group or a monovalent organic group having a C₁-C₈ fluoroalkyl chain; and X⁹ represents an oxygen element or a sulfur element;
(R²⁴—O—(R²⁵O)ₜ—)ᵤP(═O)(OH)₃₋ᵤ [13]
wherein R²⁴ mutually independently represents a C₄-C₁₈ monovalent hydrocarbon group the hydrogen elements of which may partially or entirely be replaced with a fluorine element(s);
R²⁵ mutually independently represents a C₂-C₆ divalent hydrocarbon group the hydrogen elements of which may partially or entirely be replaced with a fluorine element(s);
“t” mutually independently represents an integer of from 0 to 10; and
“u” is 1 or 2.

10. A method for preparing a liquid chemical for forming a water-repellant protective film, as claimed in claim 9, characterized in that the solvent comprises at least one selected from the group consisting of hydrocarbons, esters, ethers, ketones, halogen-containing solvents, sulfoxide-based solvents, lactone-based solvents, carbonate-based solvents, alcohols, polyalcohol derivatives, nitrogen element-containing solvents and water.

11. A liquid chemical for forming a water-repellant protective film, prepared through the steps of the method for preparing a liquid chemical for forming a water-repellant protective film, as claimed in claim 1.

12. A method for preparing a liquid chemical kit for forming a water-repellant protective film, the liquid chemical kit being for forming a water-repellent protective film at least on surfaces of recessed portions of an uneven pattern of a wafer having the uneven pattern at its surface, the liquid chemical kit having a treatment liquid (A) that contains a nonaqueous organic solvent and a silylation reagent and a treatment liquid (B) that contains a nonaqueous organic solvent and an acid or base, the method being characterized by comprising:
a fourth refinement step for eliminating the elements (metal impurities) Na, Mg, K, Ca, Mn, Fe, Cu, Li, Al, Cr, Ni, Zn and Ag in a nonaqueous organic solvent by distilling the nonaqueous organic solvent or by using a particle-eliminating membrane and an ion exchange resin membrane;
a step of preparing a treatment liquid (A) by mixing the nonaqueous organic solvent of after the fourth refinement step and a silylation reagent;
a step of preparing a treatment liquid (B) by mixing the nonaqueous organic solvent of after the fourth refinement step and an acid or base; and
a fifth refinement step for eliminating particles in the treatment liquid (A) of after the step of preparing the treatment liquid (A) and or the treatment liquid (B) of after the step of preparing the treatment liquid (B), by using a particle-eliminating membrane.

13. A method for preparing a liquid chemical kit for forming a water-repellant protective film, as claimed in claim 12, characterized by further comprising a discharge step where at least one selected from the nonaqueous organic solvent of after the fourth refinement step and a treatment liquid obtained after the fifth refinement step is brought into contact with an electrically conductive material.

14. A method for preparing a liquid chemical kit for forming a water-repellant protective film, the liquid chemical kit being for forming a water-repellent protective film at least on surfaces of recessed portions of an uneven pattern of a wafer having the uneven pattern at its surface, the liquid chemical kit having a treatment liquid (A) that contains a nonaqueous organic solvent and a silylation reagent and a treatment liquid (B) that contains a nonaqueous organic solvent and an acid or base, the method being characterized by comprising:
a step of preparing a treatment liquid (A) by mixing a nonaqueous organic solvent and a silylation reagent;
a step of preparing a treatment liquid (B) by mixing a nonaqueous organic solvent and an acid or base; and
a sixth refinement step for eliminating the elements (metal impurities) Na, Mg, K, Ca, Mn, Fe, Cu, Li, Al, Cr, Ni, Zn and Ag and particles in the treatment liquid (A) of after the step of preparing the treatment liquid (A) and or the treatment liquid (B) of after the step of preparing the treatment liquid (B), by using a particle-eliminating membrane and an ion exchange resin membrane.

15. A method for preparing a liquid chemical kit for forming a water-repellant protective film, as claimed in claim 14, characterized by further comprising a discharge step where the treatment liquid (A) and/or the treatment liquid (B) obtained after the sixth refinement step is brought into contact with an electrically conductive material.

16. A method for preparing a liquid chemical kit for forming a water-repellant protective film, as claimed in claim 12, characterized in that the nonaqueous organic solvent comprises at least one selected from the group consisting of hydrocarbons, esters, ethers, ketones, halogen-containing solvents, sulfoxide-based solvents, lactone-based solvents, carbonate-based solvents, polyalcohol derivatives having no OH group, and nitrogen element-containing solvents having no N—H group.

17. A method for preparing a liquid chemical kit for forming a water-repellant protective film, as claimed in claim 12, characterized in that the silylation reagent comprises at least one selected from the group consisting of silicon compounds represented by the following general formula [1]
(R¹)ₐSi(H)_{b}X¹_{4-a-b} [1]
wherein R¹ mutually independently represents a monovalent organic group having a C₁-C₁₈ monovalent hydrocarbon group the hydrogen elements of which may partially or entirely be replaced with a fluorine element(s); X¹ mutually independently represents at least one selected from the group consisting of a monovalent functional group of which element to be bonded to a silicon element is nitrogen, a monovalent functional group of which element to be bonded to a silicon element is oxygen, a halogen group, a nitrile group and —CO—NH—Si(CH₃)₃ group;
“a” is an integer of from 1 to 3;
“b” is an integer of from 0 to 2; and
the total of “a” and “b” is 1 to 3.

18. A method for preparing a liquid chemical kit for forming a water-repellant protective film, as claimed in claim 12, characterized in that the silylation reagent comprises a silicon compound represented by the following general formula [14].
R¹⁹ᵢSiX¹⁰₄₋ᵢ [14]
wherein R¹⁹ mutually independently represents at least one group selected from a hydrogen group and a C₁-C₁₈ monovalent hydrocarbon group the hydrogen elements of which may partially or entirely be replaced with a fluorine element(s), wherein the total number of carbons contained in all of the hydrocarbon groups bonded to a silicon element is not smaller than 6;
X¹⁰ mutually independently represents at least one group selected from a monovalent functional group of which element to be bonded to a silicon element is nitrogen, a monovalent functional group of which element to be bonded to a silicon element is oxygen, a halogen group, a nitrile group and —CO—NH—Si(CH₃)₃ group; and
“i” is an integer of from 1 to 3.

19. A method for preparing a liquid chemical kit for forming a water-repellant protective film, as claimed in claim 12, characterized in that the acid comprises at least one selected from the group consisting of hydrogen chloride, sulfuric acid, perchloric acid, phosphoric acid, sulfonic acid represented by the following general formula [2] and anhydride thereof, carboxylic acid represented by the following general formula [3] and anhydride thereof, alkyl borate ester, aryl borate ester, boron tris(trifluoroacetate), trialkoxyboroxin, boron trifluoride and a silane compound represented by the following general formula [4]
R²S(O)₂OH [2]
wherein R² represents a C₁-C₁₈ monovalent hydrocarbon group the hydrogen elements of which may partially or entirely be replaced with a fluorine element(s);
R³COOH [3]
wherein R³ represents a C₁-C₁₈ monovalent hydrocarbon group the hydrogen elements of which may partially or entirely be replaced with a fluorine element(s);
(R⁴)_{c}Si(H)_{d}X²_{4-c-d} [4]
wherein R⁴ mutually independently represents a C₁-C₁₈ monovalent hydrocarbon group the hydrogen elements of which may partially or entirely be replaced with a fluorine element(s); X² mutually independently represents at least one selected from the group consisting of chloro group, —OCO—R⁵ (where R⁵ is a C₁-C₁₈ monovalent hydrocarbon group the hydrogen elements of which may partially or entirely be replaced with a fluorine element(s)) and —OS(O)₂—R⁶ (where R⁶ is a C₁-C₁₈ monovalent hydrocarbon group the hydrogen elements of which may partially or entirely be replaced with a fluorine element(s));
“c” is an integer of from 1 to 3;
“d” is an integer of from 0 to 2; and
the total of “c” and “d” is 1 to 3.

20. A method for preparing a liquid chemical kit for forming a water-repellant protective film, as claimed in claim 12, characterized in that the base comprises at least one selected from the group consisting of ammonia, N,N,N′,N′-tetramethylethylenediamine, triethylenediamine, dimethylaniline, alkylamine, dialkylamine, trialkylamine, pyridine, piperazine, N-alkylmorpholine and a silane compound represented by the following general formula [5].
(R⁷)ₑSi(H)_{f}X³_{4-e-f} [5]
wherein R⁷ mutually independently represents a C₁-C₁₈ monovalent hydrocarbon group the hydrogen elements of which may partially or entirely be replaced with a fluorine element(s);
X³ mutually independently represents a monovalent functional group of which element to be bonded to a silicon element is nitrogen, the monovalent functional group possibly containing a fluorine element and/or a silicon element;
“e” is an integer of from 1 to 3;
“f” is an integer of from 0 to 2; and
the total of “e” and “f” is 1 to 3.

21. A liquid chemical kit for forming a water-repellant protective film, prepared through the steps of the method for preparing a liquid chemical kit for forming a water-repellant protective film, as claimed in claim 12.

22. A method for preparing a liquid chemical for forming a water-repellant protective film, as claimed in claim 3, characterized in that the agent for forming a water-repellant protective film comprises at least one selected from the group consisting of silylation reagents represented by the following general formula [1] and an acid or base
(R¹)ₐSi(H)_{b}X¹_{4-a-b} [1]
wherein R¹ mutually independently represents a monovalent organic group having a C₁-C₁₈ monovalent hydrocarbon group the hydrogen elements of which may partially or entirely be replaced with a fluorine element(s); X¹ mutually independently represents at least one selected from the group consisting of a monovalent functional group of which element to be bonded to a silicon element is nitrogen, a monovalent functional group of which element to be bonded to a silicon element is oxygen, a halogen group, a nitrile group and —CO—NH—Si(CH₃)₃ group; “a” is an integer of from 1 to 3; “b” is an integer of from 0 to 2;
and the total of “a” and “b” is 1 to 3.

23. A method for preparing a liquid chemical for forming a water-repellant protective film, as claimed in claim 22, characterized in that the solvent comprises at least one selected from the group consisting of hydrocarbons, esters, ethers, ketones, halogen-containing solvents, sulfoxide-based solvents, lactone-based solvents, carbonate-based solvents, polyalcohol derivatives having no OH group, and nitrogen element-containing solvents having no N—H group.

24. A method for preparing a liquid chemical for forming a water-repellant protective film, as claimed in claim 3, characterized in that the agent for forming a water-repellant protective film comprises at least one kind selected from the group consisting of compounds represented by the following general formulas [6] to [13] and their salts
R⁸—P(═O)(OH)_{g}(R⁹)_{2-g} [6]
wherein R⁸ represents a C₁-C₁₈ monovalent hydrocarbon group the hydrogen elements of which may partially or entirely be replaced with a fluorine element(s); R⁹ mutually independently represents a monovalent organic group having a C₁-C₃ hydrocarbon group the hydrogen elements of which may partially or entirely be replaced with a fluorine element(s);
and “g” is an integer of from 0 to 2;
R¹⁰—C(═O)—X⁴ [7]
wherein R¹⁰ represents a monovalent organic group having a C₁-C₁₈ hydrocarbon group or a monovalent organic group having a C₁-C₈ fluoroalkyl chain; X⁴ represents a group selected from the group consisting of fluoro group, chloro group, bromo group and iodo group;
R¹¹R¹²R¹³N [8]
wherein R¹¹ represents a monovalent organic group having a C₁-C₁₈ hydrocarbon group or a monovalent organic group having a C₁-C₈ fluoroalkyl chain; R¹² represents a hydrogen element, a monovalent organic group having a C₁-C₁₈ hydrocarbon group, or a monovalent organic group having a C₁-C₈ fluoroalkyl chain; R¹³ represents a hydrogen element, a monovalent organic group having a C₁-C₁₈ hydrocarbon group, or a monovalent organic group having a C₁-C₈ fluoroalkyl chain;
R¹⁴—C(═O)—X⁵—X⁶ [9]
wherein R¹⁴ represents a monovalent organic group having a C₁-C₁₈ hydrocarbon group or a monovalent organic group having a C₁-C₈ fluoroalkyl chain; X⁵ represents an oxygen element or sulfur element; X⁶ represents a group selected from the group consisting of a hydrogen element, alkyl group, aromatic group, pyridyl group, quinolyl group, succinimide group, maleimide group, benzoxazole group, benzothiazole group and benzotriazole group; and a hydrogen element(s) of these groups may be substituted with an organic group;
R¹⁵(X⁷)ₕ [10]
wherein formula [10] represents a compound where “h” hydrogen element(s) or fluorine element(s) of R¹⁵ representing a C₁-C₁₈ hydrocarbon the hydrogen elements of which may partially or entirely be replaced with a fluorine element(s) is mutually independently substituted with a group represented by X⁷, the group X⁷ being at least one selected from the group consisting of an isocyanate group, mercapto group, aldehyde group, —CONHOH group and a cyclic structure containing a nitrogen element, wherein “h” is an integer of from 1 to 6;
R¹⁶—X⁸ [11]
wherein X⁸ represents a cyclic structure containing a sulfur element; R¹⁶ represents a monovalent organic group having a C₁-C₁₈ hydrocarbon group or a monovalent organic group having a C₁-C₈ fluoroalkyl chain;
R¹⁷—C(═O)—X⁹—C(═O)R¹⁸ [12]
wherein R¹⁷ represents a monovalent organic group having a C₁-C₁₈ hydrocarbon group or a monovalent organic group having a C₁-C₈ fluoroalkyl chain; R¹⁸ represents a monovalent organic group having a C₁-C₁₈ hydrocarbon group or a monovalent organic group having a C₁-C₈ fluoroalkyl chain; and X⁹ represents an oxygen element or a sulfur element;
(R²⁴—O—(R²⁵O)ₜ—)ᵤP(═O)(OH)₃₋ᵤ [13]
wherein R²⁴ mutually independently represents a C₄-C₁₈ monovalent hydrocarbon group the hydrogen elements of which may partially or entirely be replaced with a fluorine element(s); R²⁵ mutually independently represents a C₂-C₆ divalent hydrocarbon group the hydrogen elements of which may partially or entirely be replaced with a fluorine element(s); “t” mutually independently represents an integer of from 0 to 10; and “u” is 1 or 2.

25. A liquid chemical for forming a water-repellant protective film, prepared through the steps of the method for preparing a liquid chemical for forming a water-repellant protective film, as claimed in claim 3.

26. A method for preparing a liquid chemical kit for forming a water-repellant protective film, as claimed in claim 14, characterized in that the nonaqueous organic solvent comprises at least one selected from the group consisting of hydrocarbons, esters, ethers, ketones, halogen-containing solvents, sulfoxide-based solvents, lactone-based solvents, carbonate-based solvents, polyalcohol derivatives having no OH group, and nitrogen element-containing solvents having no N—H group.

27. A method for preparing a liquid chemical kit for forming a water-repellant protective film, as claimed in claim 14, characterized in that the silylation reagent comprises at least one selected from the group consisting of silicon compounds represented by the following general formula [1]
(R¹)ₐSi(H)_{b}X¹_{4-a-b} [1]
wherein R¹ mutually independently represents a monovalent organic group having a C₁-C₁₈ monovalent hydrocarbon group the hydrogen elements of which may partially or entirely be replaced with a fluorine element(s);
X¹ mutually independently represents at least one selected from the group consisting of a monovalent functional group of which element to be bonded to a silicon element is nitrogen, a monovalent functional group of which element to be bonded to a silicon element is oxygen, a halogen group, a nitrile group and —CO—NH—Si(CH₃)₃ group;
“a” is an integer of from 1 to 3;
“b” is an integer of from 0 to 2; and
the total of “a” and “b” is 1 to 3.

28. A method for preparing a liquid chemical kit for forming a water-repellant protective film, as claimed in claim 14, characterized in that the silylation reagent comprises a silicon compound represented by the following general formula [14].
R¹⁹ᵢSiX¹⁰₄₋ᵢ [14]
wherein R¹⁹ mutually independently represents at least one group selected from a hydrogen group and a C₁-C₁₈ monovalent hydrocarbon group the hydrogen elements of which may partially or entirely be replaced with a fluorine element(s), wherein the total number of carbons contained in all of the hydrocarbon groups bonded to a silicon element is not smaller than 6;
X¹⁰ mutually independently represents at least one group selected from a monovalent functional group of which element to be bonded to a silicon element is nitrogen, a monovalent functional group of which element to be bonded to a silicon element is oxygen, a halogen group, a nitrile group and —CO—NH—Si(CH₃)₃ group; and
“i” is an integer of from 1 to 3.

29. A method for preparing a liquid chemical kit for forming a water-repellant protective film, as claimed in claim 14, characterized in that the acid comprises at least one selected from the group consisting of hydrogen chloride, sulfuric acid, perchloric acid, phosphoric acid, sulfonic acid represented by the following general formula [2] and anhydride thereof, carboxylic acid represented by the following general formula [3] and anhydride thereof, alkyl borate ester, aryl borate ester, boron tris(trifluoroacetate), trialkoxyboroxin, boron trifluoride and a silane compound represented by the following general formula [4]
R²S(O)₂OH [2]
wherein R² represents a C₁-C₁₈ monovalent hydrocarbon group the hydrogen elements of which may partially or entirely be replaced with a fluorine element(s);
R³COOH [3]
wherein R³ represents a C₁-C₁₈ monovalent hydrocarbon group the hydrogen elements of which may partially or entirely be replaced with a fluorine element(s);
(R⁴)_{c}Si(H)_{d}X²_{4-c-d} [4]
wherein R⁴ mutually independently represents a C₁-C₁₈ monovalent hydrocarbon group the hydrogen elements of which may partially or entirely be replaced with a fluorine element(s); X² mutually independently represents at least one selected from the group consisting of chloro group, —OCO—R⁵ (where R⁵ is a C₁-C₁₈ monovalent hydrocarbon group the hydrogen elements of which may partially or entirely be replaced with a fluorine element(s)) and —OS(O)₂—R⁶ (where R⁶ is a C₁-C₁₈ monovalent hydrocarbon group the hydrogen elements of which may partially or entirely be replaced with a fluorine element(s)); “c” is an integer of from 1 to 3; “d” is an integer of from 0 to 2; and the total of “c” and “d” is 1 to 3.

30. A method for preparing a liquid chemical kit for forming a water-repellant protective film, as claimed in claim 14, characterized in that the base comprises at least one selected from the group consisting of ammonia, N,N,N′,N′-tetramethylethylenediamine, triethylenediamine, dimethylaniline, alkylamine, dialkylamine, trialkylamine, pyridine, piperazine, N-alkylmorpholine and a silane compound represented by the following general formula [5].
(R⁷)ₑSi(H)_{f}X³_{4-e-f} [5]
wherein R⁷ mutually independently represents a C₁-C₁₈ monovalent hydrocarbon group the hydrogen elements of which may partially or entirely be replaced with a fluorine element(s); X³ mutually independently represents a monovalent functional group of which element to be bonded to a silicon element is nitrogen, the monovalent functional group possibly containing a fluorine element and/or a silicon element; “e” is an integer of from 1 to 3; “f” is an integer of from 0 to 2; and the total of “e” and “f” is 1 to 3.

31. A liquid chemical kit for forming a water-repellant protective film, prepared through the steps of the method for preparing a liquid chemical kit for forming a water-repellant protective film, as claimed in claim 14.
